(19) United States
(12) Patent Application Publication
(10) Pub. No.: US 2007/0182885 A1
(43) Pub. Date: Aug. 9, 2007

(54) DISPLAY DEVICE

(75) Inventors: Yuji EGI, Atsugi (JP); Takeshi NISHI, Atsugi (JP); Tetsuji ISHITANI, Isehara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/669,427

(22) Filed: Jan. 31, 2007

(30) Foreign Application Priority Data
Feb. 2, 2006 (JP) 2006-026415

(51) Int. Cl. G02F 1/1335

(52) U.S. Cl. 349/96; 349/117

(57) ABSTRACT

The present invention provides a display device with higher contrast ratio. The display device includes a first substrate, a second substrate, a layer including a display element which is interposed between the first substrate and the second substrate, and stacked polarizers on an outer side of the first substrate or the second substrate. The stacked polarizers are arranged to be in parallel Nicols. The stacked polarizers have the same wavelength distribution in the extinction coefficients. Further, a retardation plate may be provided between the stacked polarizers and the first substrate or the second substrate. The stacked polarizers are provided for both of the first substrate and the second substrate, and the stacked polarizers on the outer side of the first substrate and the stacked polarizers on the outer side of the second substrate are arranged to be in crossed Nicols or parallel Nicols.

### TECHNICAL FIELD

The present invention relates to a structure of a display device for increasing a contrast ratio.

### BACKGROUND ART

A display device which is very thin and lightweight as compared to conventional cathode-ray tube display device, a so-called flat panel display, has been developed. A liquid crystal display device including a liquid crystal element as a display element, a display device including a self-light emitting element, an FED (Field Emission Display) using an electron source and the like compete in the market of flat panel displays. Therefore, lower power consumption and a higher contrast ratio are demanded in order to increase the added value and differentiate from other products.

A general liquid crystal display device includes one polarizing plate provided for each substrate so as to keep a contrast ratio. By reducing black luminance, the contrast ratio can be increased. Therefore, higher display quality can be provided when images are seen in a dark room such as a home theater room.

For example, in order to increase a contrast ratio, it is proposed that a first polarizing plate is provided on the outer side of a substrate on a viewing side of a liquid crystal cell, a second polarizing plate is provided on the outer side of a substrate opposite to the viewing side, and a third polarizing plate is provided for heightening the polarization degree when light from an auxiliary light source provided on the substrate side is polarized through the second polarizing plate and passes through the liquid crystal cell (Reference 1: PCT International Publication No. 2000/034821). As a result, it is possible to suppress unevenness of display which is caused due to shortage of polarization degree and polarization distribution of polarizing plates, and to improve a contrast ratio.

There is a problem in that contrast ratio also has viewing angle dependence. A primary factor in the occurrence of viewing angle dependence is that there is optical anisotropy between the major axis direction and the minor axis direction of liquid crystal molecules. Due to the optical anisotropy, the visibility of liquid crystals molecules when looking at a liquid crystal display device on the front side is different to their visibility when looking at the device from an oblique direction. Consequently, the luminance of white display and the luminance of black display change depending on the viewing angle, and the contrast ratio also has viewing angle dependence.

In order to solve the problem of the viewing angle dependence of the contrast ratio, a structure in which a retardation film is inserted has been proposed. For example, in vertical alignment mode (VA mode), by setting up biaxial retardation films having refractive indexes which differ in three directions so as to interpose a liquid crystal layer, the viewing angle is improved (Reference 2: ‘Optimum Film Compensation Modes for TN and VA LCDs’, SID98 DIGEST, pp. 315-318).

Further, a structure employing stacked wide view (WV) films in which a discotic liquid crystal compound is hybrid-aligned has been proposed for twisted nematic mode (TN mode) (Reference 3: Japanese Patent No. 3315476).

In a projection type liquid crystal display device, in order to solve a problem of deterioration of a polarizing plate, it is proposed that a structure in which two or more linear polarizing plates are stacked with their absorption axes corresponded to each other, thereby suppressing the decrease of display quality (Reference 4: Japanese Published Patent Application No. 2003-172819).

As an example of a flat panel display, in addition to a liquid crystal display device, there is a display device including an electroluminescent element. The electroluminescent element is a self-light emitting element and no illumination means such as a backlight is required, thereby thinning of a display device can be attempted. Further, a display device including an electroluminescent element has an advantageous effect that response speed is higher and dependence on a viewing angle is less than a liquid crystal display device.

A structure in which a polarizing plate or a circularly polarizing plate is provided is also proposed for a display device including an electroluminescent element as described above (Reference 5: Japanese Patent No. 2761453, and Reference 6: Japanese Patent No. 3174367).

As a structure of a display device including an electroluminescent element, a structure is proposed, in which light emitted from a light emitting element interposed between light-transmitting substrates can be observed as light on an anode substrate side and light on a cathode substrate side (Reference 7: Japanese Published Patent Application No. H10-255976).

### DISCLOSURE OF INVENTION

However, there is still a strong need to increase a contrast ratio and researches have been made for improvement of contrast in a display device.

For example, black luminance of a liquid crystal display device is higher than the black luminance of light emitting elements used for plasma display panels (PDP) and electroluminescent (EL) panels when they do not emit light. As a result, there is a problem in that the contrast ratio is low, and there is a strong demand for increasing the contrast ratio.

In addition, the demand for increasing a contrast ratio is for a display device including an electroluminescent element as well as a liquid crystal display device.

Therefore, it is an object of the present invention to increase the contrast ratio of such display devices. Further, another object of the present invention is to provide display devices with a wide viewing angle.

The present invention has been made in view of the aforementioned problems. One feature of the present invention is to provide a plurality of linear polarizers for one substrate. In the plurality of polarizers, polarizing plates each including one polarizing film may be stacked, or a plurality of polarizing films may be stacked in one polarizing plate. In addition, polarizing plates including a plurality of polarizing films may be stacked.

Note that in this specification, “a plurality of polarizers which are stacked” is referred to as stacked polarizers or a polarizer having a stacked structure, “a plurality of polarizing films which are stacked” is referred to as stacked polarizing films, and “a plurality of polarizing plates which are stacked” is referred to as stacked polarizing plates or a polarizing plate having a stacked structure.

One feature of the present invention is to arrange absorption axes of the plurality of polarizers described above so as to be in a parallel Nicols state.

A parallel Nicols state refers to such arrangement that angular deviation between absorption axes of polarizers is 0°. On the other hand, a crossed Nicols state refers to arrangement such that angular deviation between absorption axes of polarizers is 90°. Note that a transmission axis is provided so as to be orthogonal to the absorption axis of a polarizer, and the crossed Nicols state and the parallel Nicols state are similarly defined when a transmission axes are used.

In this specification, it is assumed that the above angle range is to be satisfied in a parallel Nicols state and a crossed Nicols state; however, the angular deviation may differ from the above-described angles to some extent as long as a similar effect can be obtained.

One feature is that the plurality of linear polarizers of which absorption axes are parallel have the same wavelength distribution in the extinction coefficients.

In addition, a retardation plate (also referred to as a retardation film, a wavelength plate or a wave plate) may be provided between the stacked polarizers and a substrate.

Note that a combination of a polarizing plate and a retardation plate becomes a circularly polarizing plate. Thus, as a structure in which stacked polarizing plates are used as a retardation plate, a structure in which a circularly polarizing plate and a polarizing plate are stacked may be used.

A polarizer and a retardation plate provided for one substrate are arranged to be shifted by 45°. Specifically, when the angle of an absorption axis of the polarizer is 0° (when a transmission axis is 90°), the axis of a slow axis of the retardation plate is arranged to be 45° or 135°.

In this specification, although a polarizer and a retardation plate provided for one substrate are preferably arranged to be shifted from each other by 45°, the shift between the polarizer and the retardation plate may differ from the angle of 45° to some extent as long as a similar effect can be obtained.

The present invention relates to structures of display devices shown below.

An aspect of the present invention relates to a display device comprising: a first substrate; a second substrate; a layer including a display element which is interposed between the first substrate and the second substrate; and stacked polarizers on the outer side of the first substrate or the second substrate, wherein the stacked polarizers are arranged such that absorption axes of the stacked polarizers are in parallel Nicols to each other.

An aspect of the present invention also relates to a display device comprising: a first substrate; a second substrate; a layer including a display element which is interposed between the first substrate and the second substrate; stacked polarizers on the outer side of the first substrate; and stacked polarizers on the outer side of the second substrate, wherein the stacked polarizers on the outer side of the first substrate are arranged such that absorption axes of the stacked polarizers are in parallel Nicols to each other; wherein the stacked polarizers on the outer side of the second substrate are arranged such that absorption axes of the stacked polarizers are in parallel Nicols to each other, and wherein the absorption axes of the stacked polarizers on the outer side of the first substrate are arranged in crossed Nicols to the absorption axes of the stacked polarizers on the outer side of the second substrate.

An aspect of the present invention also relates to a display device comprising: a first substrate; a second substrate; a layer including a display element which is interposed between the first substrate and the second substrate; stacked polarizers on the outer side of the first substrate; and stacked polarizers on the outer side of the second substrate, wherein the stacked polarizers on the outer side of the first substrate are arranged such that absorption axes of the stacked polarizers are in parallel Nicols to each other; wherein the stacked polarizers on the outer side of the second substrate are arranged such that absorption axes of the stacked polarizers are in parallel Nicols to each other, and wherein the absorption axes of the stacked polarizers on the outer side of the first substrate are arranged in parallel Nicols to the absorption axes of the stacked polarizers on the outer side of the second substrate.

An aspect of the present invention also relates to a display device comprising: a first substrate; a second substrate; a layer including a display element which is interposed between the first substrate and the second substrate; stacked polarizers on the outer side of the first substrate or the second substrate; and a retardation plate between the stacked polarizers and the first substrate or the second substrate, wherein the stacked polarizers are arranged such that absorption axes of the stacked polarizers are in parallel Nicols to each other.

An aspect of the present invention also relates to a display device comprising: a first substrate; a second substrate; a layer including a display element which is interposed between the first substrate and the second substrate; and stacked polarizers on the outer side of the first substrate; stacked polarizers on the outer side of the second substrate; a first retardation plate between the first substrate and the stacked polarizers on the outer side of the first substrate; and a second retardation plate between the second substrate and the stacked polarizers on the outer side of the second substrate, wherein the stacked polarizers on the outer side of the first substrate are arranged such that absorption axes of the stacked polarizers are in parallel Nicols to each other; wherein the stacked polarizers on the outer side of the second substrate are arranged such that absorption axes of the stacked polarizers are in parallel Nicols to each other, and wherein the absorption axes of the stacked polarizers on the outer side of the first substrate are arranged in crossed Nicols to the absorption axes of the stacked polarizers on the outer side of the second substrate.

An aspect of the present invention also relates to a display device comprising: a first substrate; a second substrate; a layer including a display element which is interposed between the first substrate and the second substrate; and stacked polarizers on the outer side of the first substrate; stacked polarizers on the outer side of the second substrate; a first retardation plate between the first substrate and the stacked polarizers on the outer side of the first substrate; a second retardation plate between the second substrate and the stacked polarizers on the outer side of the second substrate, wherein the stacked polarizers on the outer side of the first substrate are arranged such that absorption axes of the stacked polarizers are in parallel Nicols to each other; wherein the stacked polarizers on the outer side of the second substrate are arranged such that absorption axes of the stacked polarizers are in parallel Nicols to each other, and wherein the absorption axes of the stacked polarizers on the outer side of the first substrate are arranged in parallel Nicols to the absorption axes of the stacked polarizers on the outer side of the second substrate.

In an aspect of the present invention, the absorption axes of the stacked polarizers and a slow axis of the retardation plate are arranged to be shifted by 45°.

In an aspect of the present invention, the absorption axes of the stacked polarizers on the outer side of the first substrate and a slow axis of the first retardation plate are arranged to be shifted by 45°; and the absorption axes of the stacked polarizers on the outer side of the second substrate and a slow axis of the second retardation plate are arranged to be shifted by 45°.

In an aspect of the present invention, the display element is a liquid crystal element.

In an aspect of the present invention, the display element is an electroluminescent element.

In an aspect of the present invention, each of the stacked polarizers has the same wavelength distribution in the extinction coefficients.

An aspect of the present invention is a display device including a display element interposed between a first light-transmitting substrate and a second light-transmitting substrate which are arranged to be opposite to each other; and stacked polarizing plates on the outer side of the first light-transmitting substrate or the second light-transmitting substrate, in which absorption axes of the stacked polarizing plates are arranged to be in a parallel Nicols state.

An aspect of the present invention is a display device including a display element interposed between a first light-transmitting substrate and a second light-transmitting substrate which are arranged to be opposite to each other; and stacked polarizing plates on the outer sides of the first light-transmitting substrate and the second light-transmitting substrate, in which absorption axes of the stacked polarizing plates are arranged to be in a parallel Nicols state, and absorption axes of the polarizing plates stacked on the outer sides of the first light-transmitting substrate and the second light-transmitting substrate are arranged to be in a crossed Nicols state.

An aspect of the present invention is a display device including a display element interposed between a first light-transmitting substrate and a second light-transmitting substrate which are arranged to be opposite to each other; a color filter provided on the inner side of the first light-transmitting substrate or the second light-transmitting substrate; and stacked polarizing plates on the outer sides of the first light-transmitting substrate and the second light-transmitting substrate, in which absorption axes of the stacked polarizing plates are arranged to be in a parallel Nicols state, and absorption axes of the polarizing plates provided on the outer sides of the first light-transmitting substrate and the second light-transmitting substrate are arranged to be in a crossed Nicols state.

An aspect of the present invention is a display device including a display element interposed between a first light-transmitting substrate and a second light-transmitting substrate which are arranged to be opposite to each other; and stacked polarizing plates on the outer sides of the first light-transmitting substrate and the second light-transmitting substrate, in which absorption axes of the stacked polarizing plates are arranged to be in a parallel Nicols state, absorption axes of the polarizing plates provided on the outer sides of the first light-transmitting substrate and the second light-transmitting substrate are arranged to be in a crossed Nicols state, and a change in transmittance in the case where the stacked polarizing plates are arranged to be in a parallel Nicols state is greater than that in the case where the stacked polarizing plates are arranged to be in a crossed Nicols state.

An aspect of the present invention is a display device including a display element interposed between a first light-transmitting substrate and a second light-transmitting substrate which are arranged to be opposite to each other; and stacked polarizing plates on the outer sides of the first light-transmitting substrate and the second light-transmitting substrate, in which absorption axes of the stacked polarizing plates are arranged to be in a parallel Nicols state, absorption axes of the polarizing plates provided on the outer sides of the first light-transmitting substrate and the second light-transmitting substrate are arranged to be in a crossed Nicols state, and a ratio of transmittance in the case where the stacked polarizing plates are arranged to be in a parallel Nicols state to transmittance in the case where the stacked polarizing plates are arranged to be in a crossed Nicols state is higher than a ratio of transmittance in the case where a pair of single polarizing plates is arranged to be in a parallel Nicols state to transmittance in the case where they are arranged to be in a crossed Nicols state.

In an aspect of the present invention, as the stacked polarizing plates, a first polarizing plate and a second polarizing plate are provided in contact with each other.

In an aspect of the present invention, the display element is a liquid crystal element.

An aspect of the present invention is a liquid crystal display device which includes a first light-transmitting substrate and a second light-transmitting substrate which are arranged to be opposite to each other, a display element which is interposed between the first light-transmitting substrate and the second light-transmitting substrate, and a retardation film and stacked polarizing plates which are sequentially arranged on the outer side of the first light-transmitting substrate and the second light-transmitting substrate, in which the stacked polarizing plates on each side are arranged to be in a parallel Nicols state.

An aspect of the present invention is a liquid crystal display device which includes a first light-transmitting substrate and a second light-transmitting substrate which are arranged to be opposite to each other, a display element which is interposed between the first light-transmitting substrate and the second light-transmitting substrate, a retardation film and stacked polarizing plates which are sequentially arranged on the outer side of the first light-transmitting substrate, and a retardation film and a polarizing plate which are sequentially arranged on the outer side of the second light-transmitting substrate, in which absorption axes of the stacked polarizing plates on each side are arranged to be in a parallel Nicols state.

An aspect of the present invention is a liquid crystal display device which includes a first light-transmitting substrate and a second light-transmitting substrate which are arranged to be opposite to each other, a display element which is interposed between the first light-transmitting substrate and the second light-transmitting substrate, a retardation film and stacked polarizing plates which are sequentially arranged on the outer side of the first light-transmitting substrate, and a retardation film and stacked polarizing plates which are sequentially arranged on the outer side of the second light-transmitting substrate, in which absorption axes of the stacked polarizing plates on each side are arranged to be in a parallel Nicols state, and the absorption axes of the polarizing plates provided on the outer side of the first light-transmitting substrate and the absorption axes of the polarizing plates provided on the outer side of the second light-transmitting substrate are arranged to be in a crossed Nicols state.

An aspect of the present invention is a liquid crystal display device which includes a first light-transmitting substrate and a second light-transmitting substrate which are arranged to be opposite to each other, a display element which is interposed between the first light-transmitting substrate and the second light-transmitting substrate, a color filter which is provided on the inner side of the first light-transmitting substrate or the second light-transmitting substrate, a retardation film and stacked polarizing plates which are sequentially arranged on the outer side of the first light-transmitting substrate, and a retardation film and stacked polarizing plates which are sequentially arranged on the outer side of the second light-transmitting substrate, in which absorption axes of the stacked polarizing plates are arranged to be in a parallel Nicols state, and the absorption axes of the polarizing plates provided on the outer side of the first light-transmitting substrate and the absorption axes of the polarizing plates provided on the outer side of the second light-transmitting substrate are arranged to be in a crossed Nicols state.

In an aspect of the present invention, the stacked polarizing plates preferably include two polarizing plates.

In an aspect of the present invention, the retardation film is a film in which liquid crystals are hybrid-oriented, a film in which liquid crystals are twisted-oriented, a uniaxial retardation film, or a biaxial retardation film.

In a liquid crystal element of the present invention, the first light-transmitting substrate has a first electrode, the second light-transmitting substrate has a second electrode, and the display element is a liquid crystal element which performs white display when a voltage is applied between the first electrode and the second electrode and performs black display when voltage is not applied between the first electrode and the second electrode.

In a liquid crystal element of the present invention, the first light-transmitting substrate has a first electrode, the second light-transmitting substrate has a second electrode, and the display element is a liquid crystal element which performs white display when voltage is not applied between the first electrode and the second electrode and performs display in black when a voltage is applied between the first electrode and the second electrode.

An aspect of present invention relates to a reflective type liquid crystal display device which includes a first substrate, a second substrate opposing to the first substrate, a liquid crystal provided between the first substrate and the second substrate, a reflective material provided for one of the first substrate and the second substrate, a circularly polarizing plate having a retardation plate and a linear polarizing plate having a stacked structure provided the other one of the first substrate and the second substrate.

In an aspect of the present invention, all transmission axes included in the linear polarizing plate having a stacked structure are arranged to be in a parallel Nicols state.

In an aspect of the present invention, the retardation plate is either a uniaxial retardation film or a biaxial retardation film.

An aspect of a display device of the present invention is a structure which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, and stacked second linear polarizing plates which are arranged on the outer side of the second light-transmitting substrate.

An aspect of a display device of the present invention is a structure which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, and stacked second linear polarizing plates which are arranged on the outer side of the second light-transmitting substrate, in which all the stacked first linear polarizing plates are arranged to be in a parallel Nicols state, and all the stacked second linear polarizing plates are arranged to be in a parallel Nicols state.

An aspect of a display device of the present invention is a structure which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, and stacked second linear polarizing plates which are arranged on the outer side of the second light-transmitting substrate, in which all transmission axes included in the first linear polarizing plate having a stacked structure are arranged to be in a parallel Nicols state, all the stacked second linear polarizing plates are arranged to be in a parallel Nicols state, and the stacked first linear polarizing plates and the stacked second linear polarizing plates are arranged to be in a crossed Nicols state.

An aspect of a display device of the present invention is a structure which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, and stacked second linear polarizing plates which are arranged on the outer side of the second light-transmitting substrate, in which all the stacked first linear polarizing plates are arranged to be in a parallel Nicols state, and the stacked first linear polarizing plates the stacked second linear polarizing plates are arranged to be in a crossed Nicols state.

In a structure of the present invention, the stacked polarizing plates may have a structure in which the polarizing plates are provided to be in contact with each other.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, a first circularly polarizing plate having stacked first linear polarizing plates which are arranged on the outer side of the first light-transmitting substrate, and a second circularly polarizing plate having stacked second linear polarizing plates which are arranged on the outer side of the second light-transmitting substrate.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, a first circularly polarizing plate having stacked first linear polarizing plates which are arranged on the outer side of the first light-transmitting substrate, and a second circularly polarizing plate having stacked second linear polarizing plates which are arranged on the outer side of the second light-transmitting substrate, in which all the stacked first linear polarizing plates are arranged to be in a parallel Nicols state, all the stacked second linear polarizing plates are arranged to be in a parallel Nicols state, and the stacked first linear polarizing plates and the stacked second linear polarizing plates are arranged to be in a parallel Nicols state.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, stacked second linear polarizing plates which are arranged on the outer side of the second light-transmitting substrate, a first retardation plate provided between the first light-transmitting substrate and the stacked first linear polarizing plates, and a second retardation plate provided between the second light-transmitting substrate and the stacked second linear polarizing plate, in which all the stacked first linear polarizing plates are arranged to be in a parallel Nicols state, all the stacked second linear polarizing plates are arranged to be in a parallel Nicols state, the stacked first linear polarizing plates and the stacked second linear polarizing plates are arranged to be in a parallel Nicols state, a slow axis of the first retardation plate is arranged to be shifted by 45° from the transmission axis of the stacked first linear polarizing plates, and a slow axis of the second retardation plate is arranged to be shifted by 45° from the transmission axis of the stacked second linear polarizing plates.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, stacked second linear polarizing plates which are arranged on the outer side of the second light-transmitting substrate, a first retardation plate provided between the first light-transmitting substrate and the stacked first linear polarizing plates, and a second retardation plate provided between the second light-transmitting substrate and the stacked second linear polarizing plates, in which all the stacked first linear polarizing plates are arranged to be in a parallel Nicols state, the stacked first linear polarizing plates and the stacked second linear polarizing plates are arranged to be in a parallel Nicols state, a slow axis of the first retardation plate is arranged to be shifted by 45° from the transmission axis of the stacked first linear polarizing plates, and a slow axis of the second retardation plate is arranged to be shifted by 45° from the transmission axis of the stacked second linear polarizing plates.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, a first circularly polarizing plate having stacked first linear polarizing plates which are arranged on the outer side of the first light-transmitting substrate, a second circularly polarizing plate having stacked second linear polarizing plates which are arranged on the outer side of the second light-transmitting substrate, in which all the stacked first linear polarizing plates are arranged to be in a parallel Nicols state, all the stacked second linear polarizing plates are arranged to be in a parallel Nicols state, and the stacked first linear polarizing plats and the stacked second linear polarizing plates are arranged to be in a crossed Nicols state.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, stacked second linear polarizing plates which are arranged on the outer side of the second light-transmitting substrate, a first retardation plate provided between the first light-transmitting substrate and the stacked first linear polarizing plates, and a second retardation plate provided between the second light-transmitting substrate and the stacked second linear polarizing plates, in which all the stacked first linear polarizing plates are arranged to be in a parallel Nicols state, all the stacked second linear polarizing plates are arranged to be in a parallel Nicols state, the stacked first linear polarizing plates and the stacked second linear polarizing plates are arranged to be in a crossed Nicols state, a slow axis of the first retardation plate is arranged to be shifted by 45° from the transmission axis of the stacked first linear polarizing plates, a slow axis of the second retardation plate is arranged to be shifted by 45° from the transmission axis of the stacked second linear polarizing plates, and the transmission axis of the stacked second linear polarizing plates is arranged to be shifted by 90° from the transmission axis of the stacked first linear polarizing plates.

An aspect of the present invention is a display device which includes a first light-transmitting substrate and a second light-transmitting substrate which are arranged to be opposite to each other, a light emitting element which is provided between the substrates opposite to each other and can emit light to opposite sides of the first light-transmitting substrate and the second light-transmitting substrate, stacked first linear polarizing plates which are arranged on the outer side of the first light-transmitting substrate, stacked second linear polarizing plates which are arranged on the outer side of the second light-transmitting substrate, a first retardation plate provided between the first light-transmitting substrate and the stacked first linear polarizing plates, and a second retardation plate provided between the second light-transmitting substrate and the stacked second linear polarizing plates, in which all the stacked first linear polarizing plates are arranged to be in a parallel Nicols state, the stacked first linear polarizing plates and the stacked second linear polarizing plates are arranged to be in a crossed Nicols state, a slow axis of the first retardation plate is arranged to be shifted by 45° from the transmission axis of the stacked first linear polarizing plates, a slow axis of the second retardation plate is arranged to be shifted by 45° from the transmission axis of the stacked second linear polarizing plates, and the transmission axis of the stacked second linear polarizing plates is arranged to be shifted by 90° from the transmission axis of the first stacked linear polarizing plates.

An aspect of the present invention is a display device which includes a first substrate, a second substrate which is opposite to the first substrate, a light emitting element which is provided between the first substrate and the second substrate, a circularly polarizing plate which has a retardation plate and stacked linear polarizing plates and is arranged on one of the first substrate and the second substrate, in which light from the light emitting element is emitted from the one of the first substrate and the second substrate.

In an aspect of the present invention, all the stacked linear polarizing plates are arranged to be in a parallel Nicols state.

In an aspect of the present invention, the slow axis of the retardation plate is arranged to be shifted by 45° from the transmission axis of the stacked linear polarizing plates.

In an aspect of the present invention, the light emitting element includes an electroluminescent layer formed between a pair of electrodes. One of the pair of electrodes has a reflective property, and the other of the pair of electrodes may have light-transmitting property.

In the above aspect of the present invention, the retardation plate and the stacked linear polarizing plates are arranged on the outer side of the substrate on the electrode side having light-transmitting property.

A “crossed Nicols state” refers to the arrangement in which transmission axes of polarizing plates are shifted from each other by 90°. A “parallel Nicols state” refers to the arrangement in which transmission axes of the polarizing plates are shifted from each other by 0°. An absorption axis is provided to be orthogonal to the transmission axis of the polarizing plate, and a “parallel Nicols state” is also defined using the absorption axis in a similar manner.

In the present invention, a display element is a light emitting element. An element utilizing electroluminescence (an electroluminescent element), an element utilizing plasma, and an element utilizing field emission are given as the light emitting element. The electroluminescent element (also referred to as an “EL element” in this specification) can be divided into an organic EL element and an inorganic EL element depending on a material to be applied. A display device having such a light emitting element is also referred to as a light emitting device.

In the present invention, extinction coefficients of stacked polarizers may have the same wavelength distribution.

Note that the present invention can be applied to a passive matrix type display device in which a switching element is not formed, as well as an active matrix type display device using a switching element.

Since a simple structure such that a plurality of polarizers are provided, the contrast ratio of the display device can be increased.

Since absorption axes of a plurality of polarizers are stacked to be in a parallel Nicols state, black luminance can be reduced and the contrast ratio of the display device can be increased.

In accordance with the present invention, by using a retardation plate, a viewing angle can be improved and a display device with a wide viewing angle can be provided as well as the contrast ratio of the display device is increased.

### BRIEF DESCRIPTION OF THE DRAWINGS

FIGS. 1A and 1B show a display device according to an aspect of the present invention;

FIGS. 2A to 2C each show a structure of stacked polarizers according to an aspect of the present invention;

FIGS. 3A and 3B show a display device according to an aspect of the present invention;

FIG. 4 shows angular deviation between polarizers according to an aspect of the present invention;

FIGS. 5A and 5B show a display device according to an aspect of the present invention;

FIG. 6 is a cross sectional view of a display device according to an aspect of the present invention;

FIG. 7 is a cross sectional view of a display device according to an aspect of the present invention;

FIGS. 8A and 8B show a display device according to an aspect of the present invention;

FIG. 9 is a cross sectional view of a display device according to an aspect of the present invention;

FIG. 10 is a cross sectional view of a display device according to an aspect of the present invention;

FIGS. 11A and 11B show a display device according to an aspect of the present invention;

FIGS. 12A to 12C each show angular deviation of polarizers according to an aspect of the present invention;

FIGS. 13A to 13D show a lighting means included in a display device according to an aspect of the present invention;

FIGS. 14A and 14B show a display device according to an aspect of the present invention;

FIG. 15 is a cross sectional view of a display device according to an aspect of the present invention;

FIG. 16 is a cross sectional view of a display device according to an aspect of the present invention;

FIGS. 17A and 17B show a display device according to an aspect of the present invention;

FIG. 18 is a cross sectional view of a display device according to an aspect of the present invention;

FIG. 19 is a cross sectional view of a display device according to an aspect of the present invention;

FIGS. 20A to 20C are block diagrams showing a display device according to an aspect of the present invention;

FIG. 21 is a block diagram showing a display device according to an aspect of the present invention;

FIGS. 22A and 22B show a display device according to an aspect of the present invention;

FIG. 23 is a cross sectional view of a display device according to an aspect of the present invention;

FIG. 24 is a diagram showing a display device according to an aspect of the present invention;

FIGS. 25A to 25C each show angular deviation between polarizers according to an aspect of the present invention;

FIG. 26 is a cross sectional view of a display device according to an aspect of the present invention;

FIGS. 27A and 27B show a display device according to an aspect of the present invention;

FIG. 28 shows angular deviation between polarizers according to an aspect of the present invention;

FIG. 29 is a cross sectional view of a display device according to an aspect of the present invention;

FIGS. 30A and 30B show a display device according to an aspect of the present invention;

FIG. 31 is a cross sectional view of a display device according to an aspect of the present invention;

FIG. 32 is a block diagram showing a display device according to an aspect of the present invention;

FIG. 33 is a diagram showing a display device according to an aspect of the present invention;

FIGS. 34A to 34C each show angular deviation between polarizers according to an aspect of the present invention;

FIGS. 35A and 35B show a display device according to an aspect of the present invention;

FIGS. 36A and 36B show a display device according to an aspect of the present invention;

FIGS. 37A to 37C each show a pixel circuit included in a display device according to an aspect of the present invention;

FIG. 38 shows a display device according to an aspect of the present invention;

FIG. 39 shows a display device according to an aspect of the present invention;

FIGS. 40A to 40C each show angular deviation between polarizers according to an aspect of the present invention;

FIG. 41 shows a display device according to an aspect of the present invention;

FIG. 42 shows a display device according to an aspect of the present invention;

FIGS. 43A to 43C each show angular deviation between polarizers according to an aspect of the present invention;

FIGS. 44A and 44B show a mode of a liquid crystal element according to an aspect of the present invention;

FIGS. 45A and 45B show a mode of a liquid crystal element according to an aspect of the present invention;

FIGS. 46A and 46B show a mode of a liquid crystal element according to an aspect of the present invention;

FIGS. 47A and 47B show a mode of a liquid crystal element according to an aspect of the present invention;

FIG. 48 is a top view showing one pixel of a display device according to an aspect of the present invention;

FIGS. 49A and 49B show a mode of a liquid crystal element according to an aspect of the present invention;

FIGS. 50A and 50B show a mode of a liquid crystal element according to an aspect of the present invention;

FIGS. 51A to 51D each show an electrode which drives liquid crystal molecules of a display device according to an aspect of the present invention;

FIG. 52 is a top view showing one pixel of a display device according to an aspect of the present invention;

FIGS. 53A and 53B show a mode of a liquid crystal element according to an aspect of the present invention;

FIG. 54 is a top view showing one pixel of a display device according to an aspect of the present invention;

FIGS. 55A and 55B show a mode of a liquid crystal element according to an aspect of the present invention;

FIGS. 56A and 56B show a mode of a liquid crystal element according to an aspect of the present invention;

FIGS. 57A to 57D each show an electrode which drives liquid crystal molecules of a display device according to an aspect of the present invention;

FIG. 58 shows a 2D/3D switchable liquid crystal display panel having a display device according to an aspect of the present invention;

FIGS. 59A and 59B each show a structure of stacked polarizers according to an aspect of the present invention;

FIGS. 60A to 60C each show a structure of stacked polarizers according to an aspect of the present invention;

FIGS. 61A and 61B each show a structure of stacked polarizers according to an aspect of the present invention;

FIGS. 62A and 62B each show a structure of stacked polarizers according to an aspect of the present invention;

FIGS. 63A and 63B each show a structure of stacked polarizers according to an aspect of the present invention;

FIG. 64 shows a structure of stacked polarizers according to an aspect of the present invention;

FIGS. 65A to 65F each show an electronic device having a display device according to an aspect of the present invention;

FIG. 66 shows an electronic device having a display device according to an aspect of the present invention;

FIG. 67 shows an electronic device having a display device according to an aspect of the present invention;

FIG. 68 shows an electronic device having a display device according to an aspect of the present invention;

FIG. 69 shows a structure of a panel according to an aspect of the present invention;

FIG. 70 is a graph showing change in reflectance of a structure of the present invention, which is obtained by calculation;

FIG. 71 is a graph showing change in reflectance of a structure of the present invention, which is obtained by calculation;

FIG. 72 is a graph showing change in contrast ratio of a structure of the present invention, which is obtained by calculation;

FIG. 73 shows a structure of a panel according to an aspect of the present invention;

FIG. 74 is a graph showing change in reflectance of a structure of the present invention, which is obtained by an experiment;

FIG. 75 is a graph showing change in reflectance of a structure of the present invention, which is obtained by an experiment;

FIG. 76 is a graph showing change in contrast ratio of a structure of the present invention, which is obtained by an experiment;

FIG. 77 shows a structure of a panel according to an aspect of the present invention;

FIG. 78 is a graph showing change in transmittance of a structure of the present invention, which is obtained by calculation;

FIG. 79 is a graph showing change in transmittance of a structure of the present invention, which is obtained by calculation;

FIG. 80 is a graph showing change in contrast ratio of a structure of the present invention, which is obtained by calculation;

### BEST MODE FOR CARRYING OUT THE INVENTION

### Embodiment Mode

Hereinafter, Embodiment Modes will be described with reference to the drawings. The present invention can be carried out in many different modes. It is easily understood by those skilled in the art that modes and details disclosed herein can be modified in various ways without departing from the spirit and the scope of the present invention. It should be noted that the present invention should not be interpreted as being limited to the description of the embodiment modes given below. Note that like portions or portions having a like function are denoted by the same reference numerals through drawings, and therefore, description thereon is omitted.

### Embodiment Mode 1

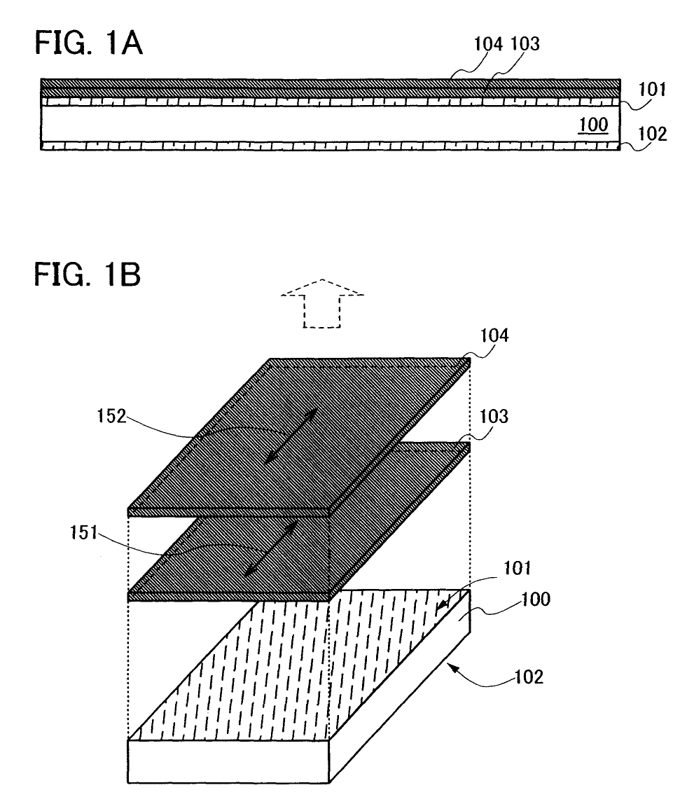

Embodiment Mode 1 will describe a conception of a display device of the present invention with reference to FIGS. 1A and 1B.

FIG. 1A is a cross-sectional view of a display device in which polarizers are stacked, and FIG. 1B is a perspective view thereof.

As shown in FIG. 1A, a display element 100 is interposed between a first substrate 101 and a second substrate 102 which are arranged to be opposite to each other.

Light-transmitting substrates can be used for the first substrate 101 and the second substrate 102. As such light-transmitting substrates, a glass substrate such as alumino borosilicate glass, barium borosilicate glass, a quartz substrate, or the like can be used. A substrate made from acrylic or plastic typified by polyethylene terephthalate (PET), polyethylene naphthalate (PEN), or polyethersulfone (PES) can be used for the light-transmitting substrates.

Polarizers are stacked on the outer side of the substrate 101, in other words, on the side which is not in contact with the display element 100. A first polarizer 103 and a second polarizer 104 are provided on the outer side of the substrate 101 side.

Next, in the perspective view of FIG. 1B, the first polarizer 103 and the second polarizer 104 are arranged in such a way that an absorption axis 151 of the first polarizer 103 and an absorption axis 152 of the second polarizer 104 should be parallel to each other. This parallel state is referred to as parallel Nicols.

The polarizers stacked in this manner are arranged to be in a parallel Nicols state.

Note that transmission axes exist in a direction orthogonal to the absorption axes based on the characteristics of the polarizers. Thus, a state in which transmission axes are parallel to each other can also be referred to as a parallel Nicols state.

In this specification, although absorption axes of polarizers are preferably arranged such that angular deviation of the absorption axes is 0°, at least in the range of −10° to 10° in a parallel Nicols state, the angular deviation thereof may be changed from the angle to some extent as long as a similar effect can be obtained. Absorption axes of polarizers are preferably arranged such that angular deviation of the absorption axes is 90°, at least in the range of 80° to 100° in a crossed Nicols state; however, the angular deviation thereof may be changed from the angle to some extent as long as a similar effect can be obtained, although it is assumed that the above angle range is satisfied.

Moreover, preferably, extinction coefficient of the first polarizer 103 and the second polarizer 104 may have the same wavelength distribution. In this specification, the range of the extinction coefficient of the absorption axes in polarizers is 3.0E-4 to 3.0E-2.

FIGS. 1A and 1B show an example in which two polarizers are stacked; however three or more polarizers may be stacked.

By stacking polarizers in such a way that absorption axes of the stacked polarizers to be in parallel Nicols, black luminance can be reduced, and thus, the contrast ratio of the display device can be increased.

In addition, this embodiment mode can be freely combined with any of other embodiment modes and other examples in this specification, if necessary.

### Embodiment Mode 2

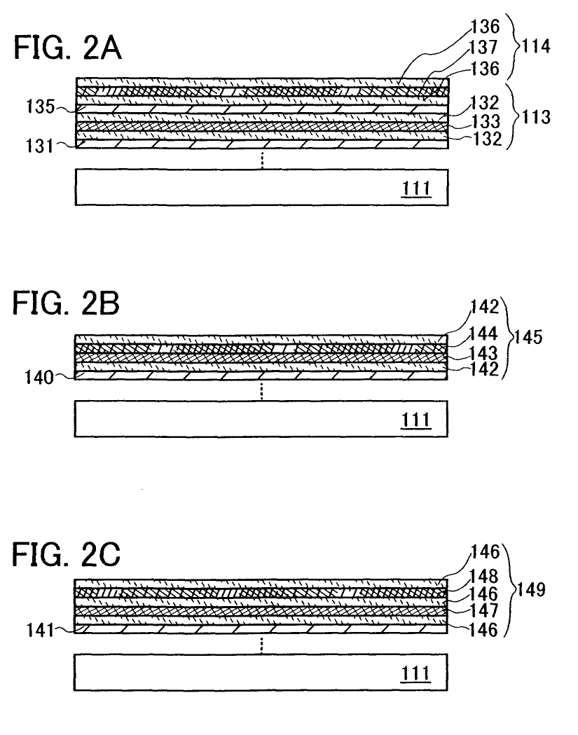

Embodiment Mode 2 will describe a structure in which polarizers are stacked with reference to FIGS. 2A to 2C.

FIG. 2A shows an example in which polarizing plates having one polarizing film are stacked as the stacked polarizers.

In FIG. 2A, each of the polarizing plates 113 and 114 is a linear polarizing plate, and can be formed from a known material with the following structure. For example, an adhesive layer 131, the polarizing plate 113 in which a protective film 132, a polarizing film 133, and another protective film 132 are sequentially stacked, an adhesive layer 135, and the polarizing plate 114 in which a protective film 136, a polarizing film 137, and another protective film 136 are stacked similarly to the polarizing plate 113, can be stacked from the substrate 111 side (FIG. 2A). As the protective films 132 and 136, TAC (triacetylcellulose) or the like can be used. As the polarizing films 133 and 137, a mixed layer including PVA (polyvinyl alcohol) and a dichromatic pigment is formed. As the dichromatic pigment, iodine and dichromatic organic dye can be cited. Further, the polarizing plate can also be called a polarizing film based on the shape in some cases.

FIG. 2B shows a case in which a plurality of polarizing films are stacked in one polarizing plate as one example of the stacked polarizers. FIG. 2B shows a state in which an adhesive layer 140, and a polarizing plate 145 including a protective film 142, a polarizing film (A) 143, a polarizing film (B) 144, and another protective film 142 are stacked from the substrate 111 side.

FIG. 2C shows another example in which a plurality of polarizing films are stacked in one polarizing plate. FIG. 2C shows a case in which an adhesive layer 141, and a polarizing plate 149 including a protective film 146, a polarizing film (A) 147, another protective film 146, a polarizing film (B) 148, and another protective film 146 are stacked from the substrate 111 side. In other words, the structure shown in FIG. 2C is a structure in which the protective film is interposed between the polarizing films.

For the protective films 142 and 146, a similar material to the protective film 132 may be used, and each of the polarizing film (A) 143, the protective film (B) 144, the polarizing film (A) 147, and the protective film (B) 148 may be formed from a similar material to the polarizing films 133 and 137.

In FIGS. 2A to 2C, two polarizers are stacked; however, it is natural that the number of polarizers is not limited to two. When three or more polarizers are stacked, three or more polarizing plates may be stacked if the structure shown in FIG. 2A is employed. If the structure shown in FIG. 2B is employed, the number of polarizing film provided between the protective films 142 may be increased. If the structure shown in FIG. 2C is employed, a polarizing film and a protective film to be formed thereover may be stacked in such a way as stacking the protective film 146, the polarizing film (A) 147, the protective film 146, the polarizing film (B) 148, the protective film 146, the polarizing film (C), the protective film 146, and the like.

Further, the stacked structures shown in FIGS. 2A to 2C may be combined. In other words, three polarizers may be stacked, by combining the polarizing plate 113 including the polarizing film 133 shown in FIG. 2A and the polarizing plate 145 including the polarizing film 143 and the polarizing film 144 shown in FIG. 2B, for example. The structure of the stacked polarizers like this may be freely combined with the structures shown in FIGS. 2A to 2C, as appropriate.

Furthermore, a plurality of polarizing plates 145 shown in FIG. 2B may be stacked so as to stack polarizers. Similarly, a plurality of polarizing plates 149 shown in FIG. 2C may be stacked.

The case where polarizers are arranged in parallel Nicols indicates that, in FIG. 2A, the absorption axes of the polarizing plates 113 and 114 are parallel, in other words, the absorption axes of the polarizing films 133 and 137 are parallel; that, in FIG. 2B, absorption axes of the polarizing films 143 and 144 are arranged to be parallel; and that in FIG. 2C, absorption axes of the polarizing films 147 and 148 are arranged to be parallel. Even when the number of polarizing films and polarizing plates increases, absorption axes of them are arranged to be parallel.

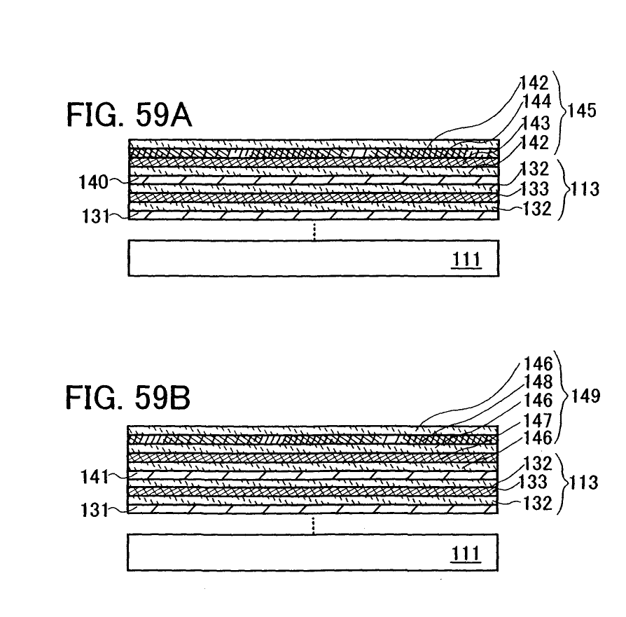

FIGS. 2A to 2C show the examples in which two polarizers are stacked. Further, FIGS. 59A and 59B show examples in which three polarizers are stacked.

FIG. 59A shows an example in which the polarizing plate 113 including the polarizing film 133 shown in FIG. 2A, and the polarizing plate 145 including the polarizing film 143 and the polarizing film 144 shown in FIG. 2B are stacked. Note that the stacking order of the polarizing plate 113 and the polarizing plate 145 may be reverse.

FIG. 59B shows an example in which the polarizing plate 113 including the polarizing film 133 shown in FIG. 2A, and the polarizing plate 149 including the polarizing film 147 and the polarizing film 148 shown in FIG. 2C are stacked. Note that the stacking order of the polarizing plate 113 and the polarizing plate 149 may be reverse.

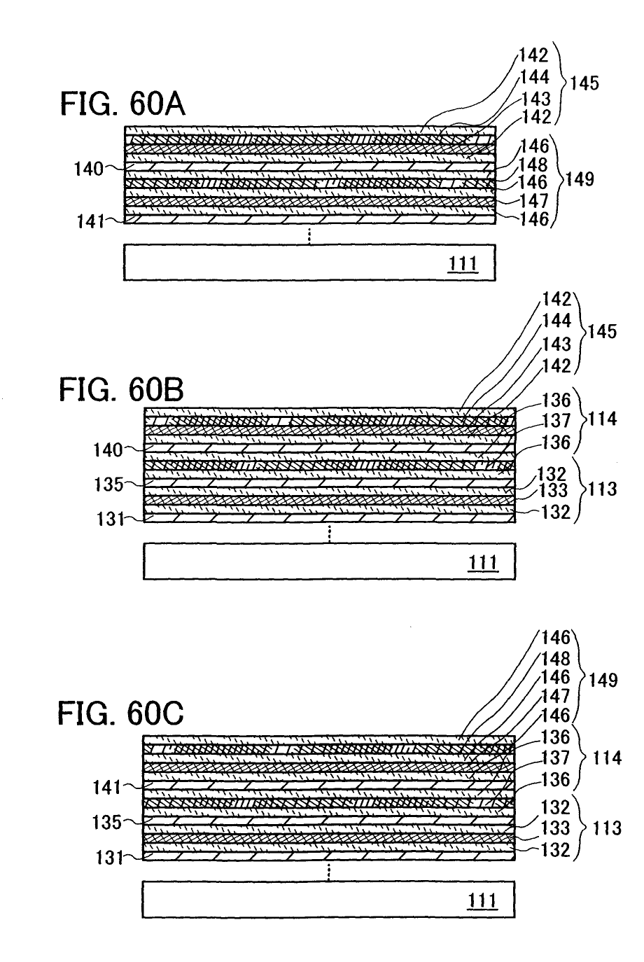

FIGS. 60A to 60C, FIGS. 61A to 61C, and FIGS. 62A to 62C show examples in which four polarizers are stacked.

FIG. 60A shows an example in which the polarizing plate 149 including the polarizing film 147 and the polarizing film 148 shown in FIG. 2C and the polarizing plate 145 including the polarizing film 143 and the polarizing film 144 shown in FIG. 2B are stacked. Note that the stacking order of the polarizing plate 145 and the polarizing plate 149 may be reverse.

FIG. 60B shows an example in which the polarizing plate 113 including the polarizing film 133 and the polarizing plate 114 including the polarizing film 137 shown in FIG. 2A, and the polarizing plate 145 including the polarizing film 143 and the polarizing film 144 shown in FIG. 2B are stacked. Note that the stacking order of the polarizing plates 113, 114 and 145 is not limited to this example.

FIG. 60C shows an example in which the polarizing plate 113 including the polarizing film 133 and the polarizing plate 114 including the polarizing film 137 shown in FIG. 2A, and the polarizing plate 149 including the polarizing film 147 and the polarizing film 148 shown in FIG. 2C are stacked. Note that the stacking order of the polarizing plates 113, 114 and 149 is not limited to this example.

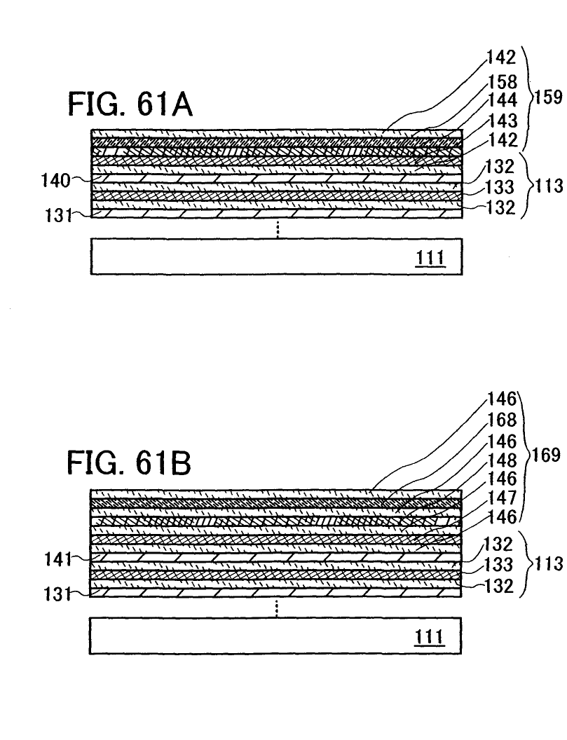

FIG. 61A shows an example in which the polarizing plate 113 including the polarizing film 133 shown in FIG. 2A, and a polarizing plate 159 including three stacked polarizing films shown in FIG. 2B, i.e., the polarizing film 143, the polarizing film 144 and the polarizing film 158, are stacked. Note that the stacking order of the polarizing plate 113 and the polarizing plate 159 may be reverse.

FIG. 61B shows an example in which the polarizing plate 113 including the polarizing film 133 shown in FIG. 2A, and a polarizing plate 169 including three stacked polarizing films shown in FIG. 2C, i.e., the polarizing film 147, the polarizing film 148 and the polarizing film 168, are stacked. Note that the stacking order of the polarizing plate 113 and the polarizing plate 169 may be reverse.

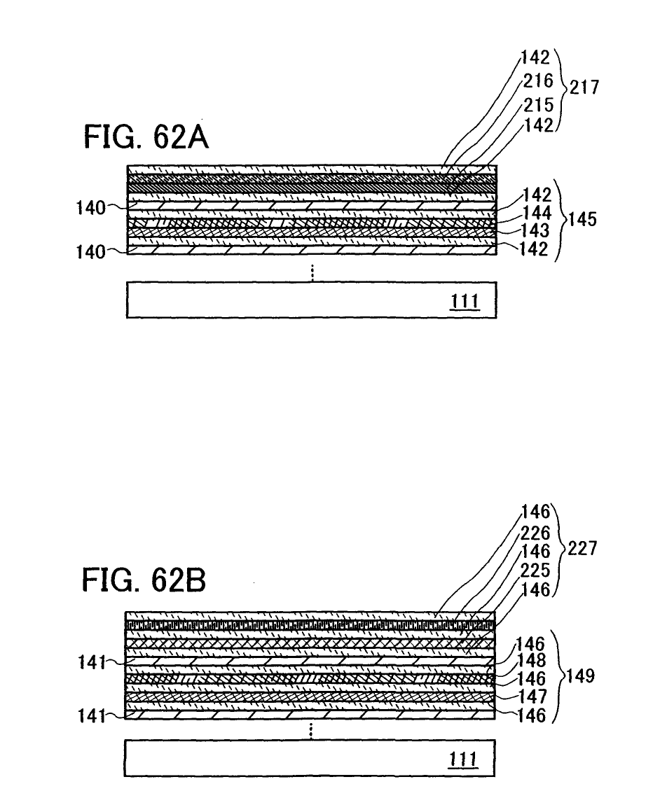

FIG. 62A shows an example in which the polarizing plate 145 including the polarizing film 143 and the polarizing film 144 shown in FIG. 2B, and the polarizing plate 217 including the polarizing film 215 and the polarizing film 216 shown in FIG. 2B are stacked.

FIG. 62B shows an example in which the polarizing plate 149 including the polarizing film 147 and the polarizing film 148 shown in FIG. 2C, and the polarizing plate 227 including the polarizing film 225 and the polarizing film 226 shown in FIG. 2C are stacked.

In FIGS. 59A and 59B, 60A to 60C, 61A and 61B, and 62A and 62B, a retardation plate may be provided between the substrate 111 and the polarizers if necessary.

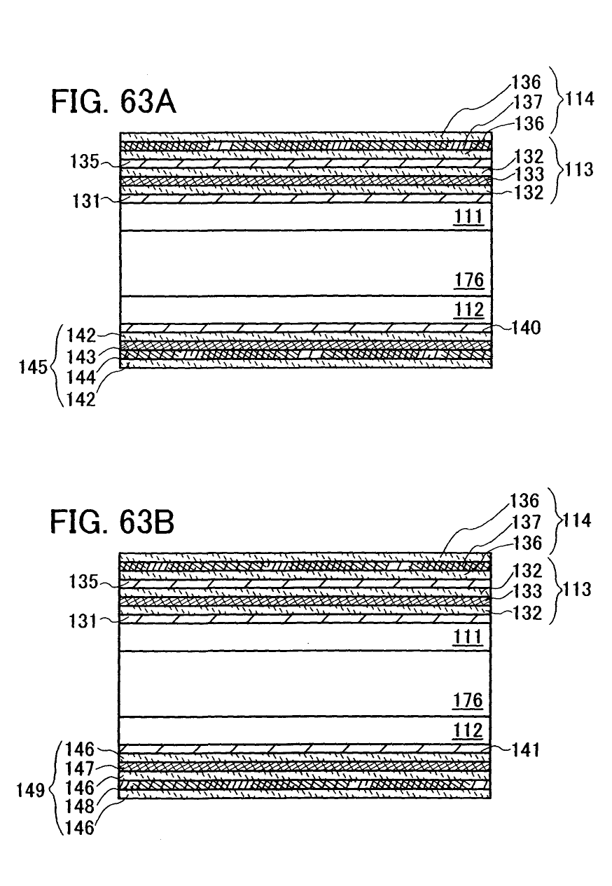

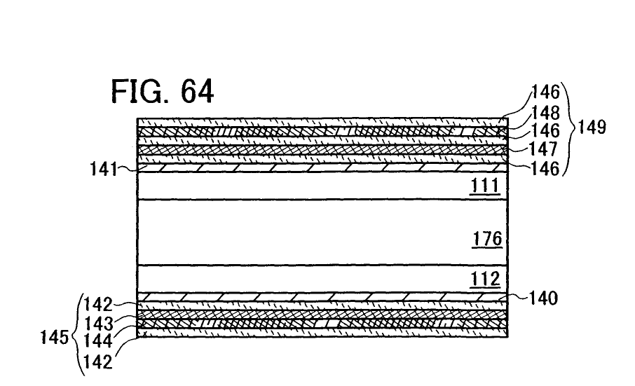

In examples shown in FIGS. 63A and 63B, and FIG. 64, a layer 176 including a display element is interposed between the substrate 111 and a substrate 112, and stacked polarizers have different structures above and below the layer 176 including the display element. Note that a retardation plate is not shown for simplification; however, a retardation plate may be provided between the substrate and the polarizers if necessary.

In FIGS. 63A and 63B and FIG. 64, the number of polarizers which are provided between the substrate 111 and the substrate 112 is two; however, needless to say, three or more polarizers may be provided. In the case of three or more polarizers, the structures shown in FIGS. 59A and 59B, 60A to 60C, 61A and 61B, and 62A and 62B may be employed.

In FIG. 63A, on the substrate 111 side, the polarizing plate 113 including the polarizing film 133 and the polarizing plate 114 including the polarizing film 137 shown in FIG. 2A are stacked. On the substrate 112 side, the polarizing plate 145 including the polarizing film 143 and the polarizing film 144 shown in FIG. 2B is provided. Note that the stacking order of the polarizing plates 113 and 114 and the polarizing plate 145 may be reverse, when top and bottom sides of the display device are considered.

In FIG. 63B, on the substrate 111 side, the polarizing plate 113 including the polarizing film 133 and the polarizing plate 114 including the polarizing film 137 shown in FIG. 2A are stacked. On the substrate 112 side, the polarizing plate 149 including the polarizing film 147 and the polarizing film 148 shown in FIG. 2C is provided. Note that the stacking order of the polarizing plates 113 and 114 and the polarizing plate 149 may be reverse, when top and bottom sides of the display device are considered.

In FIG. 64, on the substrate 111 side, the polarizing plate 149 including the polarizing film 147 and the polarizing film 148 shown in FIG. 2C is provided. On the substrate 112 side, the polarizing plate 145 including the polarizing film 143 and the polarizing film 144 is provided. Note that the stacking order of the polarizing plate 145 and the polarizing plate 149 may be reverse, when the top and bottom sides of the display device are considered.

Needless to say, this embodiment mode can be applied to Embodiment Mode 1, and further, this embodiment mode can be applied to other embodiment modes and examples in this specification.

### Embodiment Mode 3

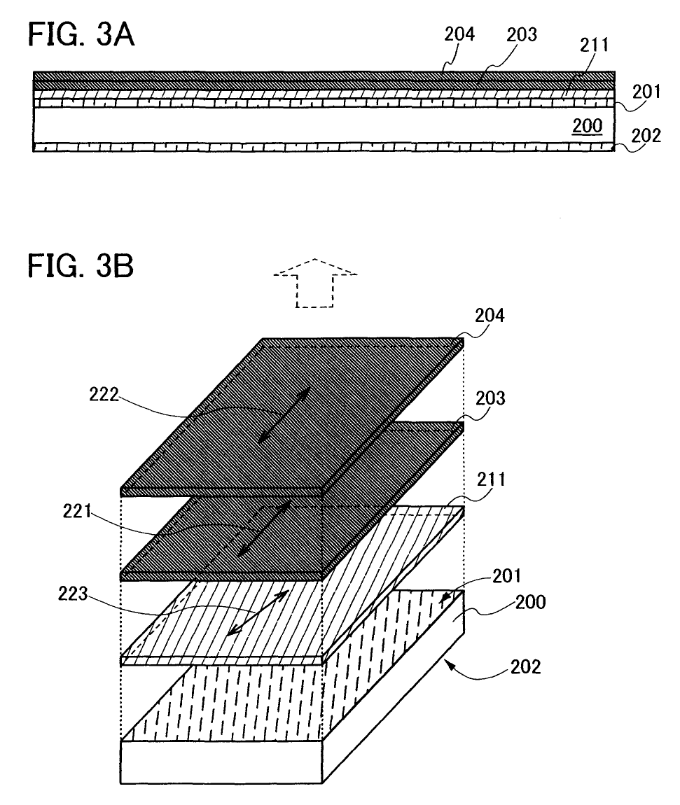

Embodiment Mode 3 will describe a concept of a display device of the present invention with reference to FIGS. 3A and 3B.

FIG. 3A is a cross sectional view of a display device in which a retardation plate and stacked polarizers are provided, and FIG. 3B is a perspective view of the display device.

As shown in FIG. 3A, a display element 200 is interposed between a first substrate 201 and a second substrate 202 which are opposite to each other.

Light-transmitting substrates can be used for the first substrate 201 and the second substrate 202. As such light-transmitting substrates, a similar material to the material of the substrate 101 described in Embodiment Mode 1 may be used.

On the outer side of the first substrate 201 and the second substrate 202, i.e., on the side which is not in contact with the display element 200 from the first substrate 201, a retardation plate 211, and polarizers 203 and 204 which are stacked are provided. Light is circularly polarized by the retardation plate (also referred to as a retardation film, a wave plate or a wavelength plate), and linearly polarized by the polarizers. In other words, the stacked polarizers can be referred to as stacked linear polarizers. The stacked polarizers indicate stacked two or more polarizers. Embodiment Mode 2 can be applied to the stacked structure of the polarizers like this.

FIGS. 3A and 3B show examples where two polarizers are stacked; however, three or more polarizers may be stacked.

In addition, extinction coefficients of the first polarizer 203 and the second polarizer 204 preferably have the same wavelength distribution.

On the outer side of the first substrate 201, a retardation plate 211, the first polarizer 203, and the second polarizer 204 are provided sequentially. In this embodiment mode, a quarter-wave plate is used as the retardation plate 211.

In this specification, such combination of the retardation plate and the stacked polarizers is also referred to as a circuit polarizer plate having the stacked polarizers (linear polarizers).

The first polarizer 203 and the second polarizer 204 are arranged in such a way that an absorption axis 221 of the first polarizer 203 and an absorption axis 222 of the second polarizer 204 should be parallel. In other words, the first polarizer 203 and the second polarizer 204, i.e., the stacked polarizers are arranged to be in a parallel Nicols state.

A slow axis 223 of the retardation plate 211 is arranged with angular deviation of 45° from the absorption axis 221 of the first polarizer 203 and the absorption axis 222 of the second polarizer 204.

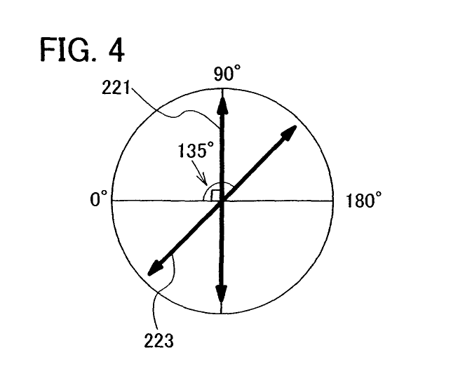

FIG. 4 shows angular deviation between the absorption axis 221 and the slow axis 223. The angle formed by the slow axis 223 and the transmission axis is 135°, and the angle formed by the absorption axis 221 and the transmission axis is 90°, and thus, the difference of the slow axis 223 and the absorption axis 221 is 45°.

The retardation plate has a fast axis in the orthogonal direction to the slow axis according to the characteristics of the retardation plate. Thus, the arrangement of the retardation plate and a polarizing plate can be determined with the use of not only the slow axis but also the fast axis. In this embodiment mode, the arrangement is done such that the angular deviation between the absorption axis and the slow axis should be 45°, in other words, the arrangement is done such that the angular deviation between the absorption axis and the fast axis should be 135°.

In this specification, it is assumed that the above angular condition is satisfied when angular deviation between an absorption axis and a slow axis, angular deviation of absorption axes, or angular deviation of slow axes is mentioned; however, the angular deviation between the axes may differ from the above-described angles to some extent as long as a similar effect can be obtained.

The retardation plate 211 may be, for example, a film in which liquid crystals are hybrid-oriented, a film in which liquid crystals are twisted-oriented, a uniaxial retardation film, or a biaxial retardation film. Such retardation plates can suppress reflection to the display device and widen the viewing angle. The film in which liquid crystals are hybrid-oriented is a complex film obtained by using a triacetylcellulose (TAC) film as a base and hybrid-orienting negative uniaxial discotic liquid crystals to have optical anisotropy.

A uniaxial retardation film is formed by stretching a resin in one direction. Further, a biaxial retardation plate is formed by stretching a resin into an axis in a crosswise direction, and then gently stretching the resin into an axis in a lengthwise direction. As the resin used here, cyclo-olefin polymer (COP), polycarbonate (PC), polymethyl methacrylate (PMMA), polystyrene (PS), polyether sulfone (PES), polyphenylene sulfide (PPS), polyethylene terephthalate (PET), polyethylene naphthalate (PEN), polypropylene (PP), polyphenylene oxide (PPO), polyarylate (PAR), polyimide (PI), polytetrafluoroethylene (PTFE), or the like is given.

Note that the film in which liquid crystals are hybrid-oriented may a film obtained by using a triacetylcellulose (TAC) film as a base and hybrid-orienting discotic liquid crystals or nematic liquid crystals. The retardation plate can be attached to the substrate with the retardation plate attached to the polarizing plate.

By stacking polarizing plates to be in parallel Nicols, reflected light of external light can be reduced compared to a case of a single polarizing plate. Therefore, black luminance can be reduced, and thus, the contrast ratio of the display device can be increased.

Moreover, in this embodiment mode, since a quarter-wave plate is used as the retardation plate, reflection can be suppressed.

In addition, this embodiment mode can be freely combined with any of other embodiment modes and other examples in this specification, if necessary.

### Embodiment Mode 4

Embodiment Mode 4 will describe a concept of a display device of the present invention.

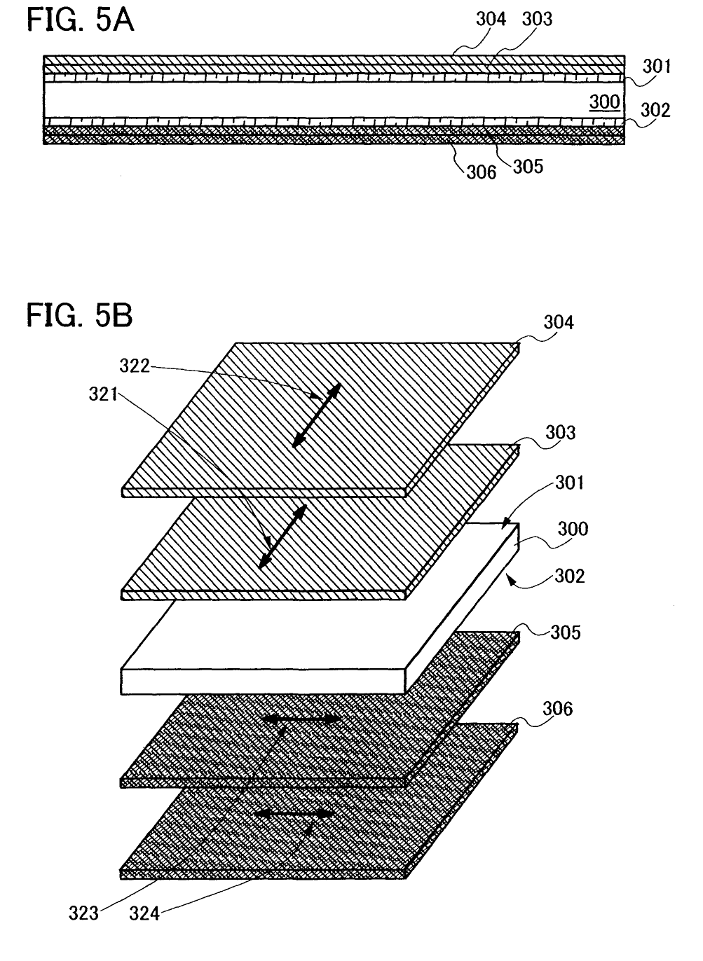

FIG. 5A is a cross sectional view of a display device provided with a polarizer having a stacked structure, and FIG. 5B is a perspective view of the display device. This embodiment mode describes a liquid crystal display device using a liquid crystal element as a display element as one example.

As shown in FIG. 5A, a layer 300 including a liquid crystal element is interposed between a first substrate 301 and a second substrate 302 which are opposite to each other. For the substrates 301 and 302, insulating substrates having a light-transmitting property (also, referred to as light-transmitting substrates) are used. For example, a glass substrate such as barium borosilicate glass or alumino borosilicate glass, a quartz substrate, or the like can be used. A substrate made from a synthetic resin such as acrylic or plastic typified by polyethylene terephthalate (PET), polyethylene naphthalate (PEN), or polyethersulfone (PES) can be used for the light-transmitting substrates.

Polarizers are stacked on the outer side of each of the substrates 301 and 302, in other words, on the side which is not in contact with the layer 300 including the liquid crystal element from the substrate 301 and 302. Note that in this embodiment mode, as the structure of the stacked polarizers, polarizing plates each including one polarizing film shown in FIG. 2A are stacked. Needless to say, the structures shown in FIGS. 2B and 2C may be used.

On the first substrate 301 side, a first polarizing plate 303 and a second polarizing plate 304 are provided, and on the second substrate 302 side, a third polarizing plate 305 and a fourth polarizing plate 306 are provided.

These polarizing plates 303 to 306 can be formed using known materials, and can have a structure in which an adhesive face, TAC (triacetylcellulose), a mixed layer of PVA (polyvinyl alcohol) and a dichroic pigment, and TAC are sequentially stacked from the substrate side. The dichroic pigment includes iodine and dichroic organic dye. In addition, the polarizing plate can also be called a polarizing film based on the shape in some cases.

Further, extinction coefficients of the first to fourth polarizing plates 303 to 306 preferably have the same wavelength distribution.

FIGS. 5A and 5B show the example in which two polarizing plates are stacked for one substrate; however, three or more polarizing plates may be stacked.

As shown in FIG. 5B, the first polarizing plate 303 and the second polarizing plate 304 are stacked in such a way that an absorption axis 321 of the first polarizing plate 303 and an absorption axis 322 of the second polarizing plate 304 should be parallel. This parallel state is referred to as parallel Nicols. Similarly, the third polarizing plate 305 and the fourth polarizing plate 306 are arranged in such a way that an absorption axis 323 of the third polarizing plate 305 and an absorption axis 324 of the fourth polarizing plate 306 should be parallel, in other words, to be in parallel Nicols. The stacked polarizing plates 304, 304 and the stacked polarizing plates 305,306 are arranged such that the absorption axes thereof are orthogonal to each other as shown in FIG. 5B. The orthogonal state is called crossed Nicols.

A transmission axis exists in the direction orthogonal to the absorption axis according to the characteristics of the polarizing plates. Thus, the case where transmission axes are parallel to each other can also be referred to as parallel Nicols. In addition, the case where transmission axes are orthogonal to each other can also be referred to as crossed Nicols.

The polarizing plates are stacked to be in a parallel Nicols state, thereby reducing light leakage in the direction of the absorption axes. Further, by arranging pairs of the stacked polarizing plates in a crossed Nicols state, light leakage can be reduced compared to the case where a pair of a single polarizing plate is arranged in crossed Nicols. Therefore, the contrast ratio of the display device can be increased.

In addition, this embodiment mode can be freely combined with any of other embodiment modes and other examples in this specification, if necessary.

### Embodiment Mode 5

Embodiment Mode 5 will describe a specific structure of the liquid crystal display device described in Embodiment Mode 4.

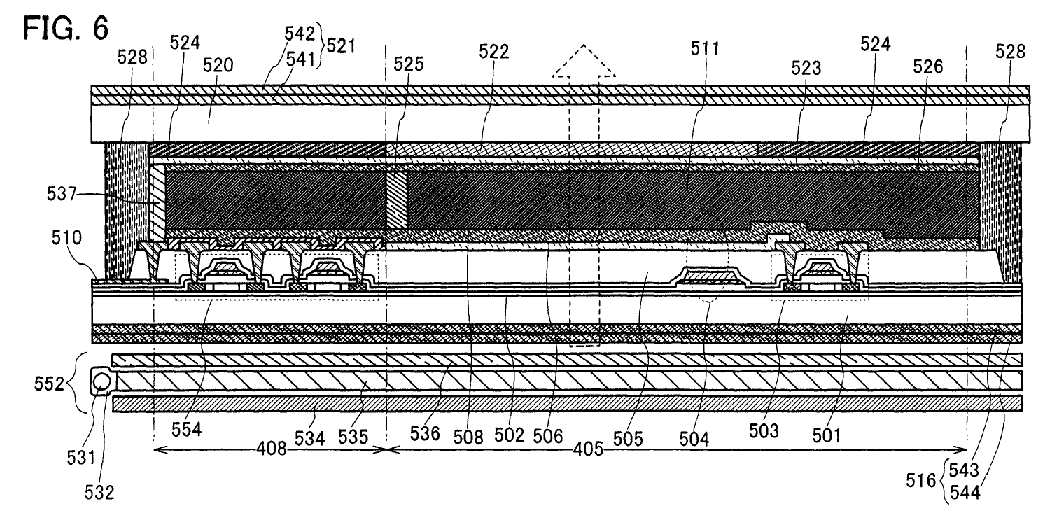

FIG. 6 shows a cross sectional view of a liquid crystal display device provided with a polarizing plate having a stacked structure.

The liquid crystal display device shown in FIG. 6 includes a pixel portion 405 and a driver circuit portion 408. In the pixel portion 405 and the driver circuit portion 408, a base film 502 is provided over a substrate 501. An insulating substrate similar to those shown in Embodiment Mode 1 to Embodiment Mode 4 can be used for the substrate 501. It is concerned that a substrate formed from a synthetic resin generally has a lower allowable temperature limit than other substrates. However, a substrate with high heat resistance is adopted in a manufacturing process first and the substrate is replaced by a substrate formed from a synthetic resin, thereby making it possible to employ such a substrate formed from a synthetic resin.

The pixel portion 405 is provided with a transistor as a switching element through the base film 502. In this embodiment mode, a thin film transistor (TFT) is used as the transistor, which is referred to as a switching TFT 503.

There are many methods for forming a TFT. For example, a crystalline semiconductor film is used as an active layer. A gate electrode is provided over the crystalline semiconductor film with a gate insulating film interposed therebetween. An impurity element can be added to the active layer by using the gate electrode as a mask. Since an impurity element is added using the gate electrode as the mask in this manner, a mask used for adding the impurity element is not required to be additionally formed. The gate electrode may have a single layer structure or a stacked structure. An impurity region can be formed as a high concentration impurity region or a low concentration impurity region by controlling the concentration thereof. A structure of such a TFT having a low concentration impurity region is referred to as an LDD (Lightly Doped Drain) structure. Further, the low concentration impurity region can be formed so as to overlap with the gate electrode. A structure of such a TFT is referred to as a GOLD (Gate Overlapped LDD) structure.

Note that the TFT may be a top gate type TFT or a bottom gate type TFT, and may be formed if necessary.

FIG. 6 shows the switching TFT 503 having a GOLD structure. The polarity of the switching TFT 503 is an n-type by using phosphorus (P) or the like for an impurity region thereof. In the case of forming a p-type TFT, boron (B) or the like may be added. After that, a protective film which covers the gate electrode and the like is formed. A dangling bond in the crystalline semiconductor film can be terminated by hydrogen elements mixed in the protective film.

Further, in order to improve planarity more, an interlayer insulating film 505 may be formed. The interlayer insulating film 505 may be formed from an organic material or an inorganic material, or formed with a stacked structure of these. Opening portions are formed in the interlayer insulating film 505, the protective film, and the gate insulating film; and wiring connected to the impurity regions is formed. In this manner, the switching TFT 503 can be formed. Note that the present invention is not limited to the structure of the switching TFT 503.

Then, a pixel electrode 506 connected to the wiring is formed.

Further, a capacitor element 504 can be formed at the same time as the switching TFT 503. In this embodiment mode, the capacitor element 504 is formed from a stack of a conductive film formed at the same time as the gate electrode, the protective film, the interlayer insulating film 505, and the pixel electrode 506.

In addition, the pixel portion 405 and the driver circuit portion 408 can be formed over the same substrate by using a crystalline semiconductor film. In that case, transistors in the pixel portion and transistors of the driver circuit portion 408 are formed at the same time. The transistors used for the driver circuit portion 408 form a CMOS circuit; and thus, the transistors are referred to as a CMOS circuit 554. Each of the transistors which form the CMOS circuit 554 can have a similar structure to the switching TFT 503. Further, the LDD structure can be used instead of the GOLD structure, and a similar structure is not necessarily required.

An alignment film 508 is formed so as to cover the pixel electrode 506. The alignment film 508 is subjected to rubbing treatment. This rubbing treatment is not performed in some cases in a mode of a liquid crystal, for example, in a case of a VA mode.

Next, a counter substrate 520 is provided. A color filter 522 and a black matrix (BM) 524 can be provided on an inner side of the counter substrate 520, that is, on the side which is in contact with the liquid crystal. These can be formed by known methods; however, a droplet discharging method (representatively an ink-jetting method) by which a predetermined material is dropped can eliminate the waste of the material. Further, the color filter and the like are provided in a region where the switching TFT 503 is not provided. That is to say, the color filter is provided to face a light-transmitting region, i.e., an opening region. Note that the color filter and the like may be formed from materials which exhibit red (R), green (G), and blue (B) in the case where the liquid crystal display device performs full-color display, or it may be formed from a material which exhibits at least one color in the case of mono-color display.

Note that the color filter is not provided in some cases where light-emitting diodes (LEDs) of RGB and the like are arranged in a backlight and a successive additive color mixing method (field sequential method) in which color display is performed by time division is employed.

The black matrix 524 is provided to reduce reflection of external light due to wirings of the switching TFT 503 and the CMOS circuit 554. Therefore, the black matrix 524 is provided so as to overlap with the switching TFT 503 or the CMOS circuit 554. Note that the black matrix 524 may be provided so as to overlap with the capacitor element 504. Accordingly, reflection on a metal film constituting a part of the capacitor element 504 can be prevented.

Then, a counter electrode 523 and an alignment film 526 are provided. The alignment film 526 is subjected to a rubbing treatment.

Note that the wiring included in the TFT, the gate electrode, the pixel electrode 506, and the counter electrode 523 can be formed from materials selected from indium tin oxide (ITO), indium zinc oxide (IZO) in which zinc oxide (ZnO) is mixed in indium oxide, a conductive material in which silicon oxide (SiO₂) is mixed in indium oxide, organic indium, organotin, a metal such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), or copper (Cu), an alloy thereof, or a metal nitride thereof.

Such a counter substrate 520 is attached to the substrate 501 using a sealing material 528. The sealing material 528 can be drawn over the substrate 501 or the counter substrate 520 by using a dispenser or the like. Further, a spacer 525 is provided in a part of the pixel portion 405 and the driver circuit portion 408 in order to keep an interval between the substrate 501 and the counter substrate 520. The spacer 525 has a columnar shape, a spherical shape, or the like.

A liquid crystal 511 is injected between the substrate 501 and the counter substrate 520 attached to each other in this manner. It is preferable to inject the liquid crystal in vacuum. The liquid crystal 511 can be formed by a method other than an injecting method. For example, the liquid crystal 511 may be dropped and then the counter substrate 520 may be attached thereto. Such a dropping method is preferably employed when using a large substrate to which the injecting method cannot be applied easily.

The liquid crystal 511 includes a liquid crystal molecule of which tilt is controlled by the pixel electrode 506 and the counter electrode 523. Specifically, the tilt of the liquid crystal molecule is controlled by a voltage applied to the pixel electrode 506 and the counter electrode 523. Such a control is performed using a control circuit provided in the driver circuit portion 408. Note that the control circuit is not necessarily formed over the substrate 501, and a circuit connected through a connecting terminal 510 may be used. In this case, an anisotropic conductive film containing conductive microparticles can be used so as to be connected to the connecting terminal 510. Further, the counter electrode 523 is electrically connected to a part of the connecting terminal 510, and thus, a potential of the counter electrode 523 can be a common potential. For example, a bump 537 can be used for the conduction.

Next, a structure of a backlight unit 552 is described. The backlight unit 552 includes a cold cathode tube, a hot cathode tube, a light-emitting diode, an inorganic EL, or an organic EL as a light source 531 which emits light, a lamp reflector 532 to effectively lead light to a light guide plate 535, the light guide plate 535 by which light is totally reflected and led to the entire surface, a diffusing plate 536 for reducing variation in brightness, and a reflective plate 534 for reusing light leaking under the light guide plate 535.

A control circuit for controlling the luminance of the light source 531 is connected to the backlight unit 552. The luminance of the light source 531 can be controlled by a signal supplied from the control circuit.

In addition, a structure in which polarizing plates are stacked as shown in FIG. 2A is used as a polarizer in this embodiment mode. Naturally, the stacked polarizers shown in FIG. 2B and FIG. 2C may also be used. As shown in FIG. 6, a polarizing plate 516 having a stacked structure is provided between the substrate 501 and the backlight unit 552, and a polarizing plate 521 having a stacked structure is provided over the counter substrate 520 as well.

That is, the substrate 501 is provided with a polarizing plate 543 and a polarizing plate 544 which are sequentially stacked from the substrate side as the polarizing plate 516 having the stacked structure. At this time, the polarizing plate 543 and the polarizing plate 544 which are stacked are attached to each other so as to be in a parallel Nicols state.

In addition, the counter substrate 520 is provided with a polarizing plate 541 and a polarizing plate 542 which are sequentially stacked from the substrate side as the polarizing plate 521 having the stacked structure. At this time, the polarizing plate 541 and the polarizing plate 542 which are stacked are attached to each other so as to be in a parallel Nicols state.

Further, the polarizing plate 516 having the stacked structure and the polarizing plate 521 having the stacked structure are arranged to be in a crossed Nicols state.

Extinction coefficients of the polarizing plates 541 to 544 preferably have the same wavelength distribution.

FIG. 6 shows an example in which two polarizing plates are stacked for one substrate; however, three or more polarizing plates may be stacked.

The contrast ratio can be increased by arranging the polarizing plates having the stacked structure in such a liquid crystal display device. In addition, in the present invention, a plurality of the stacked polarizing plates can be polarizing plates having a stacked structure, which is different from a case where a polarizing plate made thicker simply. It is preferable that the contrast ratio can be more increased than the case where a polarizing plate made thicker.

In addition, this embodiment mode can be freely combined with any of other embodiment modes and other examples in this specification, if necessary.

### Embodiment Mode 6

Embodiment Mode 6 will describe a liquid crystal display device which has a polarizer having a stacked structure, but which uses a TFT having an amorphous semiconductor film, which is different from Embodiment Mode 5.

Note that like elements to those in Embodiment Mode 5 are denoted by the same reference numerals and Embodiment Mode 5 can be applied to an element which is not particularly described.

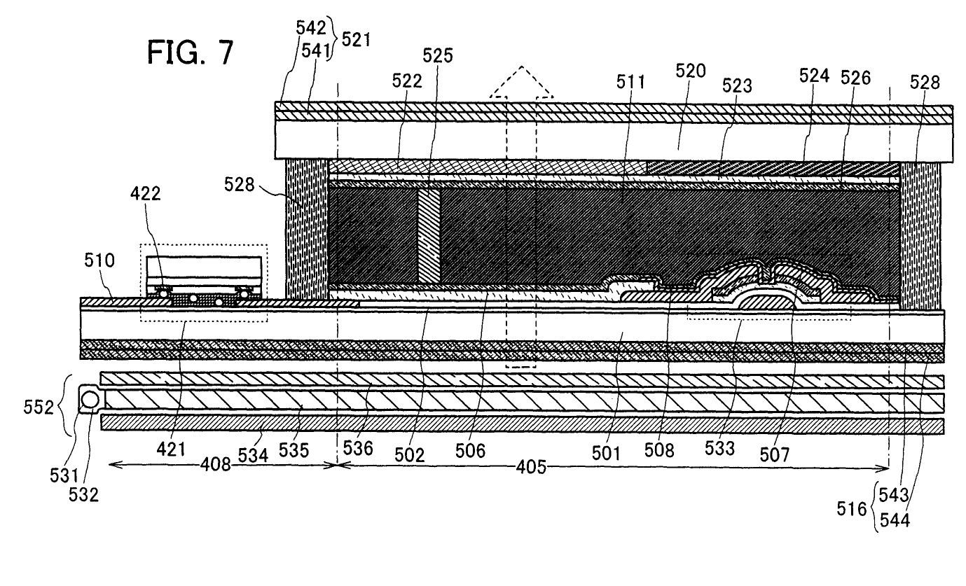

In FIG. 7, a structure of a liquid crystal display device including a transistor using an amorphous semiconductor film (hereinafter referred to as an amorphous TFT) as a switching element is described. The pixel portion 405 is provided with a switching TFT 533 formed from an amorphous TFT. The amorphous TFT can be formed by a known method. In the case of a channel etch type, for example, a gate electrode is formed over the base film 502, and a gate insulating film which covers the gate electrode, an n-type semiconductor film, an amorphous semiconductor film, a source electrode and a drain electrode are formed. By using the source electrode and the drain electrode as a mask, an opening portion is formed in the n-type semiconductor film. At this time, a part of the amorphous semiconductor film is removed, which is called a channel etch type. Then, a protective film 507 is formed and the amorphous TFT can be obtained. In addition, the amorphous TFT also includes a channel protective type, and when an opening portion is formed in the n-type semiconductor film by using the source electrode and the drain electrode as a mask, a protective film is provided such that the amorphous semiconductor film is not removed. Other structures can be similar to the channel etch type.

The alignment film 508 is formed similarly to FIG. 6, and the alignment film 508 is subjected to a rubbing treatment. This rubbing treatment is not performed in some cases in a mode of a liquid crystal, for example, in a case of a VA mode.

The counter substrate 520 is prepared and attached to the substrate 501 by using the sealing material 528 similarly to FIG. 6. By filling a space between the counter substrate 520 and the substrate 501 with the liquid crystal 511 and sealing, a liquid crystal display device can be formed.

Similarly to FIG. 6, a structure in which polarizing plates are stacked as shown in FIG. 2A is used as a polarizer in this embodiment mode. Naturally, the stacked polarizers shown in FIG. 2B and FIG. 2C may also be used. As shown in FIG. 6, the polarizing plate 516 having a stacked structure is provided between the substrate 501 and the backlight unit 552, and the polarizing plate 521 having a stacked structure is provided over the counter substrate 520 as well.

That is, the substrate 501 is provided with the polarizing plate 543 and the polarizing plate 544 which are sequentially stacked from the substrate side as the polarizing plate 516 having the stacked structure. At this time, the polarizing plate 543 and the polarizing plate 544 which are stacked are attached to each other so as to be in a parallel Nicols state.

In addition, the counter substrate 520 is provided with the polarizing plate 541 and the polarizing plate 542 which are sequentially stacked from the substrate side as the polarizing plate 521 having the stacked structure. At this time, the polarizing plate 541 and the polarizing plate 542 which are stacked are attached to each other so as to be in a parallel Nicols state.

Further, the polarizing plate 516 having the stacked structure and the polarizing plate 521 having the stacked structure are arranged to be in a crossed Nicols state.

The extinction coefficients of the polarizing plates 541 to 544 a may have the same wavelength distribution.

FIG. 7 shows an example in which two polarizing plates are stacked for one substrate; however, three or more polarizing plates may be stacked.

In the case of forming a liquid crystal display device by using an amorphous TFT as the switching TFT 533 in this manner, an IC 421 formed using a silicon wafer can be mounted as a driver on the driver circuit portion 408 in consideration of operating performance. For example, a signal to control the switching TFT 533 can be supplied by connecting a wiring of the IC 421 and a wiring connected to the switching TFT 533 by using an anisotropic conductor having a conductive microparticle 422. Note that a mounting method of the IC 421 is not limited to this, and the IC 421 may be mounted by a wire bonding method.

Further, the IC can be connected to a control circuit through the connecting terminal 510. At this time, an anisotropic conductive film having the conductive microparticle 422 can be used to connect the IC to the connecting terminal 510.

Since the other structures are similar to FIG. 6, description thereof is omitted here.

The contrast ratio can be increased by arranging the polarizing plates having the stacked structure in such a liquid crystal display device. In addition, in the present invention, a plurality of the stacked polarizing plates can be polarizing plates having a stacked structure, which is different from a case where a polarizing plate made thicker simply. It is preferable that the contrast ratio can be more increased than the case where a polarizing plate made thicker.

In addition, this embodiment mode can be freely combined with any of other embodiment modes and other examples in this specification, if necessary.

### Embodiment Mode 7

Embodiment Mode 7 will describe a concept of a display device of the present invention.

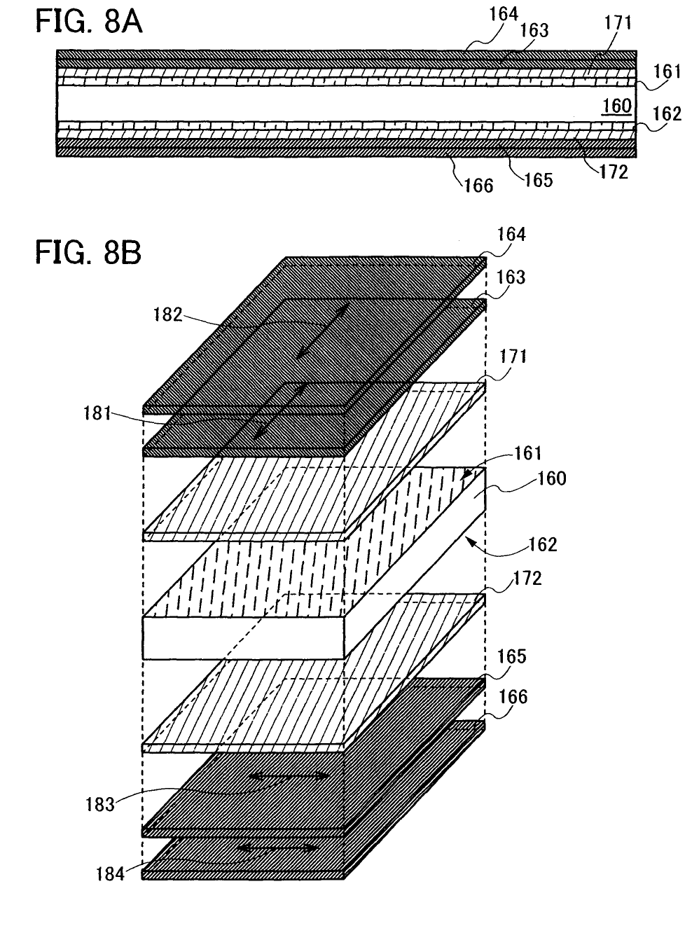

FIG. 8A shows a cross sectional view of a display device provided with a polarizer having a stacked structure, and FIG. 8B shows a perspective view of the display device. In this embodiment mode, a liquid crystal display device including a liquid crystal element as a display element is described as an example.

As shown in FIG. 8A, a layer 160 including a liquid crystal element is interposed between a first substrate 161 and a second substrate 162 which are arranged to be opposite to each other. Light-transmitting substrates are used for the substrate 161 and the substrate 162. As such light-transmitting substrates, a glass substrate such as barium borosilicate glass or alumino-borosilicate glass, a quartz substrate, or the like can be used. Alternatively, a substrate formed from a synthetic resin having flexibility, such as a plastic, typified by polyethylene-terephthalate (PET), polyethylene naphthalate (PEN), polyethersulfone (PES), or polycarbonate (PC), or acrylic, can be used for the light-transmitting substrates.

On the outer sides of the substrate 161 and the substrate 162, namely sides which are not in contact with the layer 160 including the liquid crystal element from the substrate 161 and the substrate 162, respectively, stacked polarizers are provided. Note that in this embodiment mode, as the structure of the stacked polarizers, polarizing plates each including one polarizing film shown in FIG. 2A are stacked. Needless to say, the structures shown in FIGS. 2B and 2C may also be used.

On the outer sides of the substrate 161 and the substrate 162, that is, on the sides which are not in contact with the layer 160 including the liquid crystal element from the substrate 161 and the substrate 162, respectively, a retardation plate (also referred to as a retardation film or a wave plate) and stacked polarizing plates are sequentially provided. On the first substrate 161 side, a first retardation plate 171, a first polarizing plate 163, and a second polarizing plate 164 are sequentially provided. On the second substrate 162 side, a second retardation plate 172, a third polarizing plate 165, and a fourth polarizing plate 166 are sequentially provided. The retardation plate is used for the purpose of a wider viewing angle or an antireflective effect, and when the retardation plate are used for antireflection, quarter-wave plates are used as the retardation plate 171 and the retardation plate 172.

These polarizing plates 163 to 166 can be formed from known materials. For example, a structure can be used, in which an adhesive surface, TAC (triacetylcellulose), a mixed layer of PVA (polyvinyl alcohol) and a dichroic pigment, and TAC are sequentially stacked from the substrate side. The dichroic pigment includes iodine and dichromatic organic dye. The polarizing plate is sometimes referred to as a polarizing film based on the shape.

The extinction coefficients of the first polarizing plate 163 to the fourth polarizing plate 166 preferably have the same wavelength distribution.

FIGS. 8A and 8B show the example in which two polarizing plates are stacked for one substrate; however, three or more polarizing plates may be stacked.

The retardation film may be, for example, a film in which liquid crystals are hybrid-oriented, a film in which liquid crystals are twisted-oriented, a uniaxial retardation film, or a biaxial retardation film. Such retardation films can widen the viewing angle of the display device. The film in which liquid crystals are hybrid-oriented is a complex film obtained by using a triacetylcellulose (TAC) film as a base and hybrid-orienting negative uniaxial discotic liquid crystals to have optical anisotropy.

A uniaxial retardation film is formed by stretching a resin in one direction. Further, a biaxial retardation film is formed by stretching a resin into an axis in a crosswise direction, then gently stretching the resin into an axis in a lengthwise direction. Examples of a resin that can be used here are a cyclo olefin polymer (COP), polycarbonate (PC), polymethyl methacrylate (PMMA), polystyrene (PS), polyether sulfone (PES), polyphenylene sulfide (PPS), polyethylene terephthalate (PET), polyethylene naphthalate (PEN), polypropylene (PP), polyphenylene oxide (PPO), polyarylate (PAR), polyimide (PI), polytetrafluoroethylene (PTFE) and the like.

Note that the film in which liquid crystals are hybrid-oriented may a film obtained by using a triacetylcellulose (TAC) film as a base and hybrid-orienting discotic liquid crystals or nematic liquid crystals. The retardation plate can be attached to the light-transmitting substrate with the retardation plate attached to the polarizing plate.

Next, in the perspective view shown in FIG. 8B, the first polarizing plate 163 and the second polarizing plate 164 are arranged in such a way that an absorption axis 181 of the first polarizing plate 163 and an absorption axis 182 of the second polarizing plate 164 should be parallel. This parallel state is referred to as parallel Nicols. Similarly, the third polarizing plate 165 and the fourth polarizing plate 166 are arranged in such a way that an absorption axis 183 of the third polarizing plate 165 and an absorption axis 184 of the fourth polarizing plate 166 should be parallel, that is, they are in a parallel Nicols state.

The stacked polarizing plates in this manner are arranged such that they are in a parallel Nicols state.

The stacked polarizing plates, which are opposite to each other via the layer 160 including a liquid crystal element, are arranged such that their absorption axes are orthogonal to each other. The orthogonal state is called crossed Nicols.

Note that a transmission axis exists in the direction orthogonal to the absorption axis based on the characteristics of the polarizing plate. Thus, a state in which the transmission axes are parallel to each other can also be referred to as parallel Nicols. In addition, the case where transmission axes are orthogonal to each other can also be referred to as crossed Nicols.

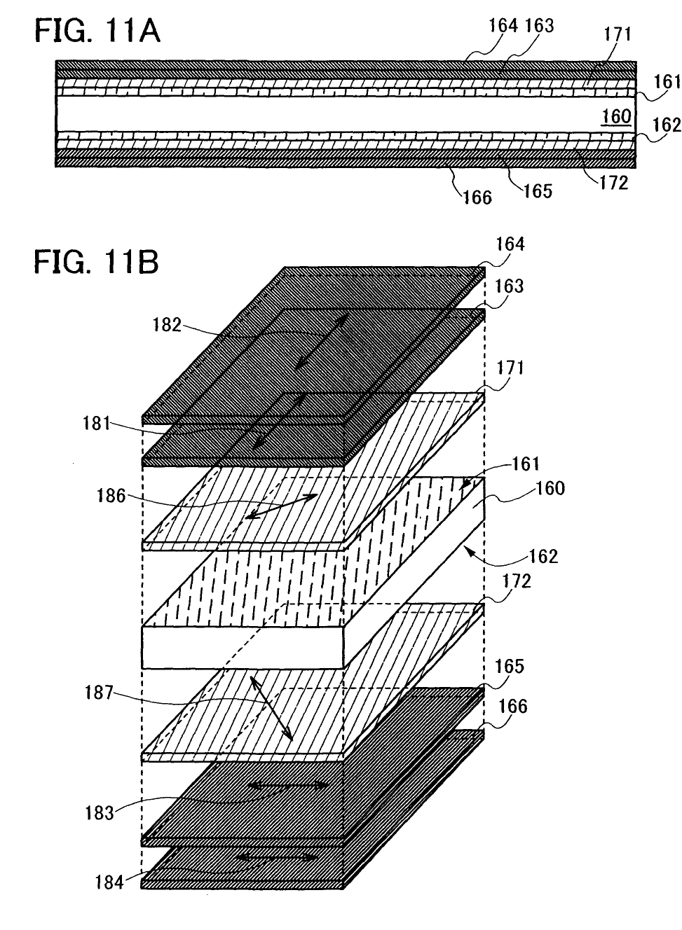

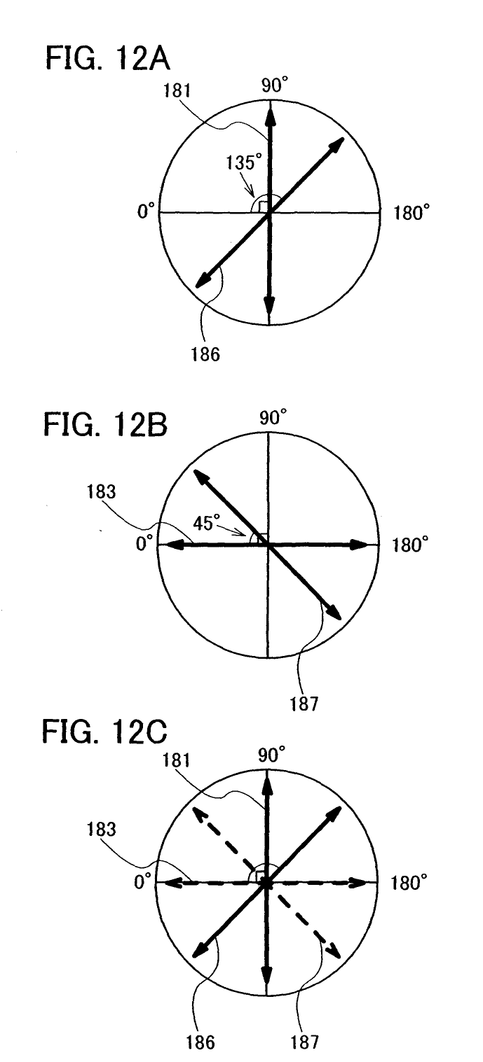

Angular deviation between the retardation plate and the slow axis for the purpose of antireflection is described with reference to FIGS. 11A, 11B and 12. In FIG. 11B, an arrow 186 denotes the slow axis of the first retardation plate 171 and an arrow 187 denotes the slow axis of the second retardation plate 172.

The slow axis 186 of the first retardation plate 171 is arranged to be shifted from the absorption axis 181 of the first polarizing plate 163 and the absorption axis 182 of the second polarizing plate 164 by 45°.

FIG. 12A shows angular deviation between the absorption axis 181 of the first polarizing plate 163 and the slow axis 186 of the first retardation plate 171. The slow axis 186 of the first retardation plate 171 is 135° and the absorption axis 181 of the first polarizing plate 163 is 90°, which means that they are shifted from each other by 45°.

The slow axis 187 of the second retardation plate 172 is arranged to be shifted from the absorption axis 183 of the third polarizing plate 165 and the absorption axis 184 of the fourth polarizing plate 166 by 45°.

FIG. 12B shows angular deviation of the absorption axis 183 of the third polarizing plate 165 and the slow axis 187 of the second retardation plate 172. The slow axis 187 of the second retardation plate 172 is 45° and the absorption axis 183 of the third polarizing plate 165 is 0°, which means that they are shifted from each other by 45°. In other words, the slow axis 186 of the first retardation plate 171 is arranged to be shifted by 45° from the absorption axis 181 of the first linear polarizing plate 163 and the absorption axis 182 of the second linear polarizing plate 164. The slow axis 187 of the second retardation plate 172 is arranged to be shifted by 45° from the absorption axis 183 of the third linear polarizing plate 165 and the absorption axis 184 of the fourth linear polarizing plate 166.

One feature of the present invention is that the absorption axis 181 (and 182) of the polarizing plate having the stacked structure provided over the first substrate 161 and the absorption axis 183 (and 184) of the polarizing plate having the stacked structure provided over the second substrate 162 are orthogonal to each other. In other words, the stacked polarizing plates 163 and 164 and the stacked polarizing plate 165 and 166, namely opposite polarizing plates, are arranged to be in a crossed Nicols state.

FIG. 12C shows a state where the absorption axis 181 and the slow axis 186 each indicated by a solid line and the absorption axis 183 and the slow axis 187 each indicated by a dotted line overlap with each other and are shown in the same circle.

FIG. 12C shows that the absorption axis 181 and the absorption axis 183 are in a crossed Nicols state, and the slow axis 186 and the slow axis 187 are also in a crossed Nicols state.

A fast axis exists in the direction orthogonal to the slow axis based on the characteristics of the retardation plate. Therefore, arrangement of the retardation plate and the polarizing plate can be determined using not only the slow axis but also the fast axis. In this embodiment mode, the absorption axis and the slow axis are arranged to be shifted from each other by 45°, in other words, the absorption axis and the fast axis are arranged to be shifted from each other by 135°.

In this specification, it is assumed that the above angle range is to be satisfied when angular deviation of an absorption axis and a slow axis, angular deviation of absorption axes, or angular deviation of slow axes is mentioned; however, the angular deviation between the axes may differ from the above-described angles to some extent as long as a similar effect can be obtained.

As the circularly polarizing plate, a circularly polarizing plate with a widened band is given. The circularly polarizing plate with a widened band is an object in which a wavelength range in which phase difference (retardation) is 90°, can be widened by stacking several retardation plates. Also in this case, a slow axis of each retardation plate arranged on the outer side of the first substrate 161 and a slow axis of each retardation plate arranged on the outer side of the second substrate 162 may be arranged to be 90°, and absorption axes of opposite polarizing plates may be arranged to be in a crossed Nicols state.

Since the stacked polarizing plates are stacked to be in a parallel Nicols state, light leakage in the absorption axis direction can be reduced. Further, by disposing opposite polarizing plates in a crossed Nicols state, light leakage can be reduced, compared to the case where a pair of single polarizing plates is arranged in crossed Nicols. Consequently, the contrast ratio of the display device can be increased.

Furthermore, in accordance with the present invention, by changing the type of a retardation plate and the angle to be deviated, a display device with a wide viewing angle can be provided.

In addition, this embodiment mode can be freely combined with any of other embodiment modes and other examples in this specification, if necessary.

### Embodiment Mode 8

Embodiment Mode 8 will describe a specific structure of the liquid crystal display device described in Embodiment Mode 7.

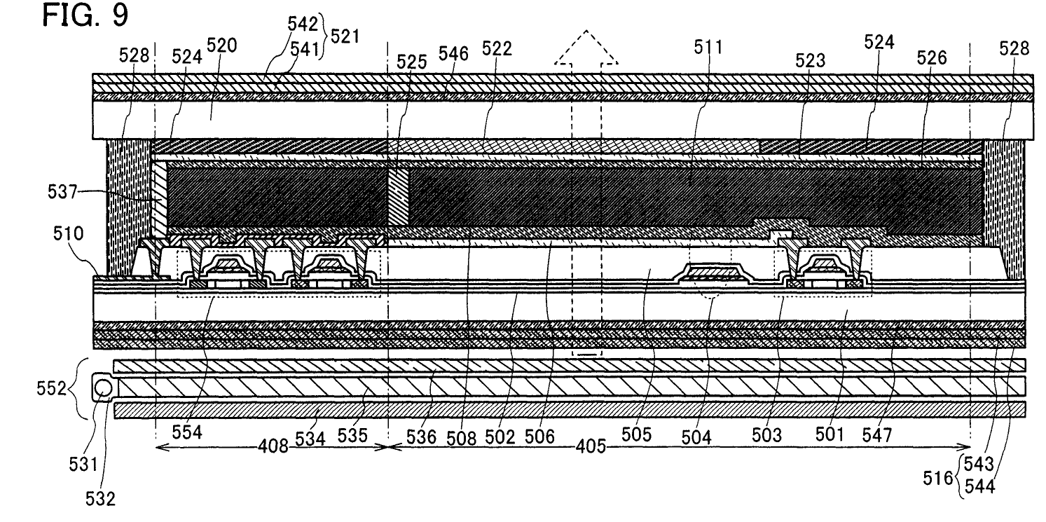

Note that elements in a liquid crystal display device shown in FIG. 9 similar to those in FIG. 6 are denoted by the same reference numerals, and description of FIG. 6 can be applied to an element which is not particularly described.

FIG. 9 is a cross sectional view of a liquid crystal display device provided with stacked polarizing plates.

A liquid crystal display device includes the pixel portion 405 and the driver circuit portion 408. In the pixel portion 405 and the driver circuit portion 408, the base film 502 is provided over the substrate 501. An insulating substrate similar to the one in Embodiment Mode 7 can be used for the substrate 501. Further, generally there is a concern that a substrate formed from a synthetic resin has a lower allowable temperature limit than other substrates. However, a substrate with high heat resistance is adopted in a manufacturing process first and the substrate is replaced by a substrate formed from a synthetic resin, thereby making it possible to employ such a substrate formed from a synthetic resin.

The pixel portion 405 is provided with a transistor as a switching element through the base film 502. In this embodiment mode, a thin film transistor (TFT) is used as the transistor, which is referred to as the switching TFT 503. There are many methods for forming a TFT. For example, a crystalline semiconductor film is used as an active layer. A gate electrode is provided over the crystalline semiconductor film with a gate insulating film interposed therebetween. An impurity element can be added to the active layer by using the gate electrode as a mask. Since an impurity element is added using the gate electrode as the mask in this manner, a mask for adding the impurity element is not required to be additionally formed. The gate electrode may have a single layer structure or a stacked structure. An impurity region can be formed as a high concentration impurity region or a low concentration impurity region by controlling the concentration thereof. A structure of such a TFT having a low concentration impurity region is referred to as an LDD (Lightly Doped Drain) structure. Further, the low concentration impurity region can be formed so as to overlap with the gate electrode. A structure of such a TFT is referred to as a GOLD (Gate Overlapped LDD) structure.

Note that the TFT may be a top gate type TFT or a bottom gate type TFT, and may be formed as appropriate.

FIG. 9 shows the switching TFT 503 having a GOLD structure. The polarity of the switching TFT 503 is an n-type by using phosphorus (P) or the like for an impurity region thereof. In the case of forming a p-type TFT, boron (B) or the like may be added. After that, a protective film which covers the gate electrode or the like is formed. A dangling bond in the crystalline semiconductor film can be terminated by a hydrogen element mixed in the protective film.

Further, in order to improve planarity more, the interlayer insulating film 505 may be formed. The interlayer insulating film 505 may be formed from an organic material or an inorganic material, or formed using a stacked structure of these. Opening portions are formed in the interlayer insulating film 505, the protective film, and the gate insulating film; and a wiring connected to the impurity regions is formed. In this manner, the switching TFT 503 can be formed. Note that the present invention is not limited to the structure of the switching TFT 503.

Then, the pixel electrode 506 connected to the wiring is formed.

Further, the capacitor element 504 can be formed at the same time as the switching TFT 503. In this embodiment mode, the capacitor element 504 is formed from a stack of a conductive film formed at the same time as the gate electrode, the protective film, the interlayer insulating film 505, and the pixel electrode 506.

In addition, the pixel portion 405 and the driver circuit portion 408 can be formed over the same substrate by using a crystalline semiconductor film. In that case, transistors in the pixel portion 405 and transistors of the driver circuit portion 408 are formed at the same time. The transistors used for the driver circuit portion 408 form a CMOS circuit; and thus, the transistors are referred to as the CMOS circuit 554. Each of the transistors which form the CMOS circuit 554 may have a similar structure to the switching TFT 503. Further, the LDD structure can be used instead of the GOLD structure, and a similar structure is not necessarily required.

The alignment film 508 is formed so as to cover the pixel electrode 506. The alignment film 508 is subjected to a rubbing treatment. This rubbing treatment is not performed in some cases in a mode of a liquid crystal, for example, in a case of a VA mode.

Next, the counter substrate 520 is provided. The color filter 522 and the black matrix (BM) 524 can be provided on an inner side of the counter substrate 520, that is, on the side which is in contact with a liquid crystal. These can be formed by a known method; however, a droplet discharging method (representatively an ink-jetting method) by which a predetermined material is dropped can eliminate the waste of the material. Further, the color filter or the like is provided in a region where the switching TFT 503 is not provided. That is to say, the color filter is provided to face a light-transmitting region, i.e., an opening region. Note that the color filters or the like may be formed from materials which exhibit red (R), green (G), and blue (B) in the case where a liquid crystal display device performs full-color display, and a material which exhibits at least one color in the case of mono-color display.

Note that the color filter is not provided in some cases when light-emitting diodes (LEDs) of RGB or the like are arranged in a backlight and a successive additive color mixing method (field sequential method) in which color display is performed by time division. The black matrix 524 is provided to reduce reflection of external light due to wirings of the switching TFT 503 and the CMOS circuit 554. Therefore, the black matrix 524 is provided so as to overlap with the switching TFT 503 and the CMOS circuit 554. Note that the black matrix 524 may be provided so as to overlap with the capacitor element 504. Accordingly, reflection on a metal film constituting a part of the capacitor element 504 can be prevented.

Then, the counter electrode 523 and the alignment film 526 are provided. The alignment film 526 is subjected to a rubbing treatment.

Note that the wiring included in the TFT, the gate electrode, the pixel electrode 506, and the counter electrode 523 can be formed from materials selected from indium tin oxide (ITO), indium zinc oxide (IZO) in which zinc oxide (ZnO) is mixed in indium oxide, a conductive material in which silicon oxide (SiO₂) is mixed in indium oxide, organic indium, organotin, a metal such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), or copper (Cu), an alloy thereof, or a metal nitride thereof.

Such a counter substrate 520 is attached to the substrate 501 using the sealing material 528. The sealing material 528 can be drawn over the substrate 501 or the counter substrate 520 by using a dispenser or the like. Further, the spacer 525 is provided in a part of the pixel portion 405 and the driver circuit portion 408 in order to keep an interval between the substrate 501 and the counter substrate 520. The spacer 525 has a columnar shape, a spherical shape, or the like.

The liquid crystal 511 is injected between the substrate 501 and the counter substrate 520 attached to each other in this manner. It is preferable to inject the liquid crystal in vacuum. The liquid crystal 511 can be formed by a method other than the injecting method. For example, the liquid crystal 511 may be dropped and then the counter substrate 520 may be attached thereto. Such a dropping method is preferably employed when using a large substrate to which the injecting method cannot be applied easily.

The liquid crystal 511 includes a liquid crystal molecule of which tilt is controlled by the pixel electrode 506 and the counter electrode 523. Specifically, the tilt of the liquid crystal molecule is controlled by a voltage applied to the pixel electrode 506 and the counter electrode 523. Such a control is performed using a control circuit provided in the driver circuit portion 408. Note that the control circuit is not necessarily formed over the substrate 501, and a circuit connected through the connecting terminal 510 may be used. In this case, an anisotropic conductive film containing conductive microparticles can be used so as to be connected to the connecting terminal 510. Further, the counter electrode 523 is electrically connected to a part of the connecting terminal 510, and a potential of the counter electrode 523 can be a common potential. For example, the bump 537 can be used for the conduction.

Next, a structure of the backlight unit 552 is described. The backlight unit 552 includes a cold cathode tube, a hot cathode tube, a diode, an inorganic EL, or an organic EL as the light source 531, the lamp reflector 532 to effectively lead light to the light guide plate 535, the light guide plate 535 by which light is totally reflected and led to the entire surface, the diffusing plate 536 for reducing variation in brightness, and the reflective plate 534 for reusing light leaking under the light guide plate 535.

A control circuit for controlling the luminance of the light source 531 is connected to the backlight unit 552. The luminance of the light source 531 can be controlled by a signal supplied from the control circuit.

In addition, a structure in which polarizing plates are stacked as shown in FIG. 2A is used as polarizers in this embodiment mode. Naturally, the stacked polarizers shown in FIG. 2B and FIG. 2C may also be used. As shown in FIG. 9, a retardation plate 547 and the polarizing plate 516 having a stacked structure are provided between the substrate 501 and the backlight unit 552, and a retardation plate 546 and the polarizing plate 521 having a stacked structure are provided over the counter substrate 520 as well. The polarizing plates having a stacked structure and the retardation film can be attached to each other and bonded to each of the substrate 501 and the counter substrate 520.

That is, the substrate 501 is provided with the retardation plate 547, the polarizing plate 543 and the polarizing plate 544 which are stacked as the polarizing plate 516 having the stacked structure, which are sequentially stacked from the substrate side. At this time, the polarizing plate 543 and the polarizing plate 544 which are stacked are attached to each other so as to be in a parallel Nicols state.

In addition, the counter substrate 520 is provided with the retardation plate 546, the polarizing plate 541 and the polarizing plate 542 which are stacked as the polarizing plate 521 having the stacked structure, which are sequentially stacked from the substrate side. At this time, the polarizing plate 541 and the polarizing plate 542 which are stacked are attached to each other so as to be in a parallel Nicols state.

Further, the polarizing plates 516 and 521 each having the stacked structure are arranged to be in a crossed Nicols state.

Extinction coefficients of the polarizing plated 541 to 544 may have the same wavelength distribution.

FIG. 9 shows the example in which two polarizing plates are stacked for one substrate; however, three or more polarizing plates may be stacked.

The contrast ratio can be increased by providing the polarizing plates having the stacked structure. By using the retardation plates, a display device in which reflection to the display device is prevented and which has a wide viewing angle can be provided.

In addition, this embodiment mode can be freely combined with any of other embodiment modes and other examples in this specification, if necessary.

### Embodiment Mode 9

Embodiment Mode 9 will describe a liquid crystal display device which has stacked polarizing plates, but which uses a TFT having an amorphous semiconductor film, which is different from Embodiment Mode 8.

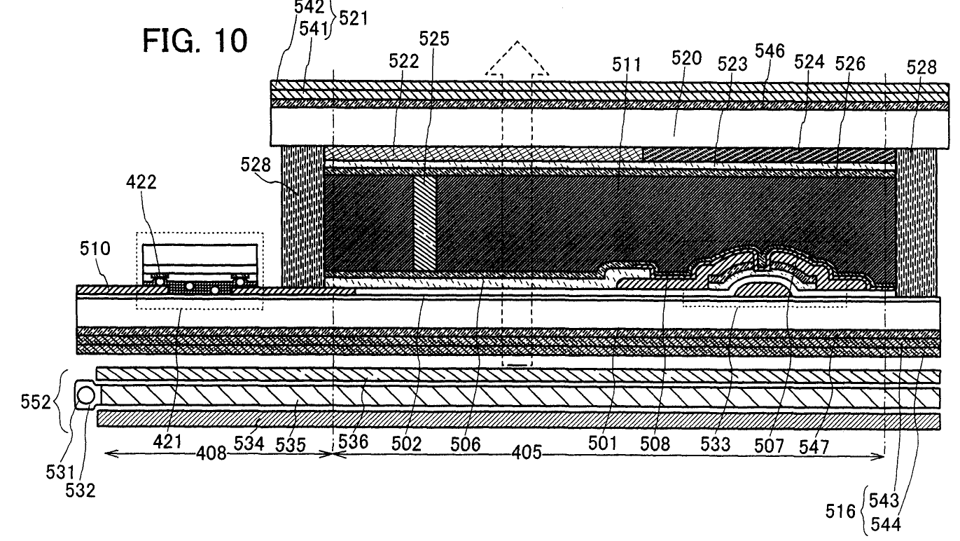

In FIG. 10, a structure of a liquid crystal display device including a transistor using an amorphous semiconductor film (hereinafter referred to as an amorphous TFT) as a switching element is described. The pixel portion 405 is provided with the switching TFT 533 including an amorphous TFT. The amorphous TFT can be formed by a known method. In the case of a channel etch type, for example, a gate electrode is formed over the base film 502, and a gate insulating film which covers the gate electrode, an n-type semiconductor film, an amorphous semiconductor film, a source electrode and a drain electrode are formed. By using the source electrode and the drain electrode as a mask, an opening portion is formed in the n-type semiconductor film. At this time, a part of the amorphous semiconductor film is removed, which is called a channel etch type. Then, the protective film 507 is formed and the amorphous TFT is formed. In addition, the amorphous TFT also includes a channel protective type, and when an opening portion is formed in the n-type semiconductor film by using the source electrode and the drain electrode as a mask, a protective film is provided such that the amorphous semiconductor film is not removed. Other structures can be similar to the channel etch type.

The alignment film 508 is formed similarly to FIG. 9, and the alignment film 508 is subjected to a rubbing treatment. This rubbing treatment is not performed in accordance with a mode of a liquid crystal.

The counter substrate 520 is prepared and attached by using the sealing material 528 similarly to FIG. 9. By filling a space between the counter substrate 520 and the substrate 501 with the liquid crystal 511 and sealing, a liquid crystal display device can be formed.

In addition, a structure in which polarizing plates are stacked as shown in FIG. 2A is used as a polarizer in this embodiment mode. Naturally, the stacked polarizers shown in FIG. 2B and FIG. 2C may also be used. As shown in FIG. 10, similarly to FIG. 9, the retardation plate 547 and the polarizing plate 516 having a stacked structure are provided between the substrate 501 and the backlight unit 552, and the retardation plate 546 and the polarizing plate 521 having a stacked structure are provided for the counter substrate 520 as well. The polarizing plate having a stacked structure and the retardation film can be attached to each other and bonded to each of the substrate 501 and the counter substrate 520.

That is, the substrate 501 is provided with the retardation plate (also referred to as the retardation film or the wave plate) 547, the polarizing plate 543 and the polarizing plate 544 which are stacked as the polarizing plate 516 having the stacked structure, which are sequentially stacked from the substrate side. At this time, the polarizing plate 543 and the polarizing plate 544 which are stacked are attached to each other so as to be in a parallel Nicols state.

In addition, the counter substrate 520 is provided with the retardation plate 546, the polarizing plate 541 and the polarizing plate 542, which are stacked, as the polarizing plate 521 having the stacked structure, which are sequentially stacked from the substrate side. At this time, the polarizing plate 541 and the polarizing plate 542, which are stacked, are attached to each other so as to be in a parallel Nicols state.

Further, the polarizing plates 516 and 521 each having the stacked structure are arranged to be in a crossed Nicols state.

The extinction coefficients of the polarizing plates 541 to 544 may have the same wavelength distribution.

FIG. 10 shows the example in which two polarizing plates are stacked for one substrate; however, three or more polarizing plates may be stacked.

The contrast ratio can be increased by providing the polarizing plates having a stacked structure. By using the retardation plate, a display device which can suppress reflection and have a wide viewing angle can be provided.

In the case of forming a liquid crystal display device by using an amorphous TFT as the switching TFT 533 in this manner, the IC 421 formed using a silicon wafer can be mounted as a driver on the driver circuit portion 408 in consideration of operating performance. For example, a signal to control the switching TFT 533 can be supplied by connecting a wiring of the IC 421 and a wiring connected to the switching TFT 533 by using an anisotropic conductor having the conductive microparticle 422. Note that the mounting method of the IC is not limited to this, and the IC may be mounted by a wire bonding method.

Further, the IC can be connected to a control circuit through the connecting terminal 510. At this time, an anisotropic conductive film having the conductive microparticle 422 can be used to connect the IC to the connecting terminal 510.

Since the other structures are similar to those shown in FIG. 9, description thereof is omitted here.

In addition, this embodiment mode can be freely combined with any of other embodiment modes and other examples in this specification, if necessary.

### Embodiment Mode 10

Embodiment Mode 10 will describe a structure of a backlight. The backlight is provided in a display device as a backlight unit having a light source. The light source is surrounded by a reflective plate so that the backlight unit can efficiently disperse light.

The backlight in this embodiment mode is used as the backlight unit 552 described in Embodiment Mode 5, Embodiment Mode 6, Embodiment Mode 8, and Embodiment Mode 9.

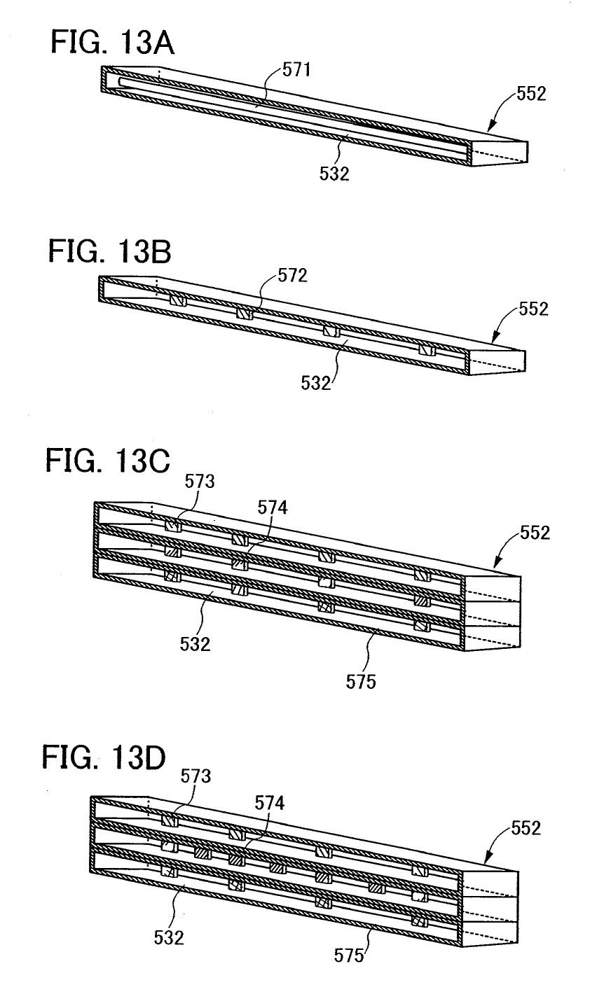

As shown in FIG. 13A, the backlight unit 552 can employ a cold cathode tube 571 as a light source. Further, in order to efficiently reflect light which is from the cold cathode tube 571, the lamp reflector 532 can be provided. The cold cathode tube 571 is often used in a large-sized display device. That is due to the intensity of the luminance from the cold cathode tube. Therefore, a backlight unit included in a cold cathode tube can be used for a display of a personal computer.

As shown in FIG. 13B, the backlight unit 552 can use a light-emitting diode (an LED) 572 as a light source. For example, the diodes (W) 572 that emit white light are arranged at predetermined intervals. Further, in order to efficiently reflect light that is from the diodes (W) 572, the lamp reflector 532 can be provided.

As shown in FIG. 13C, the backlight unit 552 can employ light-emitting diodes (LEDs) of each color, RGB, as a light source, that is, a light-emitting diode (R) 573 which emits red light, a light-emitting diode (G) 574 which emits green light, and a light-emitting diode (B) 575 which emits blue light. By using the light-emitting diodes (LEDs) 573, 574, and 575 of each color, RGB, color reproducibility can be more improved than when only the light-emitting diodes (W) 572 that emit white light are used. Further, in order to efficiently reflect light that is from the light-emitting diode (R) 573, the light-emitting diode (G) 574, and the light-emitting diode (B) 575, the lamp reflector 532 can be provided.

Further, as shown in FIG. 13D, when the diodes (LEDs) 573, 574 and 575 of each color, RGB are used as a light source, it is not necessary to provide the same number of diodes of each color or to arrange them in the same arrangement. For example, a plurality of light-emitting diodes of a color with low emission intensity (for example, green) may be arranged.

Further, the light-emitting diodes (W) 572 that emit white light may be combined with the light-emitting diodes (LEDs) 573, 574 and 575 of each color, RGB.

Note that in the case where RGB light-emitting diodes are provided, when a field sequential mode is used, color display can be conducted by activating the RGB light-emitting diodes in sequence according to time.

When light-emitting diodes are employed, since luminance is high, the backlight unit using the light-emitting diodes is suitable for a large-sized display device. Further, since the color purity of each color, RGB, is good, color reproducibility is excellent compared to when a cold cathode tube is employed, and since layout area can be reduced, if the backlight unit is adapted to a small-sized display device, a narrow frame can be attempted.

Further, the light source is not necessarily arranged as the backlight unit shown in FIGS. 13A to 13D. For example, when a large-sized display device is equipped with a backlight having diodes, the diodes can be arranged on the back surface of the substrate. At that point, diodes of each color can be sequentially arranged, keeping predetermined intervals between them. Color reproducibility can be improved according to the arrangement of the diodes.

Since stacked polarizers are provided in a display device employing such a backlight, images with high contrast ratio can be provided. In particular, the backlight having diodes is suitable for large-sized display devices, and by increasing the contrast ratio of the large-sized display devices, a high-quality image can be provided even in a dark place.

In addition, this embodiment mode can be freely combined with any of other embodiment modes and other examples in this specification, if necessary.

### Embodiment Mode 11

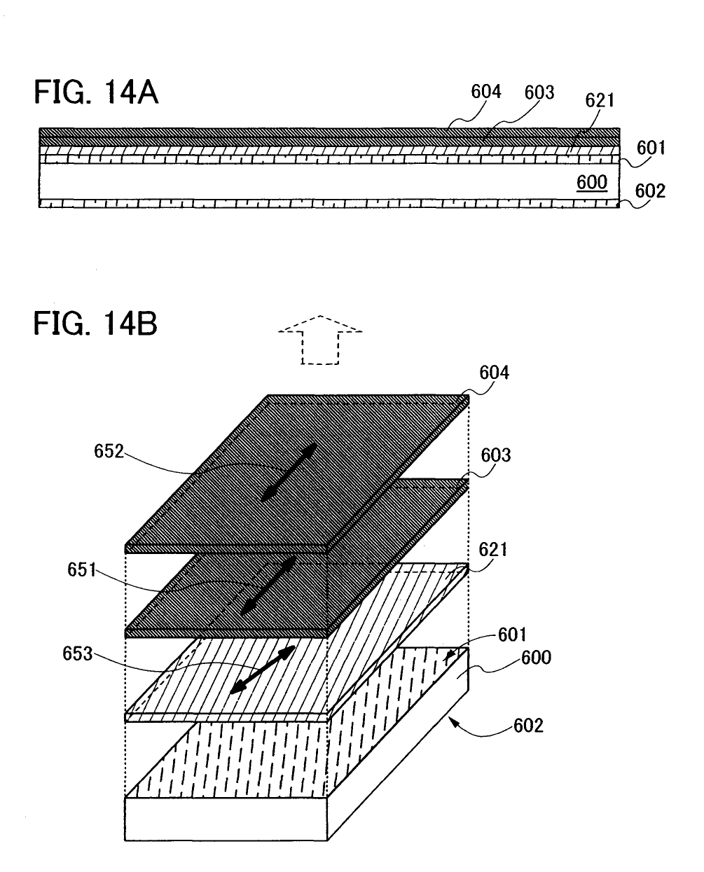

Embodiment Mode 11 will describe a concept of a reflective type liquid crystal display device of the present invention with reference to FIGS. 14A and 14B.

FIG. 14A shows a cross sectional view of a liquid crystal display device provided with stacked polarizers, and FIG. 14B shows a perspective view of the display device.

As shown in FIG. 14A, a layer 600 including a liquid crystal element is interposed between a first substrate 601 and a second substrate 602 which are arranged to be opposite to each other.

Light-transmitting substrates can be used for the first substrate 601 and the second substrate 602. As such light-transmitting substrates, a glass substrate such as barium borosilicate glass or alumino-borosilicate glass, a quartz substrate, or the like can be used. Alternatively, a substrate formed from a synthetic resin having flexibility, such as a plastic, typified by polyethylene terephthalate (PET), polyethylene naphthalate (PEN), polyethersulfone (PES), or polycarbonate (PC), or acrylic, can be used for such light-transmitting substrates.

On the outer side of the substrate 601, that is, on the side which is not in contact with the layer 600 including the liquid crystal element from the substrate 601, a retardation plate (also referred to as a retardation film or a wave plate) and stacked polarizers are sequentially provided. The structure in which polarizing plates are stacked as shown in FIG. 2A is used as the stacked polarizers in this embodiment mode. Naturally, the structure shown in FIG. 2B or FIG. 2C may also be used.

On the first substrate 601 side, a retardation plate 621, a first polarizing plate 603, and a second polarizing plate 604 are sequentially provided. A slow axis of the retardation plate 621 is denoted by reference numeral 653. External light passes through the second polarizing plate 604, the first polarizing plate 603, the retardation plate 621, and the substrate 601, and then enters the layer 600 including the liquid crystal element. The light is reflected on a reflective material provided for the second substrate 602 so that display is performed.

Since the polarizing plate 603 and the polarizing plate 604 are linear polarizing plates and are the same as the polarizing plate 113 and the polarizing plate 114 in FIG. 2A, detailed description thereof is omitted here.

The extinction coefficients of the polarizing plate 603 and the polarizing plate 604 may have the same wavelength distribution.

FIGS. 14A and 14B show the example in which two polarizing plates are stacked for one substrate; however, three or more polarizing plates may be stacked.

The retardation plate 621 (also referred to as a retardation film) may be, for example, a film in which liquid crystals are hybrid-oriented, a film in which liquid crystals are twisted-oriented, a uniaxial retardation film, or a biaxial retardation film. Such retardation films can suppress reflection to the display device. The film in which liquid crystals are hybrid-oriented is a complex film obtained by using a triacetylcellulose (TAC) film as a base and hybrid-orienting negative uniaxial discotic liquid crystals to have optical anisotropy.

A uniaxial retardation film is formed by stretching a resin in one direction. Further, a biaxial retardation film is formed by stretching a resin into an axis in a crosswise direction, then gently stretching the resin into an axis in a lengthwise direction. Examples of a resin that can be used here are a cyclo olefin polymer (COP), polycarbonate (PC), polymethyl methacrylate (PMMA), polystyrene (PS), polyether sulfone (PES), polyphenylene sulfide (PPS), polyethylene terephthalate (PET), polyethylene naphthalate (PEN), polypropylene (PP), polyphenylene oxide (PPO), polyarylate (PAR), polyimide (PI), polytetrafluoroethylene (PTFE) and the like.

Note that the film in which liquid crystals are hybrid-oriented may a film obtained by using a triacetylcellulose (TAC) film as a base and hybrid-orienting discotic liquid crystals or nematic liquid crystals. The retardation film can be attached to the light-transmitting substrate with the retardation plate attached to the polarizing plate.

Next, in the perspective view shown in FIG. 14B, the first linear polarizing plate 603 and the second linear polarizing plate 604 are arranged in such a way that an absorption axis 651 of the first linear polarizing plate 603 and an absorption axis 652 of the second linear polarizing plate 604 should be parallel. This parallel state is referred to as parallel Nicols.

The stacked polarizing plates in this manner are arranged such that they should be in a parallel Nicols state.

Note that transmission axes exist in the direction orthogonal to the absorption axes based on the characteristics of the polarizing plates. Thus, a state in which the transmission axes are parallel to each other can also be referred to as parallel Nicols.

Since arrangement of the stacked polarizing plates is done such that their absorption axes of the stacked polarizing plates are in a parallel Nicols state, black luminance can be reduced. Consequently, the contrast ratio of the display device can be increased.

Moreover, in the present invention, since the retardation film is used, reflection can be suppressed.

In addition, this embodiment mode can be freely combined with any of other embodiment modes and other examples in this specification, if necessary.

### Embodiment Mode 12

Embodiment Mode 12 will describe a specific structure of a reflective type liquid crystal display device described in Embodiment Mode 11.

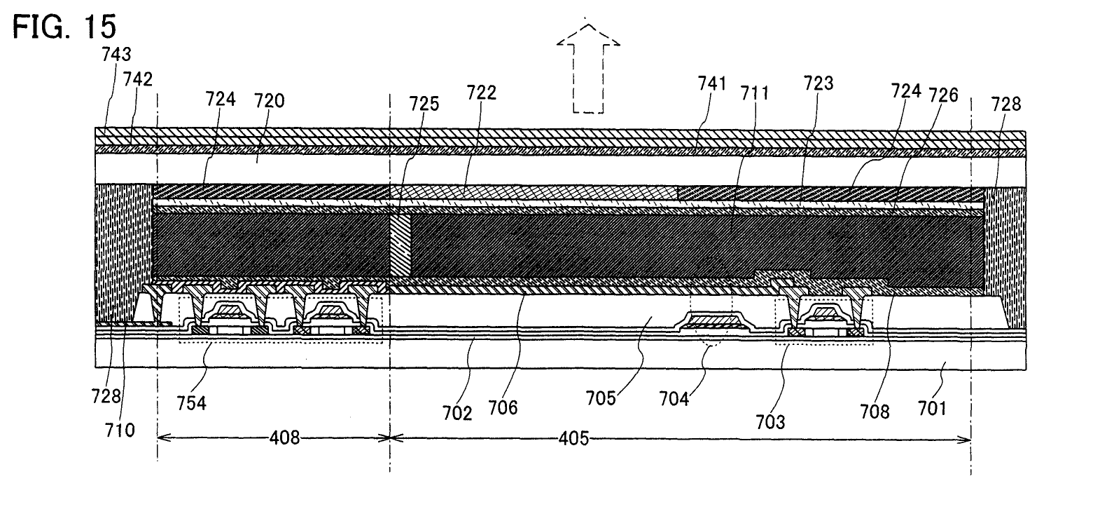

FIG. 15 shows a cross sectional view of a reflective type liquid crystal display device provided with stacked polarizers.

The reflective type liquid crystal display device shown in this embodiment mode includes the pixel portion 405 and the driver circuit portion 408. In the pixel portion 405 and the driver circuit portion 408, a base film 702 is provided over a substrate 701. A substrate similar to the substrate used in Embodiment Mode 11 can be used for the substrate 701. It is concerned that a substrate formed from a synthetic resin generally has a lower allowable temperature limit than other substrates. However, a substrate with high heat resistance is adopted in a manufacturing process first and the substrate is replaced by a substrate formed from a synthetic resin, thereby making it possible to employ such a substrate formed from a synthetic resin.

The pixel portion 405 is provided with a transistor as a switching element through the base film 702. In this embodiment mode, a thin film transistor (TFT) is used as the transistor, which is referred to as a switching TFT 703.

There are many methods for forming TFTs which are used for the switching TFT 703 and the driver circuit portion 408. For example, a crystalline semiconductor film is used as an active layer. A gate electrode is provided over the crystalline semiconductor film with a gate insulating film interposed therebetween. An impurity element can be added to the crystalline semiconductor film which serves as the active layer by using the gate electrode as a mask to form an impurity region. Since an impurity element is added using the gate electrode as a mask in this manner, a mask for adding the impurity element is not required to be additionally formed. The gate electrode may have a single layer structure or a stacked structure.

Note that the TFT may be a top gate type TFT or a bottom gate type TFT, and may be formed as appropriate

An impurity region can be formed as a high concentration impurity region and a low concentration impurity region by controlling the concentration thereof. A structure of such a TFT having a low concentration impurity region is referred to as an LDD (Lightly Doped Drain) structure. The low concentration impurity region can be formed so as to overlap with the gate electrode. A structure of such a TFT is referred to as a GOLD (Gate Overlapped LDD) structure in this specification.

FIG. 15 shows the switching TFT 703 having a GOLD structure. The polarity of the switching TFT 703 is an n-type by using phosphorus (P) or the like for an impurity region thereof. In the case of forming a p-type TFT, boron (B) or the like may be added.

After that, a protective film which covers the gate electrode or the like is formed. A dangling bond in the crystalline semiconductor film can be terminated by a hydrogen element mixed in the protective film.

Further, in order to improve planarity more, an interlayer insulating film 705 may be formed. The interlayer insulating film 705 may be formed from an organic material or an inorganic material, or formed using a stacked structure of these.

Opening portions are formed in the interlayer insulating film 705, the protective film, and the gate insulating film; and a wiring connected to the impurity regions is formed. In this manner, the switching TFT 703 can be formed. Note that the present invention is not limited to the structure of the switching TFT 703.

Then, a pixel electrode 706 connected to the wiring is formed.

Further, a capacitor element 704 can be formed at the same time as the switching TFT 703. In this embodiment mode, the capacitor element 704 is formed from a stack of a conductive film formed at the same time as the gate electrode, the protective film, the interlayer insulating film 705, and the pixel electrode 706.

In addition, the pixel portion and the driver circuit portion can be formed over the same substrate by using a crystalline semiconductor film. In that case, thin film transistors in the pixel portion and thin film transistors of the driver circuit portion 408 are formed at the same time.

The thin film transistors used for the driver circuit portion 408 form a CMOS circuit; and thus, the transistors are referred to as a CMOS circuit 754. Each of the transistors which form the CMOS circuit 754 may have a similar structure to the switching TFT 703. Further, the LDD structure can be used instead of the GOLD structure, and a similar structure is not necessarily required.

An alignment film 708 is formed so as to cover the pixel electrode 706. The alignment film 708 is subjected to a rubbing treatment. This rubbing treatment is not performed in some cases in a mode of a liquid crystal, for example, in a case of a VA mode.

Next, a counter substrate 720 is prepared. A color filter 722 and a black matrix (BM) 724 can be provided on an inner side of the counter substrate 720, that is, on the side which is in contact with a liquid crystal. The color filter 722 and the black matrix 724 can be formed by known methods; however, a droplet discharging method (representatively an ink-jetting method) by which a predetermined material is dropped can eliminate the waste of the material.

Further, the color filter 722 is provided in a region where the switching TFT 703 is not provided. That is to say, the color filter 722 is provided to face a light-transmitting region, i.e., an opening portion region. Note that the color filter 722 may be formed from materials which exhibit red (R), green (G), and blue (B) in the case where the liquid crystal display device performs full-color display, and a material which exhibits at least one color in the case of mono-color display.

Note that the color filter is not provided in some cases when a successive additive color mixing method (field sequential method) in which color display is performed by time division is employed.

The black matrix 724 is provided to reduce reflection of external light due to wirings of the switching TFT 703 and the CMOS circuit 754. Therefore, the black matrix 724 is provided so as to overlap with the switching TFT 703 and the CMOS circuit 754. Note that the black matrix 724 may be provided so as to overlap with the capacitor element 704. Accordingly, reflection on a metal film constituting a part of the capacitor element 704 can be prevented.

Then, a counter electrode 723 and an alignment film 726 are provided. The alignment film 726 is subjected to a rubbing treatment.

Note that the pixel electrode 706 is formed from a reflective conductive material. Such a reflective conductive material can be selected from a metal such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), or silver (Ag), an alloy thereof, or a metal nitride thereof. External light is emitted toward the upper side of the switching TFT 703 and the CMOS circuit 754, by being reflected on the pixel electrode 706 which is a reflective electrode, and emitted to the counter substrate 720 side.

In addition, for the wiring included in the TFT and the gate electrode, a similar material to the pixel electrode 706 may be used.

The counter electrode 723 can be formed from a light transmitting conductive material. Such a light transmitting conductive material can be selected from indium tin oxide (ITO), a conductive material in which zinc oxide (ZnO) is mixed in indium oxide, a conductive material in which silicon oxide (SiO₂) is mixed in indium oxide, organic indium, organotin, or the like.

Such a counter substrate 720 is attached to the substrate 701 using a sealing material 728. The sealing material 728 can be formed on the substrate 701 or the counter substrate 720 by using a dispenser or the like. Further, a spacer 725 is provided in a part of the pixel portion 405 and the driver circuit portion 408 in order to keep an interval between the substrate 701 and the counter substrate 720. The spacer 725 has a columnar shape, a spherical shape, or the like.

A liquid crystal 711 is injected between the substrate 701 and the counter substrate 720 attached to each other in this manner. It is preferable to inject the liquid crystal in vacuum. The liquid crystal 711 can be formed by a method other than the injecting method. For example, the liquid crystal 711 may be dropped and then the counter substrate 720 may be attached thereto. Such a dropping method is preferably employed when using a large substrate to which the injecting method cannot be applied easily.

The liquid crystal 711 includes liquid crystal molecules of which tilt is controlled by the pixel electrode 706 and the counter electrode 723. Specifically, the tilt of the liquid crystal molecules is controlled by a voltage applied to the pixel electrode 706 and the counter electrode 723. Such a control is performed using a control circuit provided in the driver circuit portion 408. Note that the control circuit is not necessarily formed over the substrate 701, and a circuit connected through a connecting terminal 710 may be used. In this case, an anisotropic conductive film containing conductive microparticles can be used so as to be connected to the connecting terminal 710. Further, the counter electrode 723 may be electrically connected to a part of the connecting terminal 710 so as to make a potential of the counter electrode 723 common.

In addition, a structure in which polarizing plates are stacked as shown in FIG. 2A is used as polarizers in this embodiment mode. Naturally, the stacked polarizers shown in FIG. 2B and FIG. 2C may also be used.

The counter substrate 720 is provided with a retardation plate 741, and a polarizing plate 742 and a polarizing plate 743 which are stacked as a polarizing plates having a stacked structure, which are sequentially provided from the substrate side. The stacked polarizing plates and the retardation plate 741 can be attached to each other and bonded to the counter substrate 720. At this time, the polarizing plate 742 and the polarizing plate 743 which are stacked are attached to be in a parallel Nicols state.

Extinction coefficients of the polarizing plate 742 and the polarizing plate 743 may have the same wavelength distribution.

FIG. 15 shows the example in which two polarizing plates are stacked for one substrate; however, three or more polarizing plates may be stacked.

The contrast ratio can be increased by providing the stacked polarizing plates. By using the retardation film, reflection to the display device can be suppressed.

Note that this embodiment mode can be combined with Embodiment Mode 11, if necessary.

In addition, this embodiment mode can be freely combined with any of other embodiment modes and other examples in this specification, if necessary.

### Embodiment Mode 13

Embodiment Mode 13 will describe a liquid crystal display device which has stacked polarizing plates, and which uses a TFT having an amorphous semiconductor film, which is different from Embodiment Mode 12.

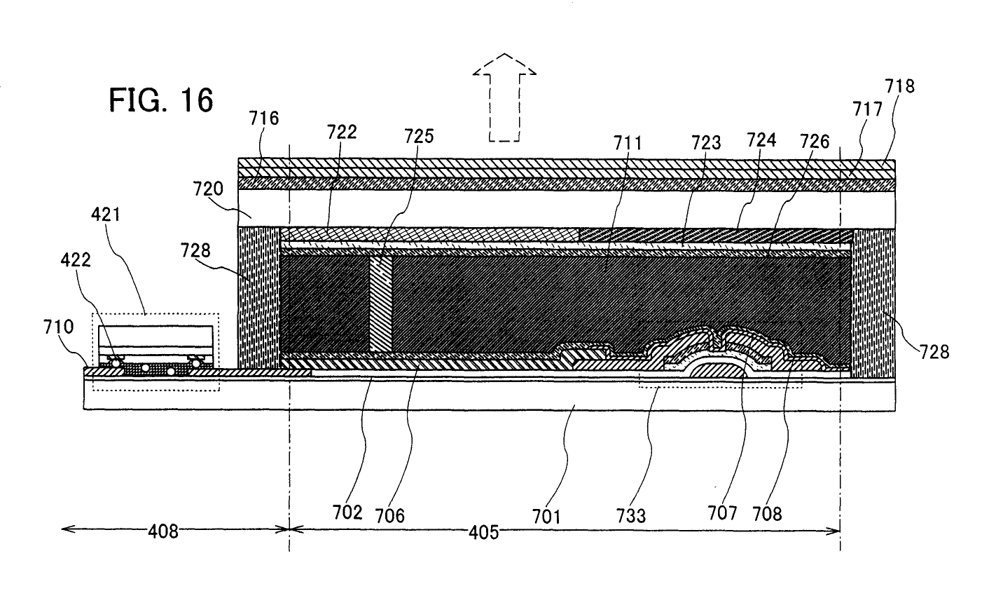

In FIG. 16, a structure of a reflective type liquid crystal display device including a transistor using an amorphous semiconductor film (hereinafter referred to as an amorphous TFT) as a switching element is described.

The pixel portion 405 is provided with a switching TFT 733 including an amorphous TFT. The amorphous TFT can be formed by a known method. In the case of a channel etch type, for example, a gate electrode is formed over the base film 702, and a gate insulating film which covers the gate electrode, an amorphous semiconductor film, an n-type semiconductor film, a source electrode and a drain electrode are formed. By using the source electrode and the drain electrode, an opening portion is formed in the n-type semiconductor film. At this time, a part of the amorphous semiconductor film is removed, which is called a channel etch type. Then, a protective film 707 is formed and the amorphous TFT is obtained. In addition, the amorphous TFT also includes a channel protective type, and when an opening portion is formed in the n-type semiconductor film by using the source electrode and the drain electrode as a mask, a protective film is provided such that the amorphous semiconductor film is not removed. Other structures can be similar to the channel etch type.

The alignment film 708 is formed similarly to FIG. 15, and the alignment film 708 is subjected to a rubbing treatment. This rubbing treatment is not performed in accordance with a mode of a liquid crystal.

The counter substrate 720 is prepared and attached by using the sealing material 728 similarly to FIG. 15. By filling a space between the counter substrate 720 and the substrate 701 with the liquid crystal 711, a reflective type liquid crystal display device can be formed.

On the counter substrate 701 side, a retardation plate 716, a polarizing plate 717 and a polarizing plate 718 which are stacked are sequentially provided from the substrate side. The polarizing plate 717 and the polarizing plate 718 which are stacked and the retardation plate 716 can be attached to each other and bonded to the counter substrate 720. At this time, the polarizing plate 717 and the polarizing plate 718 which are stacked are attached to each other so as to be in a parallel Nicols state.

The extinction coefficients of the polarizing plate 742 and the polarizing plate 743 may have the same wavelength distribution.

FIG. 16 shows the example in which two polarizing plates are stacked for one substrate; however, three or more polarizing plates may be stacked.

The contrast ratio can be increased by arranging the stacked polarizing plates. By using the retardation plate, reflection to the display device can be suppressed.

In the case of forming a liquid crystal display device by using an amorphous TFT as the switching TFT 733 in this manner, the IC 421 formed using a silicon wafer can be mounted as a driver on the driver circuit portion 408 in consideration of operating performance. For example, a signal to control the switching TFT 733 can be supplied by connecting a wiring of the IC 421 and a wiring connected to the switching TFT 733 by using an anisotropic conductor having the conductive microparticle 422. Note that a mounting method of the IC is not limited to this, and the IC may be mounted by a wire bonding method.

Further, the IC can be connected to a control circuit through the connecting terminal 710. At this time, an anisotropic conductive film having the conductive microparticle 422 can be used to connect the IC to the connecting terminal 710.

Since the other structures are similar to those in FIG. 15, description thereof is omitted here.

Note that this embodiment mode can be combined with any of Embodiment Mode 11 and Embodiment Mode 12, if necessary.

In addition, this embodiment mode can be freely combined with any of other embodiment modes and other examples in this specification, if necessary.

### Embodiment Mode 14

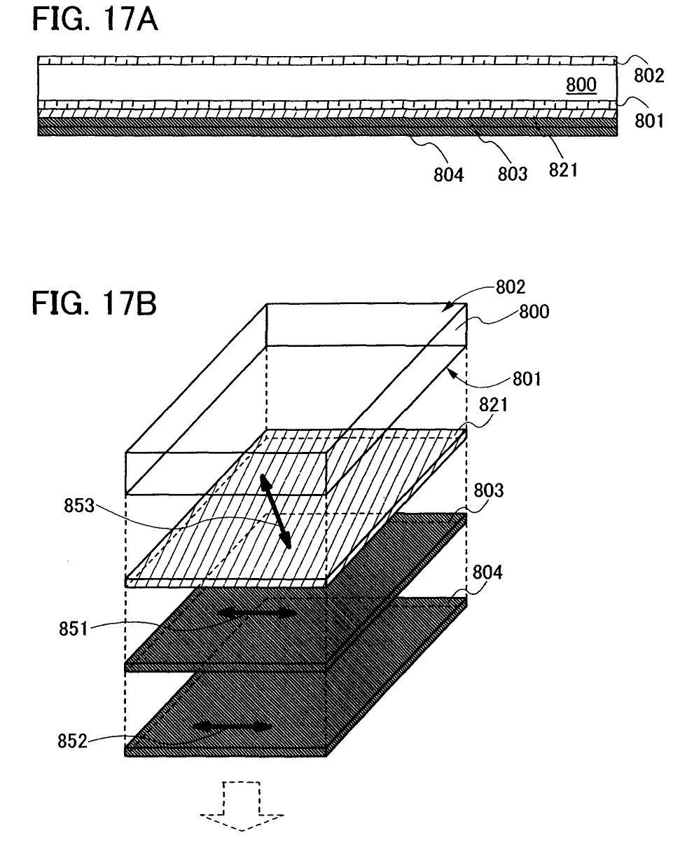

Embodiment Mode 14 will describe a reflective type liquid crystal display device which has a structure different from those in Embodiment Mode 11 to Embodiment Mode 13 with reference to FIGS. 17A, 17B, 18, and 19.

However, elements denoted by the same reference numerals as those in FIGS. 14A and 14B, 15, and 16 are similar ones to the elements shown in FIGS. 14A and 14B, 15, and 16, and thus, only different elements are described.

In a reflective type liquid crystal display device in FIGS. 17A and 17B, a layer 800 including a liquid crystal element is interposed between a first substrate 801 and a second substrate 802 which are arranged to be opposite to each other.

On the outer side of the substrate 801, that is, on a side which is not in contact with the layer 800 including the liquid crystal element from the substrate 801, a retardation plate and stacked polarizing plates are sequentially provided. On the first substrate 801 side, a retardation plate 821, a first polarizing plate 803, and a second polarizing plate 804 are sequentially provided. The first polarizing plate 803 and the second polarizing plate 804 are arranged in such a way that an absorption axis 851 of the first polarizing plate 803 and an absorption axis 852 of the second polarizing plate 804 should be parallel. A slow axis of the retardation plate 821 is denoted by reference numeral 853. External light passes through the second polarizing plate 804, the second polarizing plate 803, the retardation plate 821, and the substrate 801, and then enters the layer 800 including the liquid crystal element. The light is reflected on a reflective material provided for the second substrate 802, so that display is performed.

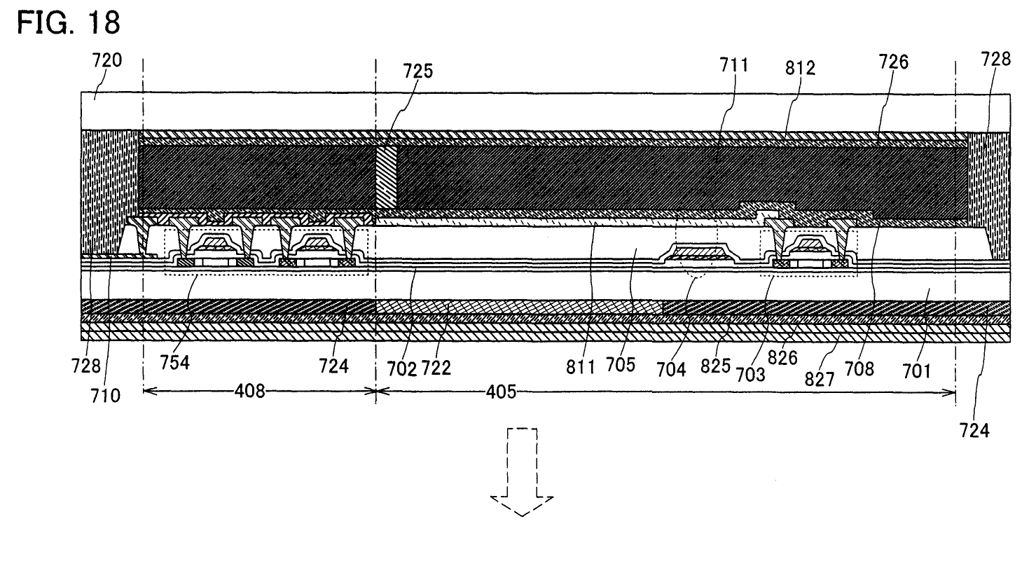

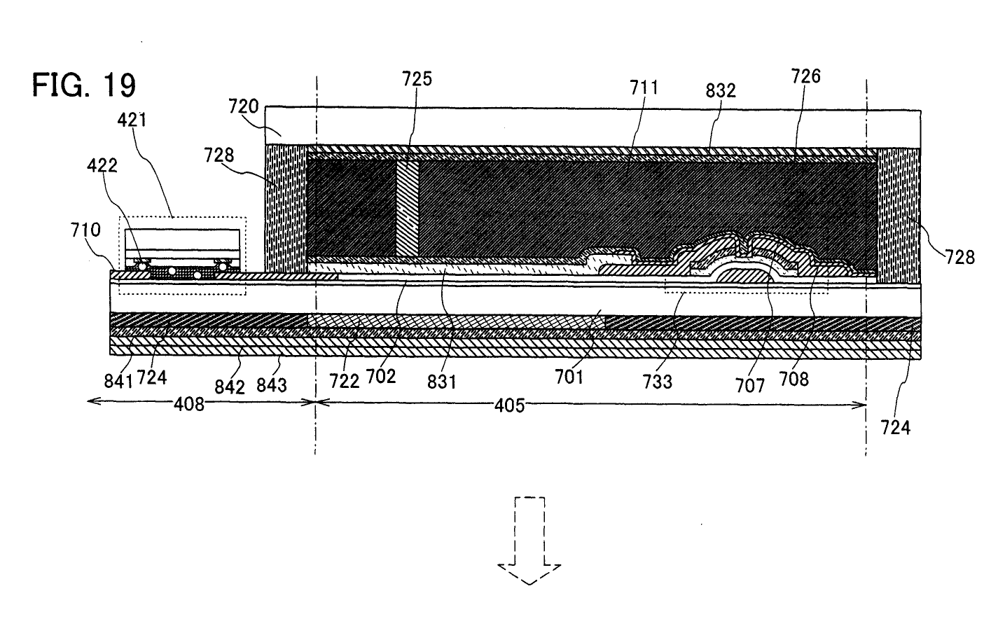

A specific structure of a reflective type liquid crystal display device in this embodiment mode is described with reference to FIGS. 18 and 19. Note that description of FIG. 15 can be applied to FIG. 18 and description of FIG. 16 can be applied to FIG. 19. Similar ones are described with the same reference numerals.

FIG. 18 shows a reflective type liquid crystal display device using a TFT having a crystalline semiconductor film as a switching element. FIG. 19 shows a reflective type liquid crystal device using a TFT having an amorphous semiconductor film as a switching element.

In FIG. 18, a pixel electrode 811 connected to the switching TFT 703 is formed from a light transmitting conductive material. As such a light transmitting conductive material, a material similar to the counter electrode 723 in Embodiment Mode 12 can be used.

A counter electrode 812 is formed from a reflective conductive material. As such a reflective conductive material, a material similar to the pixel electrode 706 in Embodiment Mode 2 can be used.

The color filter 722 and the black matrix 724 are provided on a surface opposite to a surface of the substrate 701 provided with a TFT. Further, a retardation plate 825, a first polarizing plate 826, and a second polarizing plate 827 are stacked.

In FIG. 19, a pixel electrode 831 connected to the switching TFT 733 is formed of a light transmitting conductive material. As such a light transmitting conductive material, a material similar to the counter electrode 723 in Embodiment Mode 12 can be used.

A counter electrode 832 is formed from a reflective conductive material. As such a reflective conductive material, a material similar to the pixel electrode 706 in Embodiment Mode 12 can be used

The color filter 722 and the black matrix 724 are provided on a surface opposite to a surface of the substrate 701 provided with a TFT. Further, a retardation plate 841, a first polarizing plate 842, and a second polarizing plate 843 are stacked.

The extinction coefficients of the polarizing plate 842 and the polarizing plate 843 may have the same wavelength distribution.

FIGS. 17A, 17B, 18, and 19 show the examples in which two polarizing plates are stacked for one substrate; however, three or more polarizing plates may be stacked.

Note that the structure in which stacked polarizing plates (see FIG. 2A) is used as stacked polarizers is employed in this embodiment mode. However, the structures shown in FIG. 2B and FIG. 2C may also be used.

Note that this embodiment mode can be combined with Embodiment Mode 11 to Embodiment Mode 13, if necessary.

In addition, this embodiment mode can be freely combined with any of other embodiment modes and other examples in this specification, if necessary.

### Embodiment Mode 15

Embodiment Mode 15 will describe operation of each circuit or the like included in the liquid crystal display devices in Embodiment Mode 4 to Embodiment Mode 14.

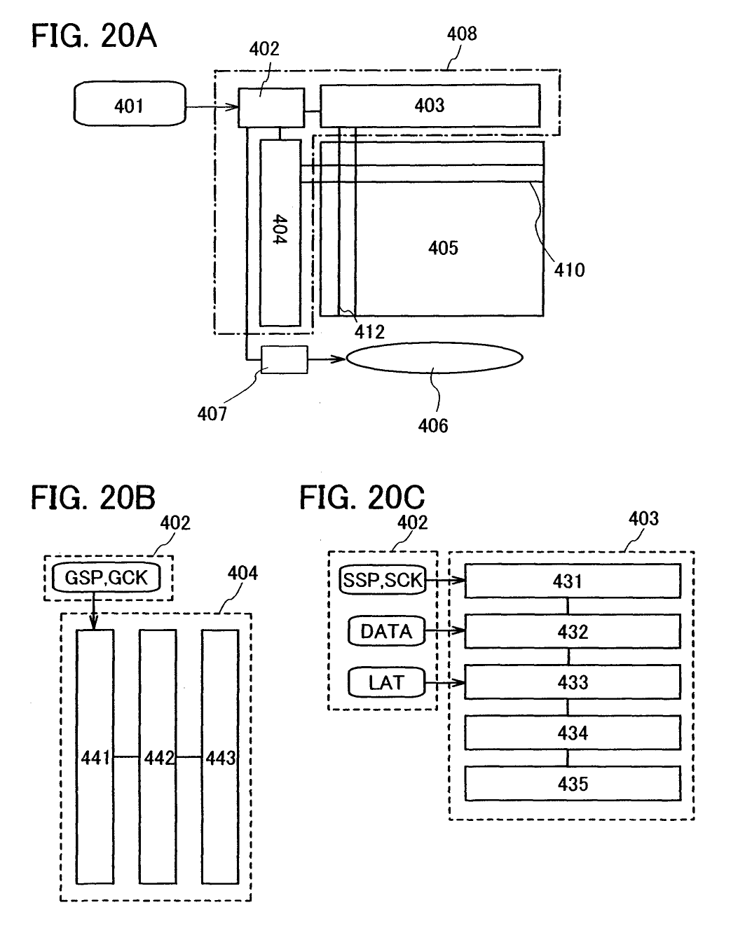

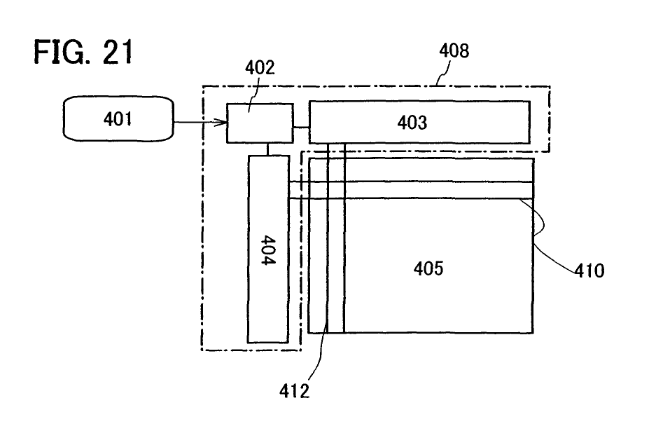

FIGS. 20A to 20C, and 21 show system block diagrams of the pixel portion 405 and the driver circuit portion 408 of a liquid crystal display device.

The pixel portion 405 includes a plurality of pixels. At intersection regions of signal lines 412 and scanning lines 410, which form each pixel, switching elements are provided. Application of a voltage for controlling a tilt of a liquid crystal molecule can be controlled by the switching element. A structure in which a switching element is provided at an intersection region is called an active structure. The pixel portion of the present invention is not limited to an active structure like this, and may have a passive structure. A passive structure does not have a switching element in each pixel; therefore, the manufacturing process is simple.

The driver circuit portion 408 includes a control circuit 402, a signal line driver circuit 403, and a scanning line driver circuit 404. The control circuit 402 includes a function of performing gray scale control in accordance with the display content of the pixel portion 405. Therefore, the control circuit 402 inputs generated signals to the signal line driver circuit 403 and the scanning line driver circuit 404. Then, when a switching element is selected by the scanning line driver circuit 404 through the scanning line 410, a voltage is applied to a pixel electrode of the selected intersection region. The value of the voltage is determined based on a signal inputted from the signal line driver circuit 403 through the signal line.

As for the transmissive type liquid crystal display devices shown in FIGS. 6, 7, 9, and 10, in the control circuit 402 shown in FIG. 20A, a signal which controls electrical power supplied to a lighting means 406 is generated, and is inputted to a power source 407 of the lighting means 406. The backlight unit shown in FIGS. 13A to 13D can be used for the lighting means. Further, a front light can be used for a lighting means instead of the backlight. A front light refers to a plate-like light unit that is fitted in front of a pixel portion and is formed from a luminous body which illuminates the whole screen and a light-guiding body. By using such a lighting means, the pixel portion can be illuminated evenly with low power consumption.

On the other hand, in the reflective type liquid crystal display devices shown in FIGS. 15, 16, 18, and 19, a lighting means is not necessarily provided; therefore, the structure shown in FIG. 21 may be used.

The scanning line driver circuit 404 as shown in FIG. 20B includes a shift register 441, a level shifter 442, and a circuit which functions as a buffer 443. Signals such as a gate start pulse (GSP) and a gate clock signal (GCK) are inputted to the shift register 441. Note that the scanning line driver circuit of the present invention is not limited to the structure shown in FIG. 20B.

Further, as shown in FIG. 20C, the signal line driver circuit 403 includes a shift register 431, a first latch 432, a second latch 433, a level shifter 434, and a circuit which functions as a buffer 435. The circuit which functions as the buffer 435 is a circuit which has a function of amplifying weak signals, and includes an operational amplifier or the like. A signal such as a start pulse (SSP) is inputted to the level shifter 434, and data (DATA) such as a video signal which is generated based on a video signal 401 is inputted to the first latch 432. Latch (LAT) signals can be held temporarily in the second latch 433, and inputted to the pixel portion 405 all together. This is referred to as line sequential drive. Therefore, when a pixel performs dot sequential drive rather than line sequential drive, it is not necessary to include the second latch. Thus, the signal line driver circuit of the present invention is not limited to the structure shown in FIG. 20C.

The signal line driver circuit 403, the scanning line driver circuit 404, and the pixel portion 405 can be formed from semiconductor elements provided over the same substrate. The semiconductor element can be formed using a thin film transistor provided over a glass substrate. In that case, a crystalline semiconductor film is preferably used for the semiconductor element. Since a crystalline semiconductor film has good electrical characteristics, in particular, high mobility, it can form a circuit included in a driver circuit portion. Further, the signal line driver circuit 403 and the scanning line driver circuit 404 can be mounted on the substrate using an IC (Integrated Circuit) chip. In that case, an amorphous semiconductor film can be used for the semiconductor element of the pixel portion (see the above embodiment modes).

Since stacked polarizers are provided in such a liquid crystal display device, a contrast ratio can be increased. That is, the contrast ratio of the light from the lighting means which is controlled by the control circuit and reflected light can be increased by the stacked polarizers.

In addition, this embodiment mode can be freely combined with any of other embodiment modes and other examples in this specification, if necessary.

### Embodiment Mode 16

Embodiment Mode 16 will describe a concept of a display device including a light emitting element of the present invention.

In a structure of the present invention, an element utilizing electroluminescence (an electroluminescent element), an element utilizing plasma, and an element utilizing field emission are given as a light emitting element. The electroluminescent element can be divided into an organic EL element and an inorganic EL element depending on a material to be applied. A display device having such a light emitting element is also referred to as a light emitting device. In this embodiment mode, an electroluminescent element is used as a light emitting element.

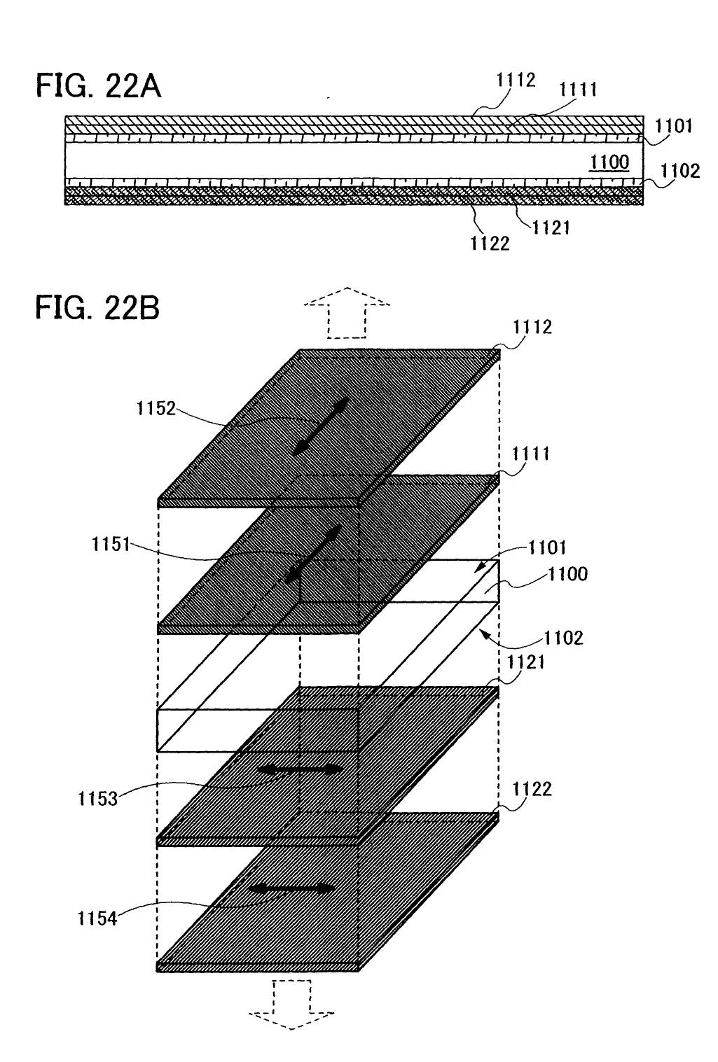

As shown in FIGS. 22A and 22B, a layer 1100 including an electroluminescent element is interposed between a first substrate 1101 and a second substrate 1102 which are arranged to be opposite to each other. Note that FIG. 22A shows a cross sectional view of a display device of this embodiment mode, and FIG. 22B shows a perspective view of the display device of this embodiment mode.

In FIG. 22B, light from the electroluminescent element can be emitted to the first substrate 1101 side and the second substrate 1102 side (in directions indicated by dashed arrows). Light-transmitting substrates are used for the first substrate 1101 and the second substrate 1102. As such light-transmitting substrate, for example, a glass substrate such as barium borosilicate glass or alumino borosilicate glass, a quartz substrate, or the like can be used. Further, a substrate formed from a synthetic resin having flexibility such as plastic typified by polyethylene-terephthalate (PES), polyethylene naphthalate (PEN), polyethersulfone (PES), or polycarbonate (PC), or acrylic can be used for the light-transmitting substrates.

Stacked polarizers are provided on the outer sides of the first substrate 1101 and the second substrate 1102, namely on the sides which are not in contact with the layer 1100 including the electroluminescent element. Light emitted from the electroluminescent element is linearly polarized by the polarizers. That is, the stacked polarizers can be referred to as a linear polarizer having a stacked structure. The stacked polarizers indicate a state where two or more polarizers are stacked. In this embodiment mode, a display device in which two polarizers are stacked is exemplified, and the two polarizers to be stacked are stacked in contact with each other as shown in FIG. 22A.

Embodiment Mode 2 can be applied to the stacked structure of the polarizers like this. In this embodiment mode, the structure shown in FIG. 2A is used as the stacked polarizers; however, the structure shown in FIG. 2B or FIG. 2C may also be used.

In FIGS. 22A and 22B, the examples in which two polarizers are stacked are shown; however, two or more polarizers may be stacked.

On the outer side of the first substrate 1101, a first polarizing plate 1111 and a second polarizing plate 1112 are sequentially provided as a polarizing plate having a stacked structure. The first polarizing plate 1111 and the second polarizing plate 1112 are arranged in such a way that an absorption axis 1151 of the first polarizing plate 1111 and an absorption axis 1152 of the second polarizing plate 1112 become parallel. That is, the first polarizing plate 1111 and the second polarizing plate 1112, namely the polarizing plate having the stacked structure, are arranged such that they are in a parallel Nicols state.

On the outer side of the second substrate 1102, a third polarizing plate 1121 and a fourth polarizing plate 1122 are sequentially provided as a polarizing plate having a stacked structure. The third polarizing plate 1121 and the fourth polarizing plate 1122 are arranged in such a way that an absorption axis 1153 of the third polarizing plate 1121 and an absorption axis 1154 of the fourth polarizing plate 1122 become parallel. That is, the third polarizing plate 1121 and the fourth polarizing plate 1122, namely the polarizing plate having the stacked structure, are arranged such that they are in a parallel Nicols state.

The absorption axis 1151 (and the absorption axis 1152) of the polarizing plate having the stacked structure provided over the first substrate 1101, and the absorption axis 1153 (and the absorption axis 1154) of the polarizing plate having the stacked structure provided for the second substrate 1102 are orthogonal to each other. That is, the polarizing plate having the stacked structure and the polarizing plate having the stacked structure, namely stacked polarizing plates which are opposite to each other, are arranged to be in a crossed Nicols state.

These polarizing plates 1111, 1112, 1121, and 1122 can be formed from known materials. For example, a structure can be used, in which an adhesive surface, TAC (triacetylcellulose), a mixed layer of PVA (polyvinyl alcohol) and a dichroic pigment, and TAC are sequentially stacked from the substrate side. The dichroic pigment includes iodine and dichromatic organic dye. The polarizing plate is sometimes referred to as a polarizing film based on the shape.

Note that a transmission axis exists in a direction orthogonal to the absorption axis based on the characteristics of the polarizing plate. Thus, a state in which the transmission axes are parallel to each other can also be referred to as parallel Nicols.

Since the polarizing plates are stacked to be in a parallel Nicols state, light leakage in the absorption axis direction can be reduced. Further, polarizing plates each having a stacked structure which are opposite to each other via a layer including an electroluminescent element are arranged to be in a crossed Nicols state. By using such stacked polarizing plates, light leakage can be reduced, compared to a structure in which a pair of single polarizing plates is arranged in a crossed Nicols state. Consequently, the contrast ratio of the display device can be increased.

The extinction coefficients of the polarizing plate 1111, 1112, 1121, and 1122 may have the same wavelength distribution.

In addition, this embodiment mode can be freely combined with any of other embodiment modes and other examples in this specification, if necessary.

### Embodiment Mode 17

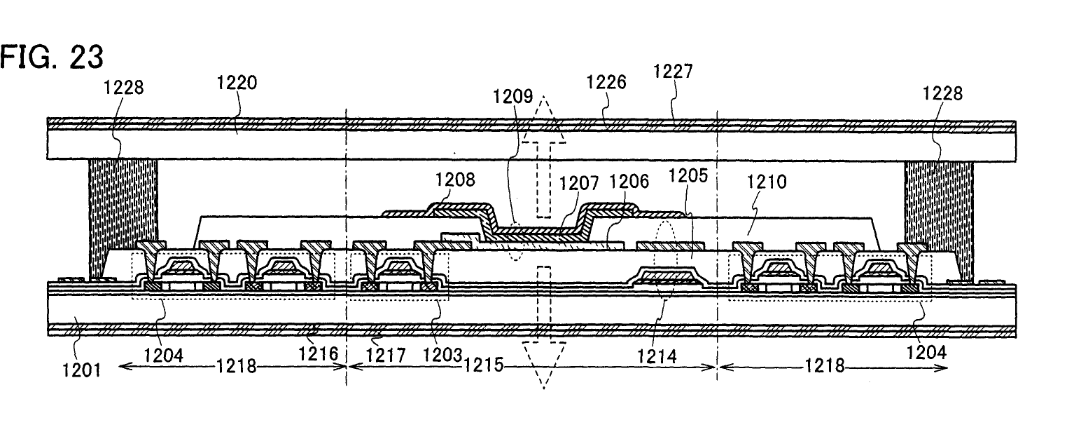

Embodiment Mode 17 will exemplify a cross sectional view of a display device of the present invention with reference to FIG. 23.

A thin film transistor is formed over a substrate (hereinafter referred to as an insulating substrate) 1201 having an insulating surface with an insulating layer interposed therebetween. The thin film transistor (also referred to as a TFT) includes a semiconductor layer processed into a predetermined shape, a gate insulating layer which covers the semiconductor layer, a gate electrode provided over the semiconductor layer with the gate insulating layer interposed therebetween, and a source electrode or drain electrode connected to an impurity layer in the semiconductor film.

A material used for the semiconductor layer is a semiconductor material having silicon, and its crystalline state may be any of amorphous, microcrystalline, and crystalline. An inorganic material is preferably used for the insulating layer typified by a gate insulating film, and silicon nitride or silicon oxide can be used. The gate electrode and the source electrode or drain electrode may be formed from a conductive material, and tungsten, tantalum, aluminum, titanium, silver, gold, molybdenum, copper, or the like is included.

The display device in this embodiment mode can be roughly divided into a pixel portion 1215 and a driver circuit portion 1218. A thin film transistor 1203 provided in the pixel portion 1215 is used as a switching element, and a thin film transistor 1204 provided in the driver circuit portion 1218 is used as a CMOS circuit. In order to use the driver circuit portion 1218 as a CMOS circuit, it is formed from a p-channel TFT and an N-channel TFT. The thin film transistor 1203 can be controlled by the CMOS circuit provided in the driver circuit portion 1218.

Note that although FIG. 23 shows a top gate type TFT as a thin film transistor, a bottom gate type TFT may be used.

An insulating layer 1205 having a stacked structure or a single layer structure is formed so as to cover the thin film transistor 1203 and the thin film transistor 1204. The insulating layer 1205 can be formed from an inorganic material or an organic material.

As the inorganic material, silicon nitride or silicon oxide can be used. As the organic material, polyimide, acrylic, polyamide, polyimide amide, resist, benzocyclobutene, siloxane, polysilazane, or the like can be used. A skeleton structure of siloxane is formed by the bond of silicon (Si) and oxygen (O), in which an organic group containing at least hydrogen (such as an alkyl group or an aromatic hydrocarbon) is included as a substituent. In addition, a fluoro group may be used as the substituent. Further, a fluoro group and an organic group containing at least hydrogen may be used as the substituent. Polysilazane is formed using a liquid material containing a polymer material having the bond of silicon (Si) and nitrogen (N) as a starting material. If the insulating layer is formed using an inorganic material, a surface thereof follows a depression/projection below. Alternatively, if the insulating layer is formed using an organic material, a surface thereof is planarized. For example, in a case where the insulating layer 1205 is required to have planarity, it is preferable that the insulating layer 1205 be formed using an organic material. Note that, even if an inorganic material is used, planarity can be obtained by forming the material with a thick thickness.

The source electrode or drain electrode is manufactured by forming a conductive layer in an opening portion provided in the insulating layer 1205 or the like. At this time, a conductive layer serving as a wiring over the insulating layer 1205 can be formed. A capacitor element 1214 can be formed from the conductive layer of the gate electrode, the insulating layer 1205, and the conductive layer of the source electrode or drain electrode.

A first electrode 1206 to be connected to either the source electrode or drain electrode is formed. The first electrode 1206 is formed using a material having a light-transmitting property. As the material having a light-transmitting property, indium tin oxide (ITO), zinc oxide (ZnO), indium zinc oxide (IZO), zinc oxide to which gallium is added (GZO), and the like can be given. Even if a non-light transmitting material such as rare-earth metal such as Yb or Er as well as alkali metal such as Li or Cs, alkaline earth metal such as Mg, Ca, or Sr, an alloy thereof (Mg:Ag, Al:Li, Mg:In, or the like), and a compound of these (calcium fluoride or calcium nitride), is used, the first electrode 1206 can have a light-transmitting property by being formed to be extremely thin. Therefore, a non-light transmitting material may be used for the first electrode 1206.

An insulating layer 1210 is formed so as to cover an end portion of the first electrode 1206. The insulating layer 1210 can be formed in a similar manner to the insulating layer 1205. An opening portion is provided in the insulating layer 1210 to cover the end portion of the first electrode 1206. An end surface of the opening portion may have a tapered shape, and thus, disconnection of a layer to be formed later can be prevented. For example, in a case where a non-photosensitive resin or a photosensitive resin is used for the insulating layer 1210, a tapered shape can be provided in a side surface of the opening portion in accordance with an exposure condition.

After that, an electroluminescent layer 1207 is formed in the opening portion of the insulating layer 1210. The electroluminescent layer includes a layer including each function, specifically, a hole injecting layer, a hole transporting layer, a light emitting layer, an electron transporting layer, and an electron injecting layer. A boundary of each layer is not necessarily clear, and there may be a case where parts of the boundaries are mixed in each other.

Specific materials for forming the light emitting layer are exemplified hereinafter. When reddish emission is desired to be obtained, 4-dicyanomethylene-2-isopropyl-6-[2-1,1,7,7-tetramethyljulolidin-9-yl)ethenyl]-4H-pyran (abbreviation: DCJI), 4-dicyanomethylene-2-methyl-6-[2-(1,1,7,7-tetramethyljulolidin-9-yl)ethenyl]4H-pyran (abbreviation: DCJT), 4-dicyanomethylene-2-tert-butyl-6-[2-(1,1,7,7-tetramethyljulolidin-9-yl)ethenyl]-4H-pyran (abbreviation: DCJTB), periflanthene, 2,5-dicyano-1,4-bis[2-(10-methoxy-1,1,7,7-tetramethyljulolidin-9-yl)ethenyl]benzene, bis[2,3-bis(4-fluorophenyl)quinoxalinato]iridium(acetylacetonate) (abbreviation: Ir[Fdpq]₂(acac)), or the like can be used for the light emitting layer. However, it is not limited to these materials, and a substance which exhibits emission with a peak from 600 nm to 700 nm in an emission spectrum can be used.

When greenish emission is desired to be obtained, N,N′-dimethylquinacridone (abbreviation: DMQd), coumarin 6, coumarin 545T, tris(8-quinolinolato)aluminum (abbreviation: Alq₃), or the like can be used for the light emitting layer. However, it is not limited to these materials, and a substance which exhibits emission with a peak from 500 nm to 600 nm in an emission spectrum can be used.

When bluish emission is desired to be obtained, 9,10-bis(2-naphthyl)-tert-butylanthracene (abbreviation: t-BuDNA), 9,9′-bianthryl, 9,10-diphenylanthracene (abbreviation: DPA), 9,10-bis(2-naphthyl)anthracene (abbreviation: DNA), bis(2-methyl-8-quinolinolato)-4-phenylphenolato-gallium (abbreviation: BGaq), bis(2-methyl-8-quinolinolato)-4-phenylphenolato-aluminum (abbreviation: BAlq), or the like can be used for the light emitting layer. However, it is not limited to these materials, and a substance which exhibits emission with a peak from 400 nm to 500 nm in an emission spectrum can be used.

When whitish emission is desired to be obtained, a structure can be used, in which TPD (aromatic diamine), 3-44-tert-butylphenyl)-4-phenyl-5-(4-biphenylyl)-1,2,4-triazole (abbreviation: TAZ), tris(8-quinolinolato)aluminum (abbreviation: Alq₃), Alq₃ doped with Nile Red which is a red light emitting pigment, and Alq₃ are stacked by an evaporation method or the like.

Then, a second electrode 1208 is formed. The second electrode 1208 can be formed in a similar manner to the first electrode 1206. A light emitting element 1209 having the first electrode 1206, the electroluminescent layer 1207, and the second electrode 1208 can be formed.

At this time, since the first electrode 1206 and the second electrode 1208 each have a light-transmitting property, light can be emitted in opposite directions from the electroluminescent layer 1207. Such a display device which can emit light in opposite directions can be referred to as a dual emission display device.

Then, the insulating substrate 1201 and a counter substrate 1220 are attached to each other by a sealing material 1228. In this embodiment mode, the sealing material 1228 is provided over a part of the driver circuit portion 1218; therefore, a narrow frame can be attempted. As a matter of course, arrangement of the sealing material 1228 is not limited thereto. The sealing material 1228 may be provided on the outer side of the driver circuit portion 1218.

A space formed by the attachment is filled with an inert gas such as nitrogen and sealed, or filled with a resin material having a light-transmitting property and high hygroscopicity. Accordingly, intrusion of moisture or oxygen, which becomes one factor of deterioration of the light emitting element 1209, can be prevented. Further, a spacer may be provided to keep an interval between the insulating substrate 1201 and the counter substrate 1220, and the spacer may have hygroscopicity. The spacer has a spherical shape or a columnar shape.

The counter substrate 1220 can be provided with a color filter or a black matrix. Even in a case where a single color light emitting layer, for example, a white light emitting layer is used, full-color display is possible by the color filter. Further, even in a case where a light emitting layer of each R, G, and B is used, a wavelength of light to be emitted can be controlled by providing the color filter, and thus, clear display can be provided. By the black matrix, reflection of external light on a wiring or the like can be reduced.

Then, a first polarizing plate 1216 and a second polarizing plate 1217 which are sequentially stacked as a polarizing plate 1219 having a stacked structure are provided on the outer side of the insulating substrate 1201. A third polarizing plate 1226 and a fourth polarizing plate 1227 which are sequentially stacked as a polarizing plate 1229 having a stacked structure are provided on the outer side of the counter substrate 1220. In other words, the polarizing plate 1219 having a stacked structure and the polarizing plate 1229 having a stacked structure are provided on the outer side of the insulating substrate 1201 and on the outer side of the counter substrate 1220, respectively.

At this time, the polarizing plate 1216 and the polarizing plate 1217 are attached to each other so as to be in a parallel Nicols state. The polarizing plate 1226 and the polarizing plate 1227 are also attached to each other so as to be in a parallel Nicols state.

Further, the polarizing plate 1219 having the stacked structure and the polarizing plate 1229 having the stacked structure are arranged to be in a crossed Nicols state.

Consequently, black luminance can be reduced, and the contrast ratio can be increased.

The structure in which polarizing plates are stacked as shown in FIG. 2A is used as a polarizer in this embodiment mode. Naturally, the stacked polarizers shown in FIG. 2B and FIG. 2C may also be used.

Extinction coefficients of the polarizing plate 1216, 1217, 1226 and 1227 preferably have the same wavelength distribution.

FIG. 23 shows the example in which two polarizing plates are stacked for one substrate; however, three or more polarizing plates may be stacked.

In this embodiment mode, a mode is shown, in which the driver circuit portion is also formed over the insulating substrate 1201. However, an IC circuit formed from a silicon wafer may be used for the driver circuit portion. In this case, a video signal or the like from the IC circuit can be inputted to the switching thin film transistor 1203 through a connecting terminal or the like.

Note that this embodiment mode is described using an active type display device. However, stacked polarizing plates can be provided even in a passive type display device. Accordingly, a contrast ratio can be increased.

In addition, this embodiment mode can be freely combined with any of other embodiment modes and other examples in this specification, if necessary.

### Embodiment Mode 18

Embodiment Mode 18 will describe a concept of a display device of the present invention. In this embodiment mode, the display device uses an electroluminescent element as a light emitting element.

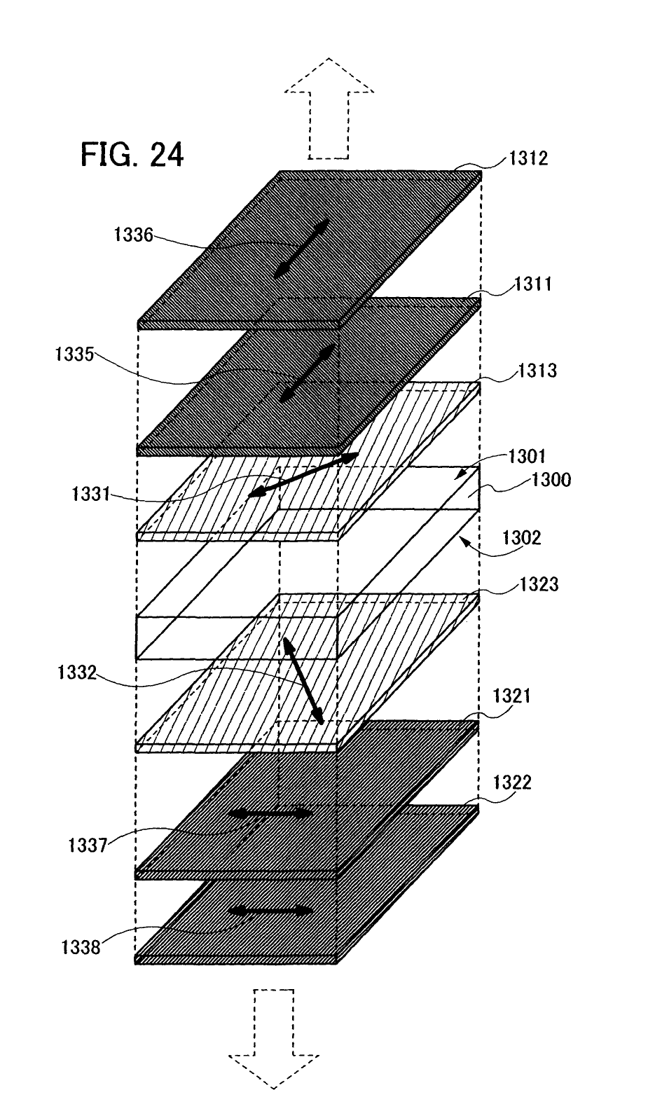

As shown in FIGS. 24A and 24B, a layer 1300 including an electroluminescent element is interposed between a first substrate 1301 and a second substrate 1302 arranged to be opposite to each other. Light from the electroluminescent element can be emitted to the first substrate 1301 side and the second substrate 1302 side (in directions indicated by dashed arrows).

Light-transmitting substrates are used for the first substrate 1301 and the second substrate 1302. As such light-transmitting substrate, for example, a glass substrate such as barium borosilicate glass or alumino borosilicate glass, a quartz substrate, a stainless steel substrate or the like can be used. Further, a substrate formed from a synthetic resin having flexibility such as plastic typified by polyethylene terephthalate (PE), polyethylene naphthalate (PEN), polyethersulfone (PES), or polycarbonate (PC), or acrylic can be used for the light-transmitting substrate.

A retardation plate and stacked polarizers are provided on the outer sides of the first substrate 1301 and the second substrate 1302, namely on the sides which are not in contact with the layer 1300 including the electroluminescent element from the first substrate 1301 and the second substrate 1302, respectively. Note that in this embodiment mode, as the structure of the stacked polarizers, polarizing plates each including one polarizing film shown in FIG. 2A are stacked. Needless to say, the structures shown in FIGS. 2B and 2C may also be used. Light is circularly polarized by the retardation plate and linearly polarized by the polarizing plate. That is, the stacked polarizers can be referred to as a linear polarizer having a stacked structure. The stacked polarizers indicate a state where two or more polarizers are stacked.

A first retardation plate 1313, and a first polarizing plate 1311 and a second polarizing plate 1312 which are stacked as a polarizing plate 1315 having a stacked structure, are sequentially provided on the outer side of the first substrate 1301. In this embodiment mode, quarter-wave plates are used as the retardation plate 1313 and a retardation plate 1323 which is described later.

The retardation plate and the stacked polarizing plates are also collectively referred to as a circularly polarizing plate having stacked polarizing plates (linear polarizing plates). The first polarizing plate 1311 and the second polarizing plate 1312 are arranged in such a way that an absorption axis 1335 of the first polarizing plate 1311 and an absorption axis 1336 of the second polarizing plate 1312 should be parallel. In other words, the first polarizing plate 1311 and the second polarizing plate 1312, namely the polarizing plate 1315 having the stacked structure, are arranged to be in a parallel Nicols state.

A slow axis 1331 of the retardation plate 1313 is arranged to be shifted from the absorption axis 1335 of the first polarizing plate 1311 and the absorption axis 1336 of the second polarizing plate 1312 by 45°.

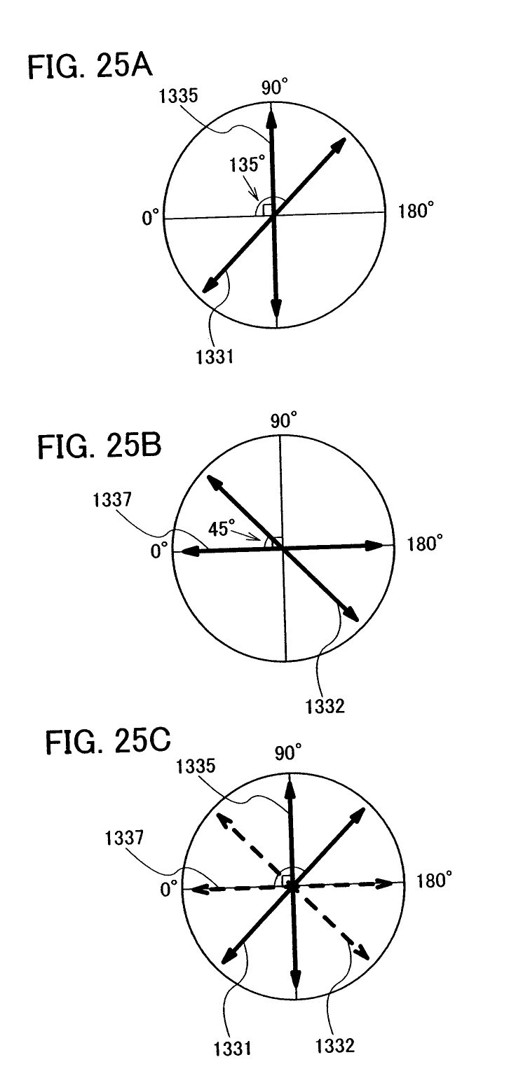

FIG. 25A shows angular deviation between the absorption axis 1335 (and the absorption axis 1336) and the slow axis 1331. The angle formed by the slow axis 1331 and the transmission axes of the stacked polarizing plates 1315 is 135° and the angle formed by the absorption axis 1335 (and the absorption axis 1336) and the transmission axes of the stacked polarizing plates 1315 is 90°, which means the slow axis and the absorption axes are shifted from each other by 45°.

The second retardation plate 1323, and a third polarizing plate 1321 and a fourth polarizing plate 1322 which are stacked as a polarizing plate 1325 having a stacked structure, are sequentially provided on the outer side of the second substrate 1302. The retardation plate and the stacked polarizing plates are also referred to as a circularly polarizing plate having stacked polarizing plates. An absorption axis 1337 of the third polarizing plate 1321 and an absorption axis 1338 of the fourth polarizing plate 1322 are arranged to be parallel to each other. In other words, the third polarizing plate 1321 and the fourth polarizing plate 1322, namely the polarizing plate 1325 having the stacked structure, are arranged to be in a parallel Nicols state.

A slow axis 1332 of the retardation plate 1323 is arranged to be shifted from the absorption axis 1337 of the third polarizing plate 1321 and the absorption axis 1338 of the fourth polarizing plate 1322 by 45°.

FIG. 25B shows angular deviation between the absorption axis 1337 (and the absorption axis 1338) and the slow axis 1332. The angle formed by the slow axis 1332 and the transmission axes of the stacked polarizing plates 1315 is 45° and the angle formed by the absorption axis 1337 (and the absorption axis 1338) and the transmission axes of the stacked polarizing plates 1315 is 0°, which means the slow axis and the absorption axes are shifted from each other by 45°. In other words, the slow axis 1331 of the first retardation plate 1313 is arranged to be shifted by 45° from the absorption axis 1335 of the first linear polarizing plate 1311 (and the absorption axis 1336 of the second linear polarizing plate 1312). The slow axis 1332 of the second retardation plate 1323 is arranged to be shifted by 45° from the absorption axis 1337 of the third linear polarizing plate 1321 (and the absorption axis 1338 of the fourth linear polarizing plate 1322).

In this embodiment mode, the absorption axis 1335 (and the absorption axis 1336) of the polarizing plate 1315 having the stacked structure provided over the first substrate 1301 and the absorption axis 1337 (and the absorption axis 1338) of the polarizing plate 1325 having the stacked structure provided for the second substrate 1302 are orthogonal to each other. In other words, the polarizing plate 1315 having the stacked structure and the polarizing plate 1325 having the stacked structure, namely opposite polarizing plates via the layer 1300 including an electroluminescent element, are arranged to be in a crossed Nicols state.

FIG. 25C shows a state where the absorption axis 1335 and the slow axis 1331 each indicated by a solid line and the absorption axis 1337 and the slow axis 1332 each indicated by a dashed line overlap with each other and are shown in the same circle. FIG. 25C shows that the absorption axis 1335 and the absorption axis 1337 are orthogonal to each other, and the slow axis 1331 and the slow axis 1332 are also orthogonal to each other.

In this specification, it is assumed that the above angle condition is to be satisfied when angular deviation between an absorption axis and a slow axis, an angular deviation between absorption axes, or angular deviation of slow axes is mentioned; however, the angular deviation between the axes may differ from the above-described angles to some extent as long as a similar effect can be obtained.

These polarizing plates 1311, 1312, 1321, and 1322 can be formed from known materials. For example, a structure can be used, in which an adhesive surface, TAC (triacetylcellulose), a mixed layer of PVA (polyvinyl alcohol) and a dichroic pigment, and TAC are sequentially stacked from the substrate side. The dichroicc pigment includes iodine and dichromatic organic dye. The polarizing plate is sometimes referred to as a polarizing film based on the shape.

Note that transmission axes exist in the direction orthogonal to the absorption axes based on the characteristics of the polarizing plates. Therefore, a state in which the transmission axes are parallel to each other can also be referred to as parallel Nicols.

The extinction coefficients of the polarizing plate 1311, 1312, 1321, and 1322 preferably have the same wavelength distribution.

FIG. 24 shows the example in which two polarizing plates are stacked for one substrate; however, three or more polarizing plates may be stacked.

A fast axis exists in the direction orthogonal to the slow axis based on the characteristics of the retardation plate. Therefore, arrangement of the retardation plate and the polarizing plate can be determined using not only the slow axis but also the fast axis. In this embodiment mode, the absorption axis and the slow axis are arranged to be shifted from each other by 45°, in other words, the absorption axis and the fast axis are arranged to be shifted from each other by 135°.

As the circularly polarizing plate, a circularly polarizing plate with a widened band is given. The circularly polarizing plate with a widened band is an object in which a wavelength range in which phase difference (retardation) is 90°, can be widened by stacking several retardation plates. Also in this case, a slow axis of each retardation plate arranged on the outer side of the first substrate 1301 and a slow axis of each retardation plate arranged on the outer side of the second substrate 1302 may be arranged to be 90°, and opposite polarizing plates may be arranged to be in a crossed Nicols state.

In this specification, it is assumed that the above angle range is to be satisfied in a parallel Nicols state and a crossed Nicols state; however, the angular deviation may differ from the above-described angles to some extent as long as a similar effect can be obtained.

Since the stacked polarizing plates are stacked to be in a parallel Nicols state, light leakage in the absorption axis direction can be reduced. Further, polarizing plates opposite to each other via a layer including an electroluminescent element are arranged to be in a crossed Nicols state. The polarizing plates are arranged to be in a crossed Nicols state. Since circularly polarizing plates each having such polarizing plates are provided, light leakage can be further reduced compared to the case in which circularly polarizing plates each having a single polarizing plates are arranged to be in a crossed Nicols state. Accordingly, the contrast ratio of the display device can be increased.

### Embodiment Mode 19

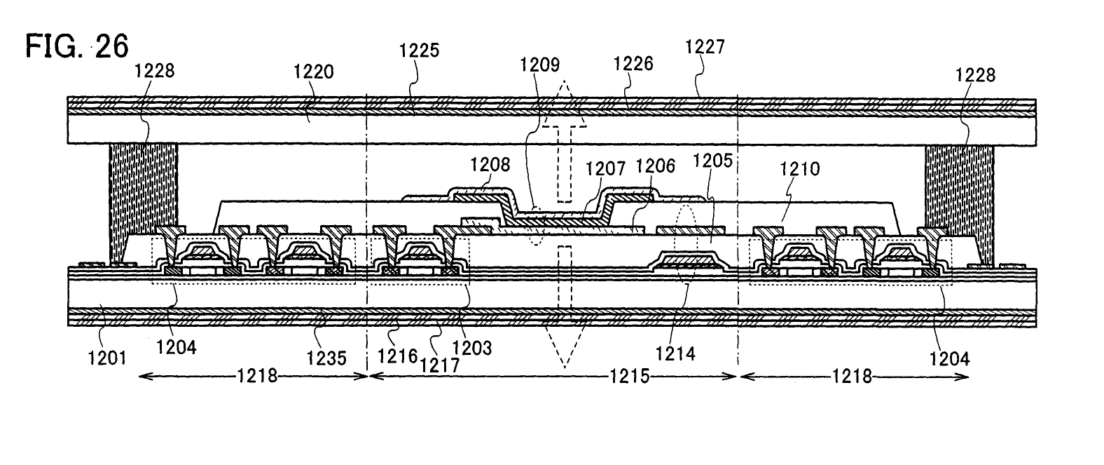

Embodiment Mode 19 will exemplify a cross sectional view of a display device of the present invention with reference to FIG. 26.

Note that elements in a display device shown in FIG. 26 similar to those in FIG. 23 are denoted by the same reference numerals, and description of FIG. 23 can be applied to elements which are not particularly described.

A thin film transistor is formed over the substrate (hereinafter referred to as an insulating substrate) 1201 having an insulating surface with an insulating layer interposed therebetween. The thin film transistor (also referred to as a TFT) includes a semiconductor layer processed into a predetermined shape, a gate insulating layer which covers the semiconductor layer, a gate electrode provided over the semiconductor layer with the gate insulating layer interposed therebetween, and a source electrode or drain electrode connected to an impurity layer in a semiconductor film. A material used for the semiconductor layer is a semiconductor material having silicon, and a crystalline state thereof may be any of amorphous, microcrystalline, and crystalline. An inorganic material is preferably used for the insulating layer typified by a gate insulating film, and silicon nitride or silicon oxide can be used. The gate electrode and the source electrode or drain electrode may be formed from a conductive material, and may include tungsten, tantalum, aluminum, titanium, silver, gold, molybdenum, copper, or the like.

The display device can be roughly divided into the pixel portion 1215 and the driver circuit portion 1218. The thin film transistor 1203 provided in the pixel portion 1215 is used as a switching element, and the thin film transistor 1204 provided in the driver circuit portion is used as a CMOS circuit. In order to use the thin film transistor 1204 as a CMOS circuit, it is formed from a p-channel TFT and an N-channel TFT. The thin film transistor 1203 can be controlled by the CMOS circuit provided in the driver circuit portion 1218.

Note that although FIG. 26 shows a top gate type TFT as a thin film transistor, a bottom gate type TFT may be used.

The insulating layer 1205 having a stacked structure or a single layer structure is formed so as to cover the thin film transistor 1203 and the thin film transistor 1204. The insulating layer 1205 can be formed from an inorganic material or an organic material. As the inorganic material, silicon nitride or silicon oxide can be used. As the organic material, polyimide, acrylic, polyamide, polyimide amide, resist, benzocyclobutene, siloxane, polysilazane, or the like can be used. A skeleton structure of siloxane is formed by the bond of silicon (Si) and oxygen (O), in which an organic group containing at least hydrogen (such as an alkyl group or an aromatic hydrocarbon) is included as a substituent. In addition, a fluoro group may be used as the substituent. Further, a fluoro group and an organic group containing at least hydrogen may be used as the substituent. Polysilazane is formed using a liquid material containing a polymer material having the bond of silicon (Si) and nitrogen (N) as a starting material. If the insulating layer is formed using an inorganic material, a surface thereof follows a depression/projection below. Alternatively, if the insulating layer is formed using an organic material, a surface thereof is planarized. For example, in a case where the insulating layer 1205 is required to have planarity, it is preferable that the insulating layer 1205 be formed using an organic material. Note that, even if an inorganic material is used, planarity can be obtained by forming the material with a thick thickness.

The source electrode or drain electrode is manufactured by forming a conductive layer in an opening portion provided in the insulating layer 1205 or the like. At this time, a conductive layer serving as a wiring over the insulating layer 1205 can be formed. The capacitor element 1214 can be formed from the conductive layer of the gate electrode, the insulating layer 1205, and the conductive layer of the source electrode or drain electrode.

The first electrode 1206 to be connected to either the source electrode or drain electrode is formed. The first electrode 1206 is formed using a material having a light-transmitting property. As the material having a light-transmitting property, indium tin oxide (ITO), zinc oxide (ZnO), indium zinc oxide (IZO), zinc oxide to which gallium is added (GZO), and the like can be given. Even if a non-light transmitting material such as rare-earth metal such as Yb or Er as well as alkali metal such as Li or Cs, alkaline earth metal such as Mg, Ca, or Sr, an alloy thereof (Mg:Ag, Al:Li, Mg:In, or the like), and a compound of these (CaF₂ or calcium nitride), is used, the first electrode 1206 can have a light-transmitting property by being formed to be extremely thin. Therefore, a non-light transmitting material may be used for the first electrode 1206.

The insulating layer 1210 is formed so as to cover an end portion of the first electrode 1206. The insulating layer 1210 can be formed in a similar manner to the insulating layer 1205. An opening portion is provided in the insulating layer 1210 so as to cover the end portion of the first electrode 1206. An end surface of the opening portion may have a tapered shape, and thus, disconnection of a layer to be formed later can be prevented. For example, in a case where a non-photosensitive resin or a photosensitive resin is used for the insulating layer 1210, a tapered shape can be provided in a side surface of the opening portion in accordance with an exposure condition.

After that, the electroluminescent layer 1207 is formed in the opening of the insulating layer 1210. The electroluminescent layer 1207 includes a layer including each function, specifically, a hole injecting layer, a hole transporting layer, a light emitting layer, an electron transporting layer, and an electron injecting layer. A boundary of each layer is not necessarily clear, and there may be a case where parts of the boundaries are mixed.

Specific materials for forming the light emitting layer are exemplified hereinafter. When reddish emission is desired to be obtained, 4-dicyanomethylene-2-isopropyl-6-[(2-(1,1,7,7-tetramethyljulolidin-9-yl)ethenyl]-4H-pyran (abbreviation: DCJTI), 4-dicyanomethylene-2-methyl-6-[2-(1,1,7,7-tetramethyljulolidin-9-yl)ethenyl]-4H-pyran (abbreviation: DCJT), 4-dicyanomethylene-2-tert-butyl-6-[2-(1,1,7,7-tetramethyljulolidin-9-yl)ethenyl]-4H-pyran (abbreviation: DCJTB), periflanthene, 2,5-dicyano-1,4-bis[2-(10-methoxy-1,1,7,7-tetramethyljulolidin-9-yl)ethenyl]benzene, bis[2,3-bis(4-fluorophenyl)quinoxalinato]iridium(acetylacetonate) (abbreviation: Ir[Fdpq]₂(acac)), or the like can be used for the light emitting layer. However, it is not limited to these materials, and a substance which exhibits emission with a peak from 600 nm to 700 nm in an emission spectrum can be used.

When greenish emission is desired to be obtained, N,N′-dimethylquinacridone (abbreviation: DMQd), coumarin 6, coumarin 545T, tris(8-quinolinolato)aluminum (abbreviation: Alq₃), or the like can be used for the light emitting layer. However, it is not limited to these materials, and a substance which exhibits emission with a peak from 500 nm to 600 nm in an emission spectrum can be used.

When bluish emission is desired to be obtained, 9,10-bis(2-naphthyl)-tert-butylanthracene (abbreviation: t-BuDNA), 9,9′-bianthryl, 9,10-diphenylanthracene (abbreviation: DPA), 9,10-bis(2-naphthyl)anthracene (abbreviation: DNA), bis(2-methyl-8-quinolinolato)-4-phenylphenolato-gallium (abbreviation: BGaq), bis(2-methyl-8-quinolinolato)-4-phenylphenolato-aluminum (abbreviation: BAlq), or the like can be used for the light emitting layer. However, it is not limited to these materials, and a substance which exhibits emission with a peak from 400 nm to 500 nm in an emission spectrum can be used.

When whitish emission is desired to be obtained, a structure can be used, in which TPD (aromatic diamine), 3-(4-tert-butylphenyl)-4-phenyl-5-(4-biphenylyl)-1,2,4-triazole (abbreviation: TAZ), tris(8-quinolinolato)aluminum (abbreviation: Alq₃), Alq₃ doped with Nile Red which is a red light emitting pigment, are stacked by an evaporation method or the like.

Then, the second electrode 1208 is formed. The second electrode 1208 can be formed in a similar manner to the first electrode 1206. The light emitting element 1209 having the first electrode 1206, the electroluminescent layer 1207, and the second electrode 1208 can be formed.

At this time, since the first electrode 1206 and the second electrode 1208 each have a light-transmitting property, light can be emitted in opposite directions from the electroluminescent layer 1207. Such a display device which can emit light in opposite directions can be referred to as a dual emission display device.

Then, the insulating substrate 1201 and the counter substrate 1220 are attached to each other by the sealing material 1228. In this embodiment mode, the sealing material 1228 is provided over a part of the driver circuit portion 1218; therefore, a narrow frame can be attempted. As a matter of course, arrangement of the sealing material 1228 is not limited thereto. The sealing material 1228 may be provided on the outer side of the driver circuit portion 1218.

A space formed by the attachment is filled with an inert gas such as nitrogen and sealed, or filled with a resin material having a light-transmitting property and high hygroscopicity. Accordingly, intrusion of moisture or oxygen, which becomes one factor of deterioration of the light emitting element 1209, can be prevented. Further, a spacer may be provided to keep an interval between the insulating substrate 1201 and the counter substrate 1220, and the spacer may have hygroscopicity. The spacer has a spherical shape or a columnar shape.

The counter substrate 1220 can be provided with a color filter or a black matrix. Even in a case where a single color light emitting layer, for example, a white light emitting layer is used, full-color display is possible by the color filter. Further, even in a case where a light emitting layer of each R, G, and B is used, a wavelength of light to be emitted can be controlled by providing the color filter, and thus, clear display can be provided. By the black matrix, reflection of external light on a wiring or the like can be reduced.

Then, a first retardation plate 1235, and the first polarizing plate 1216 and the second polarizing plate 1217 which are sequentially stacked as the polarizing plate 1219 having a stacked structure are provided on the outer side of the insulating substrate 1201. A second retardation plate 1225, and the third polarizing plate 1226 and the fourth polarizing plate 1227 which are sequentially stacked as the polarizing plate 1229 having the stacked structure are provided on the outer side of the counter substrate 1220. In other words, a circularly polarizing plate having stacked polarizing plates is provided on the outer side of the insulating substrate 1201 and on the outer side of the counter substrate 1220.

At this time, the polarizing plate 1216 and the polarizing plate 1217 are attached to each other so as to be in a parallel Nicols state. The polarizing plate 1226 and the polarizing plate 1227 are also attached to each other so as to be in a parallel Nicols state.

Further, the polarizing plate 1219 having the stacked structure and the polarizing plate 1229 having the stacked structure are arranged to be in a crossed Nicols state.

Consequently, black luminance can be reduced, and the contrast ratio of the display device can be increased.

Since the retardation plate 1235 and the retardation plate 1225 are provided, reflection of external light to the display device can be suppressed.

A structure in which polarizing plates are stacked as shown in FIG. 2A is used as a polarizer in this embodiment mode. Naturally, the stacked polarizers shown in FIG. 2B and FIG. 2C may also be used.

Extinction coefficients of the polarizing plate 1216, 1217, 1226 and 1227 preferably have the same wavelength distribution.

FIG. 23 shows the example in which two polarizing plates are stacked for one substrate; however, three or more polarizing plates may be stacked.

In this embodiment mode, a mode is shown, in which the driver circuit portion is also formed over the insulating substrate 1201. However, an IC circuit formed from a silicon wafer may be used for the driver circuit portion. In this case, a video signal or the like from the IC circuit can be inputted to the switching TFT 1203 through a connecting terminal or the like.

Note that this embodiment mode is described using an active type display device. However, a circularly polarizing plate having stacked polarizing plates can be provided even in a passive type display device. Accordingly, a contrast ratio can be increased.

In addition, this embodiment mode can be freely combined with any of other embodiment modes, if necessary.

### Embodiment Mode 20

Embodiment Mode 20 will describe a concept of a display device of the present invention. In this embodiment mode, the display device uses an electroluminescent element as a light emitting element.

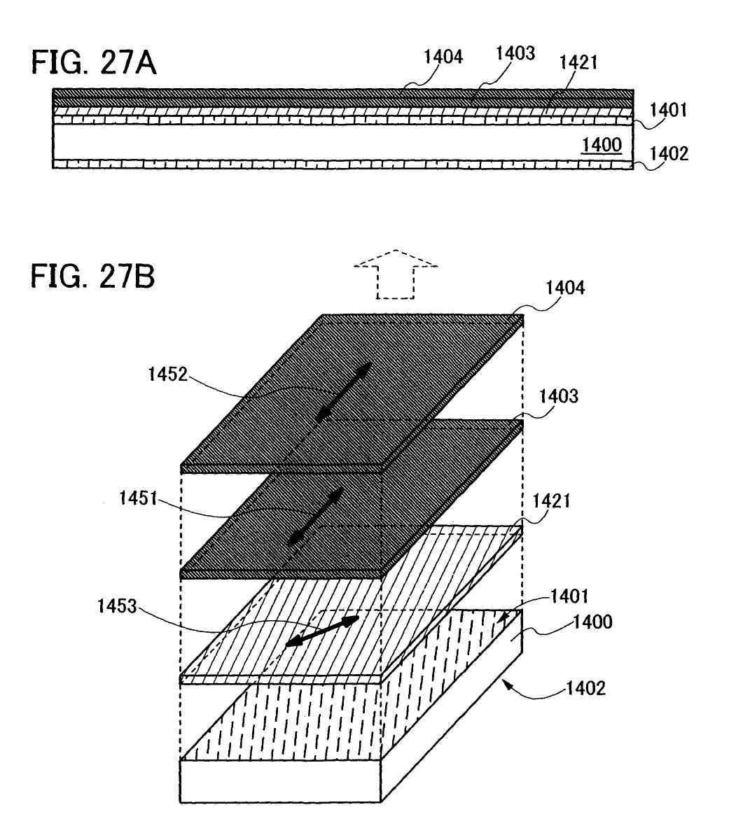

FIGS. 27A and 27B show a display device in which light from a light emitting element is emitted to the upper side of a substrate (light is emitted upwardly). As shown in FIGS. 27A and 27B, a layer 1400 including an electroluminescent element as a light emitting element is interposed between a first substrate 1401 and a second substrate 1402 arranged to be opposite to each other. Light from the electroluminescent element can be emitted to the first substrate 1401 side (in a direction indicated by a dashed arrow).

A light-transmitting substrate is used for the first substrate 1401. As such light-transmitting substrate, for example, a glass substrate such as barium borosilicate glass or alumino borosilicate glass, a quartz substrate, or the like can be used. Further, a substrate formed from a synthetic resin having flexibility such as plastic typified by polyethylene terephthalate (PEI), polyethylene naphthalate (PEN), polyethersulfone (PES), or polycarbonate (PC), or acrylic can be used for the light-transmitting substrate.

Although a light-transmitting substrate may be used for the second substrate 1402, light from the layer 1400 including the electroluminescent element is not emitted through the second substrate 1402 because an electrode which is provided for the layer 1400 including the electroluminescent element may be formed using a conductive film having a reflective property, or a material having a reflective property is formed on an entire surface of the second substrate 1402; therefore, light from the layer 1400 including the electroluminescent element may be reflected on the second substrate 1402 side and emitted toward the first substrate 1401 side, as is described later.

A retardation plate (also referred to as a wave plate) and stacked polarizers are provided on the outer side of a surface of the first substrate 1401 to which light is emitted. The stacked polarizers can be referred to as a linear polarizer having a stacked structure. The stacked polarizers indicate a state where two or more polarizers are stacked. Note that in this embodiment mode, as the structure of the stacked polarizers, polarizing plates each including one polarizing film shown in FIG. 2A are stacked. Needless to say, the structures shown in FIGS. 2B and 2C may also be used.

FIGS. 27A and 27B show an example in which two polarizing plates are provided; however, three or more polarizing plates may be stacked.

The retardation plate (in this embodiment mode, a quarter wave plate) and the stacked polarizing plates are also collectively referred to as a circularly polarizing plate having stacked polarizing plates (linear polarizing plates).

A first polarizing plate 1403 and a second polarizing plate 1404 are arranged in such a way that an absorption axis 1451 of the first polarizing plate 1403 and an absorption axis 1452 of the second polarizing plate 1404 should be parallel. In other words, the first polarizing plate 1403 and the second polarizing plate 1404 are arranged to be in a parallel Nicols state. A slow axis 1453 of a retardation plate 1421 is arranged to be shifted from the absorption axis 1451 of the first polarizing plate 1403 and the absorption axis 1452 of the second polarizing plate 1404 by 45°.

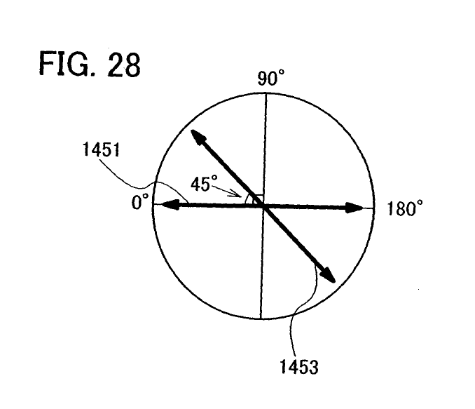

FIG. 28 shows angular deviation between the absorption axis 1451 and the slow axis 1453. The angle formed by the slow axis 1453 and the absorption axis 1451 is 45°. Note that since the absorption axis 1452 is the same direction as the absorption axis 1451, the explanation with respect to the absorption axis 1452 is omitted here. In other words, the slow axis 1453 of the retardation plate 1421 is arranged to be shifted by 45° from the absorption axis 1451 of the first linear polarizing plate 1403.

In this specification, it is assumed that the above angle range is to be satisfied in a parallel Nicols state and the angular deviation between an absorption axis and a slow axis; however, the angular deviation may differ from the above-described angles to some extent as long as a similar effect can be obtained.

The polarizing plate 1403 and the polarizing plate 1404 can be formed of known materials. For example, a structure can be used, in which an adhesive surface, TAC (triacetylcellulose), a mixed layer of PVA (polyvinyl alcohol) and a dichromatic pigment, and TAC are sequentially stacked from the substrate side. The dichroic pigment includes iodine and dichromatic organic dye. The polarizing plate is sometimes referred to as a polarizing film based on the shape.

Note that transmission axes exist in the direction orthogonal to the absorption axes based on the characteristics of the polarizing plates. Therefore, a state in which the transmission axes are parallel to each other can also be referred to as parallel Nicols.

The extinction coefficients of the polarizing plate 1403 and the polarizing plate 1404 preferably have the same wavelength distribution.

FIGS. 27A and 27B show the example in which two polarizing plates are stacked for one substrate; however, three or more polarizing plates may be stacked.

A fast axis exists in the direction orthogonal to the slow axis based on the characteristics of the retardation plate. Therefore, arrangement of the retardation plate and the polarizing plate can be determined using not only the slow axis but also the fast axis. In this embodiment mode, the transmission axis and the slow axis are arranged to be shifted from each other by 45°, in other words, the transmission absorption axis and the fast axis are arranged to be shifted from each other by 135°.

Since the stacked polarizing plates are stacked such that their transmission axes are in a parallel Nicols state, reflected light of external light can be reduced, compared to the case of a single polarizing plate. Accordingly, black luminance can be increased, and the contrast ratio of the display device can be increased.

### Embodiment Mode 21

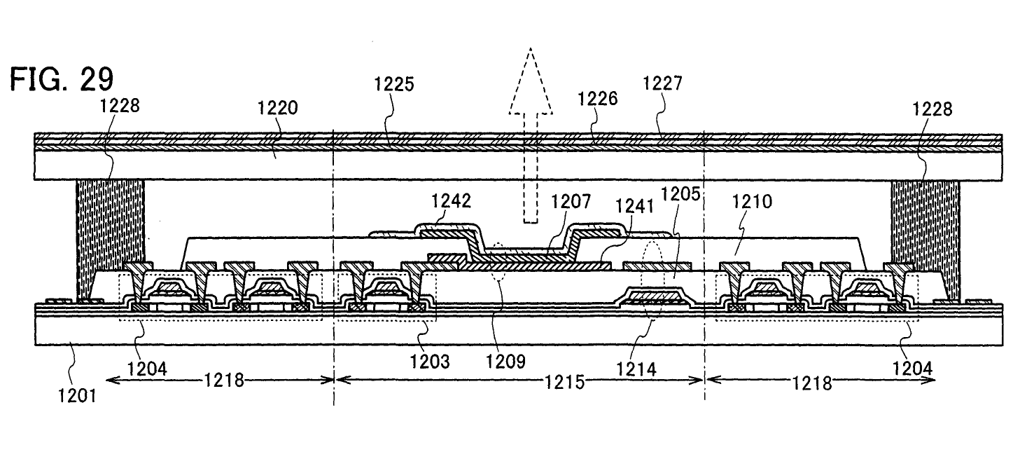

Embodiment Mode 21 will describe a cross sectional view of a display device of the present invention with reference to FIG. 29.

Note that elements in a display device shown in FIG. 29 similar to those in FIG. 26 are denoted by the same reference numerals, and description of FIG. 26 can be applied to elements which are not particularly described.

A thin film transistor is formed over the substrate (hereinafter referred to as an insulating substrate) 1201 having an insulating surface with an insulating layer interposed therebetween. The thin film transistor (also referred to as a TFT) includes a semiconductor layer processed into a predetermined shape, a gate insulating layer which covers the semiconductor layer, a gate electrode provided over the semiconductor layer with the gate insulating layer interposed therebetween, and a source electrode or drain electrode connected to an impurity layer in the semiconductor film.

A material used for the semiconductor layer is a semiconductor material having silicon, and a crystalline state thereof may be any of amorphous, microcrystalline, and crystalline.

An inorganic material is preferably used for the insulating layer typified by a gate insulating film, and silicon nitride or silicon oxide can be used. The gate electrode and the source electrode or drain electrode may be formed from a conductive material, and includes tungsten, tantalum, aluminum, titanium, silver, gold, molybdenum, copper, or the like.

The display device can be roughly divided into the pixel portion 1215 and the driver circuit portion 1218. The thin film transistor 1203 provided in the pixel portion 1215 is used as a switching element of the light emitting element, and the thin film transistor 1204 provided in the driver circuit portion 1218 is used as a CMOS circuit. In order to use the thin film transistor 1204 as a CMOS circuit, it is formed from a p-channel TFT and an N-channel TFT. The thin film transistor 1203 in the pixel portion 1215 can be controlled by the CMOS circuit provided in the driver circuit portion 1218.

Note that although FIG. 29 shows a top gate type TFT which is used as the thin film transistor 1203 and the thin film transistor 1204, a bottom gate type TFT may be used.

The insulating layer 1205 having a stacked structure or a single layer structure is formed to cover the thin film transistors in the pixel portion 1215 and the driver circuit portion 1218. The insulating layer 1205 can be formed from an inorganic material or an organic material. As the inorganic material, silicon nitride or silicon oxide can be used. As the organic material, polyimide, acrylic, polyamide, polyimide amide, resist, benzocyclobutene, siloxane, polysilazane, or the like can be used.

A skeleton structure of siloxane is formed by the bond of silicon (Si) and oxygen (O), in which an organic group containing at least hydrogen (such as an alkyl group or an aromatic hydrocarbon) is included as a substituent. In addition, a fluoro group may be used as the substituent. Further, a fluoro group and an organic group containing at least hydrogen may be used as the substituent. Polysilazane is formed using a liquid material containing a polymer material having the bond of silicon (Si) and nitrogen (N) as a starting material.

If the insulating layer 1205 is formed using an inorganic material, a surface thereof follows a depression/projection below. Alternatively, if the insulating layer is formed using an organic material, a surface thereof is planarized. For example, in a case where the insulating layer 1205 is required to have planarity, it is preferable that the insulating layer 1205 be formed using an organic material. Note that, even if an inorganic material is used, planarity can be obtained by forming the material with a thick thickness.

The source electrode or drain electrode is manufactured by forming a conductive layer in an opening provided in the insulating layer 1205 or the like. At this time, a conductive layer serving as a wiring over the insulating layer 1205 can be formed. The capacitor element 1214 can be formed from the conductive layer of the gate electrode, the insulating layer 1205, and the conductive layer of the source electrode or drain electrode.

A first electrode 1241 to be connected to either the source electrode or drain electrode is formed. The first electrode 1241 is formed using a conductive film having a reflective property. As the conductive film having a reflective property, a conductive film having a high work function such as platinum (Pt) or gold (Au) is used. Since these metals are expensive, a pixel electrode may be used in which such metal is stacked over an appropriate conductive film such as an aluminum film or a tungsten film, so that platinum or gold may be exposed at least in the outermost surface.

The insulating layer 1210 is formed so as to cover an end portion of the first electrode 1241. The insulating layer 1210 can be formed in a similar manner to the insulating layer 1205. An opening is provided in the insulating layer 1210 to cover the end portion of the first electrode 1206. An end surface of the opening may have a tapered shape, and thus, disconnection of a layer to be formed later can be prevented. For example, in a case where a non-photosensitive resin or a photosensitive resin is used for the insulating layer 1210, a tapered shape can be provided in a side surface of the opening portion in accordance with an exposure condition.

After that, the electroluminescent layer 1207 is formed in the opening portion of the insulating layer 1210. The electroluminescent layer 1207 includes a layer including each function, specifically, a hole injecting layer, a hole transporting layer, a light emitting layer, an electron transporting layer, and an electron injecting layer. A boundary of each layer is not necessarily clear, and there may be a case where parts of the boundaries are mixed.

Specific materials for forming the light emitting layer are exemplified hereinafter. When reddish emission is desired to be obtained, 4-dicyanomethylene-2-isopropyl-6-[2-(1,1,7,7-tetramethyljulolidin-9-yl)ethenyl]4H-pyran (abbreviation: DCJTI), 4-dicyanomethylene-2-methyl-6-[2-1,1,7,7-tetramethyljulolidin-9-yl)ethenyl]-4H-pyran (abbreviation: DCJT), 4-dicyanomethylene-2-tert-butyl-6-[2-(1,1,7,7-tetramethyljulolidin-9-yl)ethenyl]-4H-pyran (abbreviation: DCJTB), periflanthene, 2,5-dicyano-1,4-bis[2-10-methoxy-1,1,7,7-tetramethyljulolidin-9-yl)ethenyl]benzene, bis[2,3-bis(4-fluorophenyl)quinoxalinato]iridium(acetylacetonate) (abbreviation: Ir[Fdpq]₂(acac)), or the like can be used for the light emitting layer. However, it is not limited to these materials, and a substance which exhibits emission with a peak from 600 nm to 700 nm in an emission spectrum can be used.

When greenish emission is desired to be obtained, N,N′-dimethylquinacridone (abbreviation: DMQd), coumarin 6, coumarin 545T, tris(8-quinolinolato)aluminum (abbreviation: Alq₃), or the like can be used for the light emitting layer. However, it is not limited to these materials, and a substance which exhibits emission with a peak from 500 nm to 600 nm in an emission spectrum can be used.

When bluish emission is desired to be obtained, 9,10-bis(2-naphthyl)-tert-butylanthracene (abbreviation: t-BuDNA), 9,9′-bianthryl, 9,10-diphenylanthracene (abbreviation: DPA), 9,10-bis(2-naphthyl)anthracene (abbreviation: DNA), bis(2-methyl-8-quinolinolato)-4-phenylphenolato-gallium (abbreviation: BGaq), bis(2-methyl-8-quinolinolato)-4-phenylphenolato-aluminum (abbreviation: BAlq), or the like can be used for the light emitting layer. However, it is not limited to these materials, and a substance which exhibits emission with a peak from 400 nm to 500 nm in an emission spectrum can be used.

When whitish emission is desired to be obtained, a structure can be used, in which TPD (aromatic diamine), 3-(4-tert-butylphenyl)-4-phenyl-5-(4-biphenylyl)-1,2,4-triazole (abbreviation: TAZ), tris(8-quinolinolato)aluminum (abbreviation: Alq₃), Alq₃ doped with Nile Red which is a red light emitting pigment are stacked by an evaporation method or the like.

Then, a second electrode 1242 is formed. The second electrode 1242 is formed by staking a conductive film having a light-transmitting property over a conductive film which has a low work function and a thin film thickness (preferably 10 to 50 nm). The conductive film having a low work function is formed from a material containing an element which belongs to Group 1 or Group 2 of the periodic table (for example, Al, Mg, Ag, Li, Ca, or an alloy thereof such as MgAg, MgAgAl, MgIn, LiAl, LiFAl, CaF₂, or Ca₃N₂). The conductive film having a light transmitting property is formed using indium tin oxide (ITO), zinc oxide (ZnO), indium zinc oxide, zinc oxide to which gallium is added (GZO), or the like.

In addition, an alkali metal such as Li or Cs, an alkaline earth metal such as Mg, Ca, or Sr, an alloy thereof (Mg:Ag, Al:Li, Mg:In, or the like), and a compound of these (CaF₂, calcium nitride) may also be used. Furthermore, a material with a non-light-transmitting property such as a rare-earth metal such as Yb or Er, may be used for the second electrode 1242, as long as a light-transmitting property can be obtained by making the film thickness very thin.

In this way, the light emitting element 1209 which has the first electrode 1241 and the second electrode 1242, which are a pair of electrodes, and the electroluminescent layer 1207 provided between the pair of electrodes can be formed.

At this time, since the second electrode 1242 has a light-transmitting property, light can be emitted upwardly from the electroluminescent layer 1207.

Then, the insulating substrate 1201 and the counter substrate 1220 are attached to each other by the sealing material 1228. In this embodiment mode, the sealing material 1228 is provided over a part of the driver circuit portion 1218; therefore, a narrow frame can be attempted. As a matter of course, arrangement of the sealing material 1228 is not limited thereto. The sealing material 1228 may be provided on the outer side of the driver circuit portion 1218.

A space formed by the attachment is filled with an inert gas such as nitrogen and sealed, or filled with a resin material having a light-transmitting property and high hygroscopicity. Accordingly, intrusion of moisture or oxygen, which becomes one factor of deterioration of the light emitting element 1209, can be prevented. Further, a spacer may be provided to keep an interval between the insulating substrate 1201 and the counter substrate 1220, and the spacer may have hygroscopicity. The spacer has a spherical shape or a columnar shape.

The counter substrate 1220 can be provided with a color filter or a black matrix. Even in a case where a single color light emitting layer, for example, a white light emitting layer is used, full-color display is possible by the color filter. Further, even in a case where a light emitting layer of each R, G, and B is used, a wavelength of light to be emitted can be controlled by providing the color filter, thereby providing clear display. By the black matrix, reflection of external light on a wiring or the like can be reduced.

Then, the retardation plate 1225, the first polarizing plate 1226, and the second polarizing plate 1227 are provided on the outer side of the counter substrate 1220 to which light from the light emitting element is emitted. In other words, a circularly polarizing plate having the stacked polarizing plates is provided on the outer side of the counter substrate 1220.

At this time, the polarizing plate 1226 and the polarizing plate 1227 are attached to each other so as to be in a parallel Nicols state.

Consequently, light leakage from external light can be prevented, so that black luminance can be reduced, and the contrast ratio of the display device can be increased.

Since the retardation plate 1225 is provided, reflection to the display device can be suppressed.

The retardation plate 1225 may be provided similarly to the retardation plate 1421 described in Embodiment Mode 20, and the first polarizing plate 1226 and the second polarizing plate 1227 may also be provided similarly to the polarizing plate 1403 and the polarizing plate 1404. Note that in this embodiment mode, only two polarizing plates are provided; however, three or more polarizing plates may be stacked.

A structure in which polarizing plates are stacked as shown in FIG. 2A is used as a polarizer in this embodiment mode. Naturally, the stacked polarizers shown in FIG. 2B and FIG. 2C may also be used.

Extinction coefficients of the polarizing plate 1226 and the polarizing plate 1227 preferably have the same wavelength distribution

In this embodiment mode, a mode is shown, in which the driver circuit portion is also formed over the insulating substrate 1201. However, an IC circuit formed from a silicon wafer may be used for the driver circuit portion. In this case, a video signal or the like from the IC circuit can be inputted to the switching TFT 1203 through a connecting terminal or the like.

This embodiment mode is described using an active type display device. However, a circularly polarizing plate having stacked polarizing plates can be provided even in a passive type display device. Accordingly, a contrast ratio can be increased.

In addition, this embodiment mode can be freely combined with any of the other embodiment modes described above, if necessary.

### Embodiment Mode 22

Embodiment Mode 22 will describe a concept of a display device of the present invention. In this embodiment mode, the display device uses an electroluminescent element as a light emitting element.

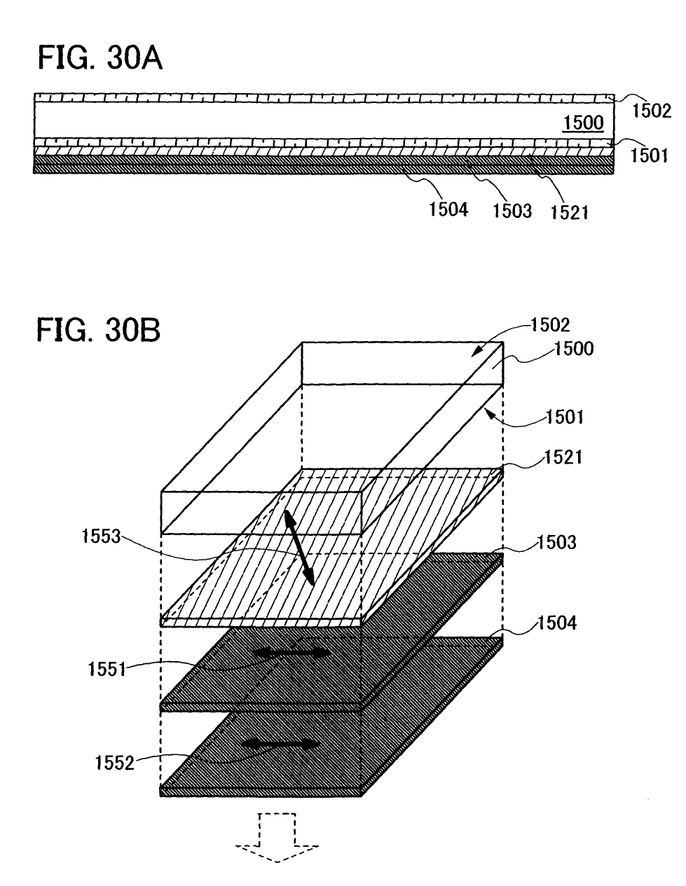

FIGS. 30A and 30B show a display device in which light from a light emitting element is emitted to the lower side of a substrate (light is emitted downwardly). As shown in FIGS. 30A and 30B, a layer 1500 including an electroluminescent element as a light emitting element is interposed between a first substrate 1501 and a second substrate 1502 arranged to be opposite to each other. Light from the electroluminescent element can be emitted to the first substrate 1501 side (in a direction indicated by a dashed arrow).

A light-transmitting substrate is used for the first substrate 1501. As such a light-transmitting substrate, a material similar to the substrate 1401 in Embodiment Mode 20 may be used.

Although a light-transmitting substrate may be used for the second substrate 1502, light from the layer 1500 including the electroluminescent element is not emitted through the second substrate 1502. An electrode which is provided in the layer 1500 including the electroluminescent element may be formed using a conductive film having a reflective property, or a material having a reflective property is formed on an entire surface of the second substrate 1502; therefore, light from the layer 1500 including the electroluminescent element may be reflected to the first substrate 1501 side, as described later.

A retardation plate (also referred to as a wave plate) and stacked polarizers are provided on the outer side of a surface to which light of the first substrate 1501 is emitted.

The structure in which polarizing plates are stacked as shown in FIG. 2A is used as a polarizer in this embodiment mode. Naturally, the stacked polarizers shown in FIG. 2B and FIG. 2C may also be used.

The retardation plate (in this embodiment mode, a quarter-wave plate) and the stacked polarizing plates are also collectively referred to as a circularly polarizing plate having stacked polarizing plates (linear polarizing plates). Note that in this embodiment mode, only two polarizing plates are provided; however, three or more polarizing plates may be stacked.

A first polarizing plate 1503 and a second polarizing plate 1504 are arranged in such a way that an absorption axis 1551 of the first polarizing plate 1503 and an absorption axis 1552 of the second polarizing plate 1504 become parallel to each other. In other words, the first polarizing plate 1503 and the second polarizing plate 1504, namely stacked polarizing plates, are arranged to be in a parallel Nicols state. A slow axis 1553 of a retardation plate 1521 is arranged to be shifted from the absorption axis 1551 of the first polarizing plate 1503 and the absorption axis 1552 of the second polarizing plate 1504 by 45°.

In this specification, it is assumed that the above angle range is to be satisfied in a parallel Nicols state and the angular deviation between an absorption axis and a slow axis; however, the angular deviation may differ from the above-described angles to some extent as long as a similar effect can be obtained.

For the polarizing plate 1503 and the polarizing plate 1504, a similar material to the polarizing plate 1403 and the polarizing plate 1404 in Embodiment Mode 20 may be used.

Extinction coefficients of the polarizing plate 1503 and the polarizing plate 1504 preferably have the same wavelength distribution.

In addition, a positional relationship between the absorption axis 1551 of the polarizing plate 1503, the absorption axis 1552 of the polarizing plate 1504, and the slow axis 1553 of the retardation plate 1521 is similar to that of Embodiment Mode 20 (see FIG. 28).

In the display device in which light is emitted to the lower side of a substrate (light is emitted downwardly) described in this embodiment mode, reflected light of external light can be reduced by stacking the polarizing plates to be in a parallel Nicols state, compared to the case of a single polarizing plate. Accordingly, black luminance can be reduced, and the contrast ratio of the display device can be increased.

In addition, this embodiment mode can be freely combined with any of the other embodiment modes described above, if necessary.

### Embodiment Mode 23

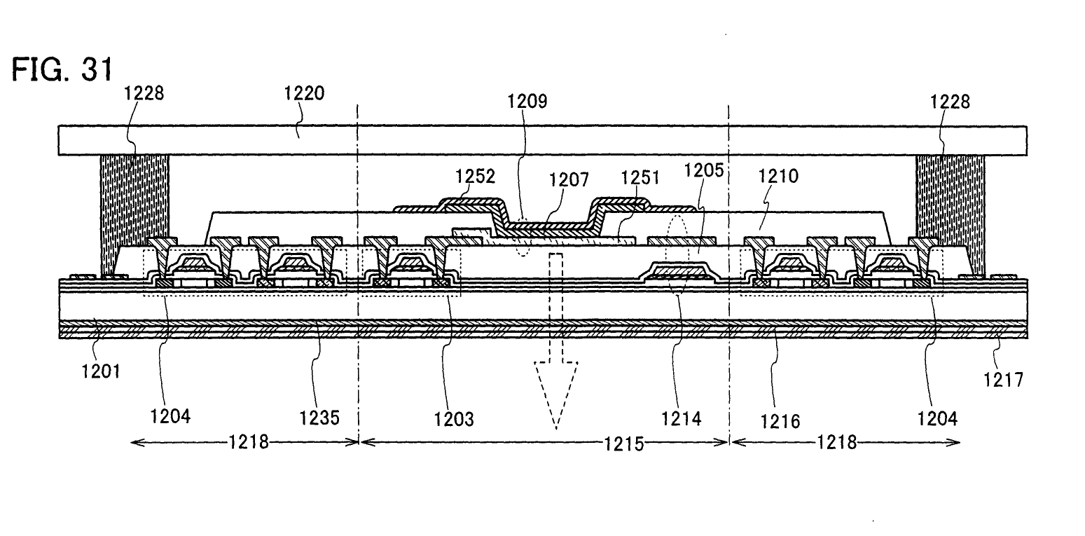

FIG. 29 shows the display device in which light is emitted to the side opposite to the substrate provided with the thin film transistor (light is emitted upwardly), while FIG. 31 shows a display device in which light is emitted to the substrate side provided with a thin film transistor (light is emitted downwardly).

Elements in FIG. 31 similar to those in FIG. 29 are denoted by the same reference numerals. A display device in FIG. 31 includes a first electrode 1251, the electroluminescent layer 1207, and a second electrode 1252. The first electrode 1251 may be formed using the same material as that of the second electrode 1242 in FIG. 29. The second electrode 1252 may be formed using the same material as that of the first electrode 1241 in FIG. 29. The electroluminescent layer 1207 may be formed using a material similar to the electroluminescent layer 1207 in Embodiment Mode 3. Since the first electrode 1251 has a light-transmitting property, light can be emitted downwardly from the electroluminescent layer 1207.

The retardation plate 1235, the first polarizing plate 1216, and the second polarizing plate 1217 are provided on the outer side of the substrate 1201 to which light from the light emitting element is emitted. In other words, a circularly polarizing plate having stacked polarizing plates is provided on the outer side of the substrate 1201. Consequently, a display device having a high contrast ratio can be obtained. The retardation plate 1235 may be provided similarly to the retardation plate 1521 described in Embodiment Mode 22, and the first polarizing plate 1216 and the second polarizing plate 1217 may also be provided similarly to the polarizing plate 1503 and the polarizing plate 1504. Note that in this embodiment mode, only two polarizing plates are provided; however, three or more polarizing plates may be stacked.

Extinction coefficients of the polarizing plate 1216 and the polarizing plate 1217 preferably have the same wavelength distribution.

In addition, this embodiment mode can be freely combined with any of the other embodiment modes described above, if necessary.

### Embodiment Mode 24

Embodiment Mode 24 will describe a structure of a display device having the pixel portion and the driver circuit as shown in Embodiment Mode 16 to Embodiment Mode 23.

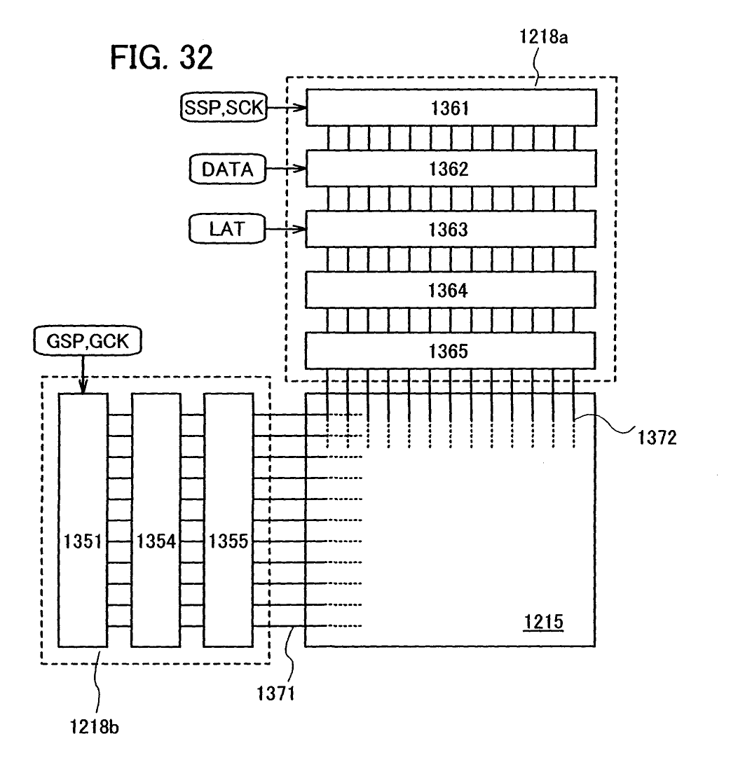

FIG. 32 shows a block diagram of a state where a scanning line driver circuit portion 1218b and a signal line driver circuit portion 1218a which are the driver circuit portion 1218 are provided in the periphery of the pixel portion 1215.

The pixel portion 1215 has a plurality of pixels, and the pixel is provided with a light emitting element and a switching element.

The scanning line driver circuit portion 1218b has a shift register 1351, a level shifter 1354, and a buffer 1355. A signal is produced based on a start pulse (GSP) and a clock pulse (GCK) inputted to the shift register 1351, and is inputted to the buffer 1355 through the level shifter 1354. A signal is amplified in the buffer 1355 and an amplified signal is inputted to the pixel portion 1215 through a scanning line 1371. The pixel portion 1215 is provided with a light emitting element and a switching element which selects the light emitting element, and a signal from the buffer 1355 is inputted to a gate line of the switching element. Accordingly, the switching element of a predetermined pixel is selected.

The signal line driver circuit portion 1218a includes a shift register 1361, a first latch circuit 1362, a second latch circuit 1363, a level shifter 1364, and a buffer 1365. A start pulse (SSP) and a clock pulse (SCK) are inputted to the shift register 1361. A data signal (DATA) is inputted to the first latch circuit 1362, and a latch pulse (LAT) is inputted to the second latch circuit 1363. The DATA is inputted to the second latch circuit 1363 based on the SSP and the SCK The DATA for one row is held in the second latch circuit 1363 to be inputted all together to the pixel portion 1215 through a signal line 1372.

The signal line driver circuit portion 1218a, the scanning line driver circuit portion 1218b, and the pixel portion 1215 can be formed using a semiconductor element provided over the same substrate. For example, the signal line driver circuit portion 1218a, the scanning line driver circuit portion 1218b, and the pixel portion 1215 can be formed using a thin film transistor included in the insulating substrate described in the above embodiment modes.

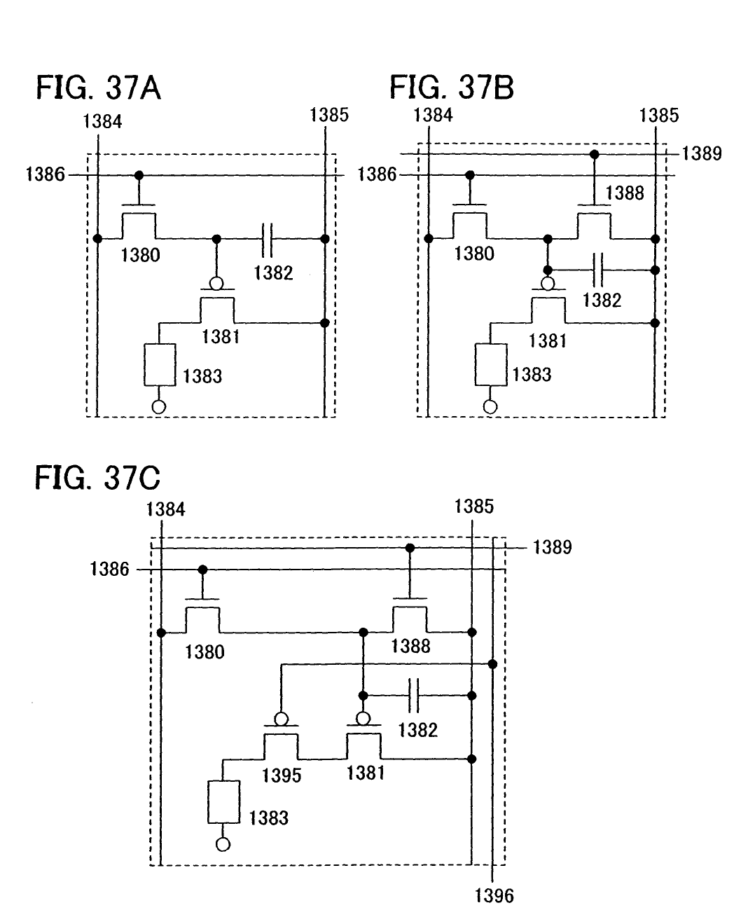

An equivalent circuit diagram of a pixel included in a display device in this embodiment mode is described with reference to FIGS. 37A to 37C.

FIG. 37A shows an example of an equivalent circuit diagram of a pixel, which includes a signal line 1384, a power supply line 1385, and a scanning line 1386, and in an intersection region thereof, a light emitting element 1383, transistors 1380 and 1381, and a capacitor element 1382. An image signal (also referred to as a video signal) is inputted to the signal line 1384 by a signal line driver circuit. The transistor 1380 can control supply of an electric potential of the image signal to a gate of the transistor 1381 in accordance with a selection signal inputted to the scanning line 1386. The transistor 1381 can control supply of a current to the light emitting element 1383 in accordance with an electric potential of the image signal. The capacitor element 1382 can hold a voltage between the gate and a source (referred to as a gate-source voltage) of the transistor 1381. Although the capacitor element 1382 is shown in FIG. 37A, the capacitor element 1382 is not necessarily provided in a case where a gate capacitance of the transistor 1381 or other parasitic capacitances can serve.

FIG. 37B is an equivalent circuit diagram of a pixel in which a transistor 1388 and a scanning line 1389 are additionally provided in the pixel shown in FIG. 37A The transistor 1388 makes it possible to make the electric potentials of the gate and source of the transistor 1381 equal to each other, so that a state where no current flows in the light emitting element 1383 can be forcibly made. Therefore, a sub-frame period can be more shortened than a period during which an image signal is inputted to all pixels.

FIG. 37C is an equivalent circuit diagram of a pixel in which a transistor 1395 and a wiring 1396 are additionally provided in the pixel shown in FIG. 37B. An electric potential of a gate of the transistor 1395 is fixed by the wiring 1396. The transistor 1381 and the transistor 1395 are connected in series between the power supply line 1385 and the light emitting element 1383. Accordingly, a value of a current supplied to the light emitting element 1383 can be controlled by the transistor 1395, and whether or not the current is supplied to the light emitting element 1383 can be controlled by the transistor 1381, in FIG. 37C.

A pixel circuit included in a display device of the present invention is not limited to the structure shown in this embodiment mode. For example, a pixel circuit having a current mirror and having a structure which conducts analog gradation display may be employed.

In addition, this embodiment mode can be freely combined with any of the other embodiment modes described above, if necessary.

### Embodiment Mode 25

Embodiment Mode 25 will describe a concept of a display device in which polarizers each having a stacked structure are arranged to be in a parallel Nicols state, namely, polarizers opposite to each other via a layer including a display element are arranged to be in a parallel Nicols state.

This embodiment mode can be applied to the transmissive type liquid crystal display devices (Embodiment Modes 7 to 9) and the dual-emission light emitting display devices (Embodiment Mode 18 and Embodiment Mode 19).

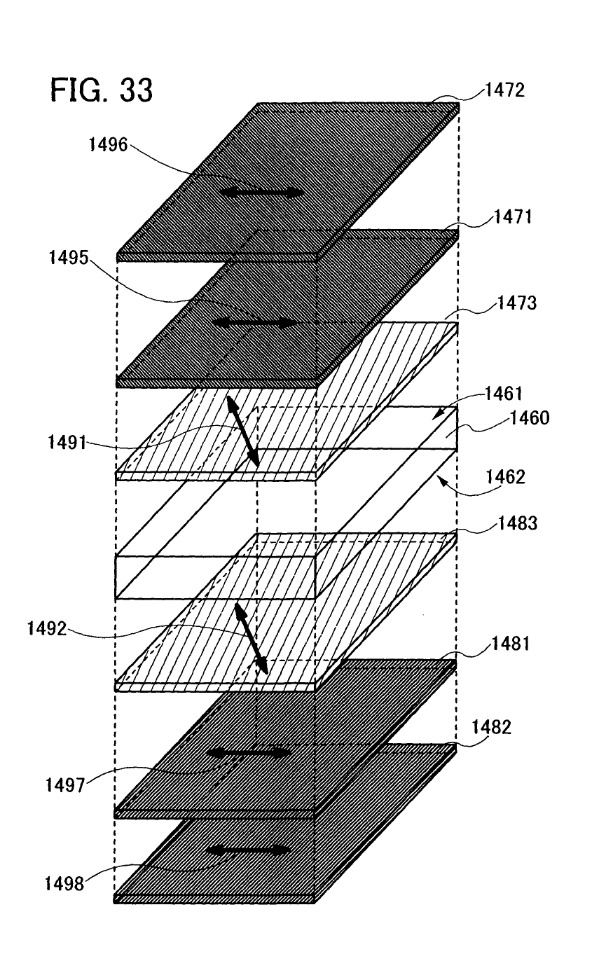

As shown in FIG. 33, a layer 1460 including a display element is interposed between a first substrate 1461 and a second substrate 1462. It is acceptable as long as the display element is a liquid crystal element for a liquid crystal display device and an electroluminescent element for a light emitting display device.

Light-transmitting substrates are used for the first substrate 1461 and the second substrate 1462. As the light-transmitting substrates, a material similar to the substrate 101 in Embodiment Mode 1 may be used.

On the outer sides of the substrate 1461 and the substrate 1462, namely on each of the sides which are not in contact with the layer 1460 including the display element from the substrate 1461 and the substrate 1462, stacked polarizers are provided. Note that in this embodiment mode, as the structure of the stacked polarizers, polarizing plates each including one polarizing film shown in FIG. 2A are stacked. Needless to say, the structures shown in FIGS. 2B and 2C may also be used. In a liquid crystal display device, light emitted from a backlight (not shown) passes through a layer including a liquid crystal element, a substrate, a retardation plate, and a polarizer so as to be extracted outside. In a light emitting display device, light from an electroluminescent element is emitted to the first substrate 1461 side and the second substrate 1462 side.

On the outer side of the first substrate 1461, a first retardation plate 1473, a first polarizing plate 1471, and a second polarizing plate 1472 are sequentially provided. The first polarizing plate 1471 and the second polarizing plate 1472 are arranged in such a way that an absorption axis 1495 of the first polarizing plate 1471 and an absorption axis 1496 of the second polarizing plate 1472 should be parallel, namely stacked polarizing plates 1471 and 1472 are arranged to be in a parallel Nicols state. A slow axis 1491 of the first retardation plate 1473 is arranged so that shifted from the absorption axis 1495 of the first polarizing plate 1471 and the absorption axis 1496 of the second polarizing plate 1472 are shifted from the slow axis 1491 of the first retardation plate 1473 by 45°.

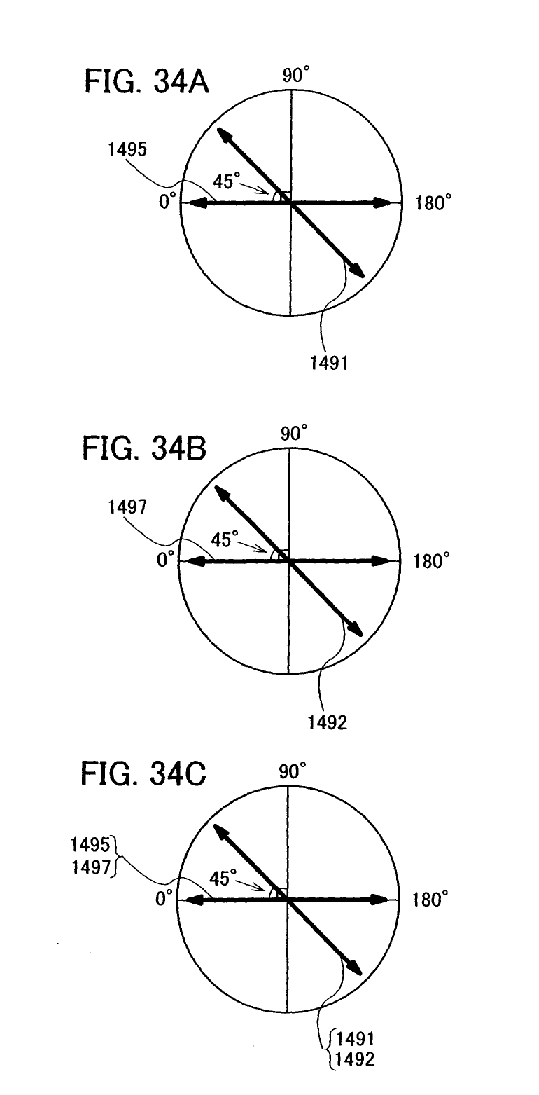

FIG. 34A shows the angular deviation between the absorption axis 1495 (and the absorption axis 1496) and the slow axis 1491. The angle formed by the slow axis 1491 and the absorption axis 1495 (and the absorption axis 1496) is 45°.

On the outer side of the second substrate 1462, a retardation plate 1483, a third polarizing plate 1481, and a fourth polarizing plate 1482 are sequentially provided. The third polarizing plate 1481 and the fourth polarizing plate 1482 are arranged in such a way that an absorption axis 1497 of the third polarizing plate 1481 and an absorption axis 1498 of the fourth polarizing plate 1482 should be parallel, namely stacked polarizing plate 1481 and 1482 are arranged to be in a parallel Nicols state. A slow axis 1492 of the retardation plate 1483 is arranged to be shifted from the absorption axis 1497 of the third polarizing plate 1481 and the absorption axis 1498 of the fourth polarizing plate 1482 by 45°.

FIG. 34B shows the angular deviation between the absorption axis 1497 (and the absorption axis 1498) and the slow axis 1492. The angle formed by the slow axis 1492 and the absorption axis 1497 (and the absorption axis 1498) is 45°.

That is, the slow axis 1491 of the first retardation plate 1473 is arranged to be shifted from the absorption axis of the first linear polarizing plate 1471 and the absorption axis of the second linear polarizing plate 1472 by 45°. The slow axis 1492 of the second retardation plate 1483 is arranged to be shifted from the absorption axis 1497 of the third linear polarizing plate 1481 and the absorption axis 1498 of the fourth linear polarizing plate 1482 by 45°. The absorption axis 1497 of the third linear polarizing plate 1481 and the absorption axis 1498 of the fourth linear polarizing plate 1482 are arranged to be parallel to the absorption axis 1495 of the first linear polarizing plate 1471 and the absorption axis 1496 of the second linear polarizing plate 1472.

In this embodiment mode, the absorption axis 1495 (and the absorption axis 1496) of the polarizing plate 1475 having a stacked structure provided over the first substrate 1461 and the absorption axis 1497 (and the absorption axis 1498) of the polarizing plate 1485 having a stacked structure provided under the second substrate 1462 are parallel to each other. In other words, the polarizing plate 1475 having the stacked structure and the polarizing plate 1485 having the stacked structure, namely polarizing plates each having a stacked structure and opposite to each other via a layer including a display device, are arranged to be in a parallel Nicols state.

FIG. 34C shows a state where the absorption axis 1495 and the absorption axis 1497 overlap each other, and the slow axis 1491 and the slow axis 1492 overlap each other, which indicates that the polarizing plates 1471, 1472, 1481 and 148 are in a parallel Nicols state.

Extinction coefficients of the polarizing plates 1471, 1472, 1481, and 1482 preferably have the same wavelength distribution.

As the circularly polarizing plate, a circularly polarizing plate with a widened band is given. The circularly polarizing plate with a widened band is an object in which a wavelength range in which phase difference (retardation) is 90°, is widened by stacking several retardation plates. Also in this case, a slow axis of each retardation plate arranged on the outer side of the first substrate 1461 and a slow axis of each retardation plate arranged on the outer side of the second substrate 1462 may be arranged to be parallel, and absorption axes of opposite polarizing plates may be arranged to be in a parallel Nicols state.

Since polarizing plates are stacked to be in a parallel Nicols state, light leakage in the absorption axis direction can be reduced. The polarizing plates each having a stacked structure and opposite to each other via a layer including a display device are arranged to be in a parallel Nicols state. By providing such circularly polarizing plates, light leakage can be further reduced compared to the case circularly polarizing plates having a single polarizing plate are arranged to be in a parallel Nicols state. Accordingly, the contrast ratio of the display device can be increased.

In addition, this embodiment mode can be freely combined with any of the other embodiment modes described above, if necessary.

### Embodiment Mode 26

Embodiment Mode 26 will describe a display device having a structure in which the number of polarizers on the upper side is different from the number of polarizers on the lower side of a layer including a light emitting element.

This embodiment mode can be applied to transmissive type liquid crystal display devices (Embodiment Mode 7 to Embodiment Mode 9) and a dual-emission light emitting display devices (Embodiment Mode 18 and Embodiment Mode 19).

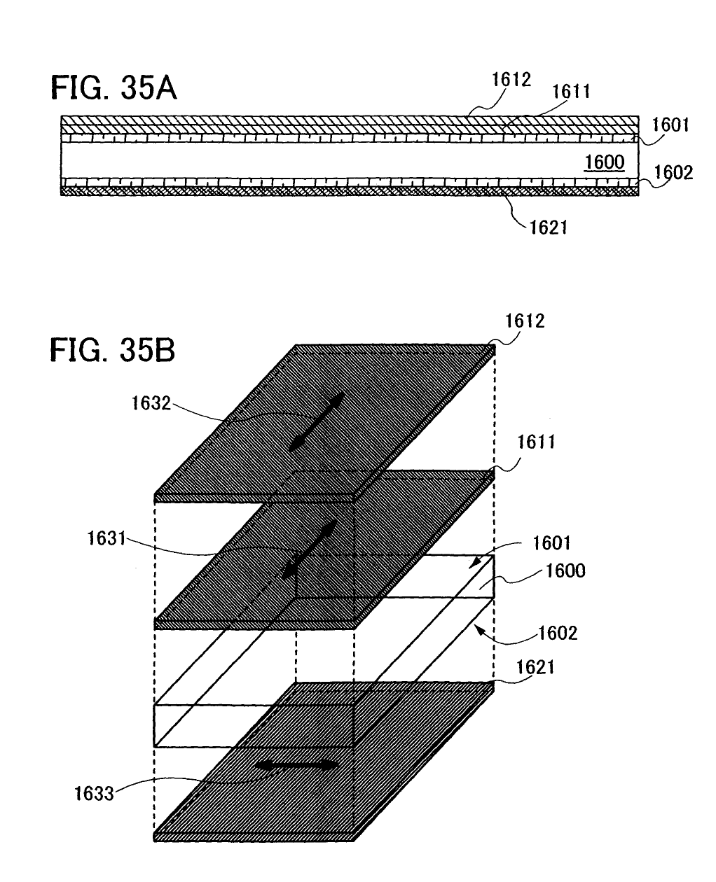

As shown in FIGS. 35A and 35B, a layer 1600 including a display element is interposed between a first substrate 1601 and a second substrate 1602 which are arranged to be opposite to each other. Note that FIG. 35A shows a cross sectional view of a display device of this embodiment mode, and FIG. 35B shows a perspective view of the display device of this embodiment mode.

It is acceptable as long as the display element may be a liquid crystal element for a liquid crystal display device, and may be an electroluminescent element for a light emitting display device.

Light-transmitting substrates are used for the first substrate 1601 and the second substrate 1602. As such light-transmitting substrates, for example, a glass substrate such as barium borosilicate glass or alumino-borosilicate glass, a quartz substrate, or the like can be used. Alternatively, a substrate formed from a synthetic resin having flexibility, such as a plastic, typified by polyethylene-terephthalate (PET), polyethylene naphthalate (PEN), polyethersulfone (PES), or polycarbonate (PC), or acrylic, can be used for the light-transmitting substrates.

Stacked polarizers or a polarizer having a single layer structure is provided on the outer sides of the substrate 1601 and the substrate 1602, namely on the sides which are not in contact with the layer 1600 including the display element from the substrates 1601 and 1602, respectively. Note that in this embodiment mode, as the structure of the stacked polarizers, polarizing plates each including one polarizing film shown in FIG. 2A are stacked. Needless to say, the structures shown in FIGS. 2B and 2C may also be used.

In a liquid crystal display device, light from a backlight (not shown) is extracted outside, passing through a layer including a liquid crystal element, a substrate, and a polarizer. In the light emitting display device, light from the electroluminescent element is emitted to the first substrate 1601 side and the second substrate 1602 side.

Light passing through the layer including the liquid crystal element or light emitted from the electroluminescent element is linearly polarized by the polarizing plate. That is, the stacked polarizing plates can be referred to as a linear polarizing plate having a stacked structure. The stacked polarizing plates indicate a state where two or more polarizing plates are stacked. The polarizing plate having a single layer structure refers to a state where one polarizing plate is provided.

In this embodiment mode, a display device in which two polarizing plates are stacked on one side of the layer 1600 including the display element and a polarizing plate having a single layer structure is provided on the other side thereof is exemplified, and the two polarizing plates to be stacked are stacked in contact with each other as shown in FIG. 35A.

A first polarizing plate 1611 and a second polarizing plate 1612 are sequentially provided on the outer side of the first substrate 1601. An absorption axis 1631 of the first polarizing plate 1611 and an absorption axis 1632 of the second polarizing plate 1612 are arranged to be parallel to each other. In other words, the first polarizing plate 1611 and the second polarizing plate 1612 are arranged to be in a parallel Nicols state.

A third polarizing plate 1621 is provided on the outer side of the second substrate 1602.

In this embodiment mode, the absorption axis 1631 and the absorption axis 1632 of the polarizing plate 1613 having the stacked structure provided over the first substrate 1601 and an absorption axis 1633 of the polarizing plate 1621 having a single layer structure provided under the second substrate 1602 are orthogonal to each other. In other words, the polarizing plate 1613 having the stacked structure and the polarizing plate 1621 having a single layer structure, namely polarizing plates opposite to each other via the layer including the display element, are arranged to be in a crossed Nicols state.

These polarizing plates 1611, 1612, and 1621 can be formed from known materials. For example, a structure can be used, in which an adhesive surface, TAC (triacetylcellulose), a mixed layer of PVA (polyvinyl alcohol) and a dichroic pigment, and TAC are sequentially stacked from the substrate side. The dichroic pigment includes iodine and dichromatic organic dye. The polarizing plate is sometimes referred to as a polarizing film based on the shape.

Note that transmission axes exist in the direction orthogonal to the absorption axes based on the characteristics of the polarizing plates. Therefore, a state in which the transmission axes are parallel to each other can also be referred to as parallel Nicols.

The extinction coefficients of the polarizing plates 1611, 1612 and 1621 preferably have the same wavelength distribution.

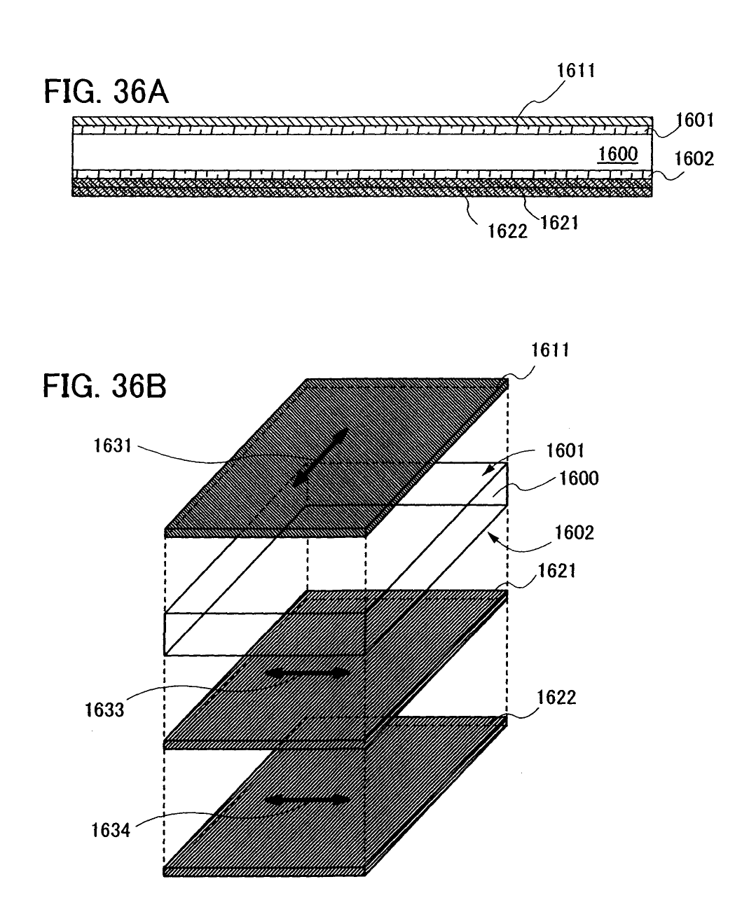

As shown in FIGS. 36A and 36B, on the first substrate 1601 side, the first polarizing plate 1611 is provided. That is, on the first substrate 1601 side, a polarizing plate having a single layer structure is formed using the first polarizing plate 1611. On the second substrate 1602 side, the second polarizing plate 1621 and a third polarizing plate 1622 are sequentially provided from the substrate side. That is, on the second substrate 1602 side, a polarizing plate 1623 having a stacked structure is formed from the second polarizing plate 1621 and the third polarizing plate 1622. Since the other structures are similar to those in FIGS. 35A and 35B, description thereof is omitted here.

The second polarizing plate 1621 and the third polarizing plate 1622 are arranged in such a way that the absorption axis 1633 of the second polarizing plate 1621 and an absorption axis 1634 of the third polarizing plate 1622 should be parallel. That is, the second polarizing plate 1621 and the third polarizing plate 1622 are in a parallel Nicols state.

In this embodiment mode, the absorption axis 1631 of the polarizing plate 1611 having a single layer structure provided over the first substrate 1601, and the absorption axis 1633 and the absorption axis 1634 of the polarizing plate 1623 having a stacked structure provided for the second substrate 1602 are orthogonal to each other. That is, the polarizing plate 1611 having a single layer structure and the polarizing plate 1623 having a stacked structure, namely polarizing plates which are opposite to each other via the layer including the display element, are arranged to be in a crossed Nicols state.

The extinction coefficients of the polarizing plates 1611, 1612 and 1622 preferably have the same wavelength distribution.

As described above, of the polarizing plates arranged to be opposite to each other via the layer including the display device, a polarizing plate provided on the side of one of the substrates stacked on one another, and the polarizing plates opposite to each other via the layer including the display device are arranged to be in a crossed Nicols state. In this manner as well, light leakage in the absorption axis direction can be reduced. Consequently, the contrast ratio of the display device can be increased.

In this embodiment mode, an example in which stacked polarizing plates are used as an example of the stacked polarizers, and one polarizing plate is provided on one substrate side and two polarizing plates are provided on the other side is described. However, the number of stacked polarizers is not necessarily two, and three or more polarizers may be stacked.

In addition, this embodiment mode can be freely combined with any of other embodiment modes and other examples in this specification, if necessary.

### Embodiment Mode 27

Embodiment Mode 27 will describe a display device in which a circularly polarizing plate having stacked polarizers on one side of a layer including a display element and a circularly polarizing plate having one polarizer on the other side are used to.

This embodiment mode can be applied to a transmissive type liquid crystal display devices (Embodiment Mode 7 to Embodiment Mode 9) and a dual-emission light emitting display devices (Embodiment Mode 18 and Embodiment Mode 19).

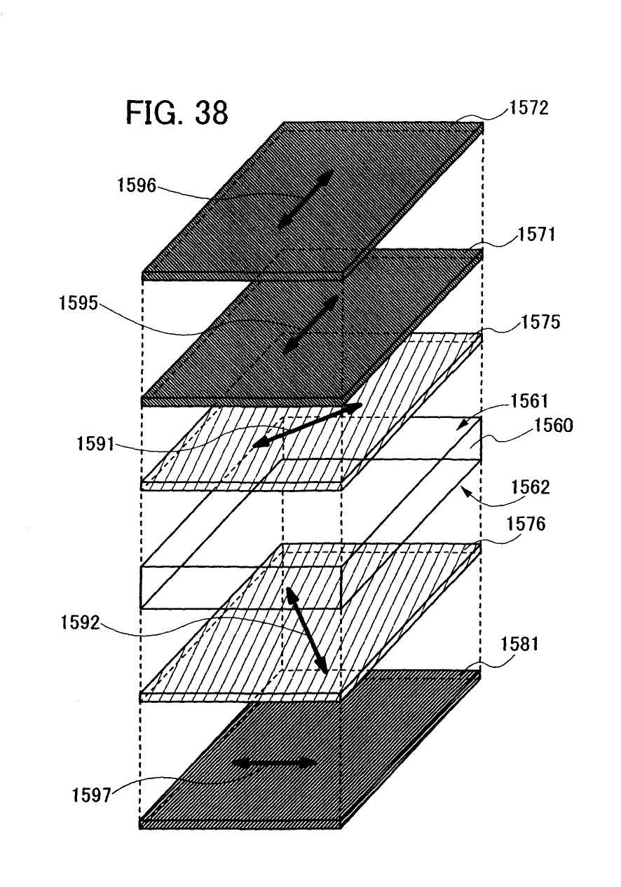

As shown in FIG. 38, a layer 1560 including a display element is interposed between a first substrate 1561 and a second substrate 1562 which are arranged to be opposite to each other

As shown in FIG. 38, on the first substrate 1561 side, a retardation plate 1575, a first polarizing plate 1571, and a second polarizing plate 1572 are sequentially provided from the substrate side. That is, on the first substrate 1561 side, a polarizing plate 1573 having a stacked structure is formed from the first polarizing plate 1571 and the second polarizing plate 1572. On the second substrate 1562 side, a retardation plate 1576 and a third polarizing plate 1581 are sequentially provided from the substrate side. That is, on the second substrate 1562 side, a polarizing plate having a single layer structure is formed from the third polarizing plate 1581.

It is acceptable as long as the display element is a liquid crystal element for a liquid crystal display device, and is an electroluminescent element for a light emitting display device.

Light-transmitting substrates are used for the first substrate 1561 and the second substrate 1562. As such light-transmitting substrates, for example, a glass substrate such as barium borosilicate glass or alumino-borosilicate glass, a quartz substrate, or the like can be used. Alternatively, a substrate formed from a synthetic resin having flexibility, such as a plastic, typified by polyethylene terephthalate (PET), polyethylene naphthalate (PEN), polyethersulfone (PES), or polycarbonate (PC), or acrylic, can be used for the light-transmitting substrates.

A retardation plate and stacked polarizers, and a retardation plate and a polarizer having a single layer structure are provided on the outer sides of the substrate 1561 and the substrate 1562, namely on the sides which are not in contact with the layer 1560 including the display element from the substrates 1561 and 1562, respectively. Note that in this embodiment mode, as the structure of the stacked polarizers, polarizing plates each including one polarizing film shown in FIG. 2A are stacked. Needless to say, the structures shown in FIGS. 2B and 2C may also be used.

In the liquid crystal display device, light from a backlight (not shown) is extracted outside, passing through the layer including the liquid crystal element, the substrate, the retardation plate, and the polarizer. In the light emitting display device, light from the electroluminescent element is emitted to the first substrate 1561 side and the second substrate 1562 side.

Light which has passed through the layer including having a liquid crystal element or light emitted from the electroluminescent element is circularly polarized by the retardation plate and linearly polarized by the polarizing plate. That is, the stacked polarizing plates can be referred to as a linear polarizing plate having a stacked structure. The stacked polarizing plates indicate a state where two or more polarizing plates are stacked. The polarizing plate having a single layer structure refers to a state where one polarizing plate is provided.

The first polarizing plate 1571 and the second polarizing plate 1572 are arranged in such a way that an absorption axis 1595 of the first polarizing plate 1571 and an absorption axis 1596 of the second polarizing plate 1572 should be parallel. This parallel state is referred to as a parallel Nicols state.

The polarizing plates 1571 and 1572 in this manner are arranged to be in a parallel Nicols state.

The absorption axis 1595 (and the absorption axis 1596) of the polarizing plates 1571 and 1572 and an absorption axis 1597 of the polarizing plate 1581 having a single layer structure are orthogonal to each other. In other words, the absorption axes of polarizing plates opposite to each other via the layer including the display device are arranged to be orthogonal to each other. This orthogonal state is referred to as a crossed Nicols state.

Note that transmission axes exist in the direction orthogonal to the absorption axes based on the characteristics of the polarizing plates. Therefore, a state in which the transmission axes are parallel to each other can also be referred to as parallel Nicols. In addition, a state in which the transmission axes are orthogonal to each other can be also referred to as a crossed Nicols state.

The extinction coefficients of the polarizing plates 1571, 1572 and 1581 preferably have the same wavelength distribution.

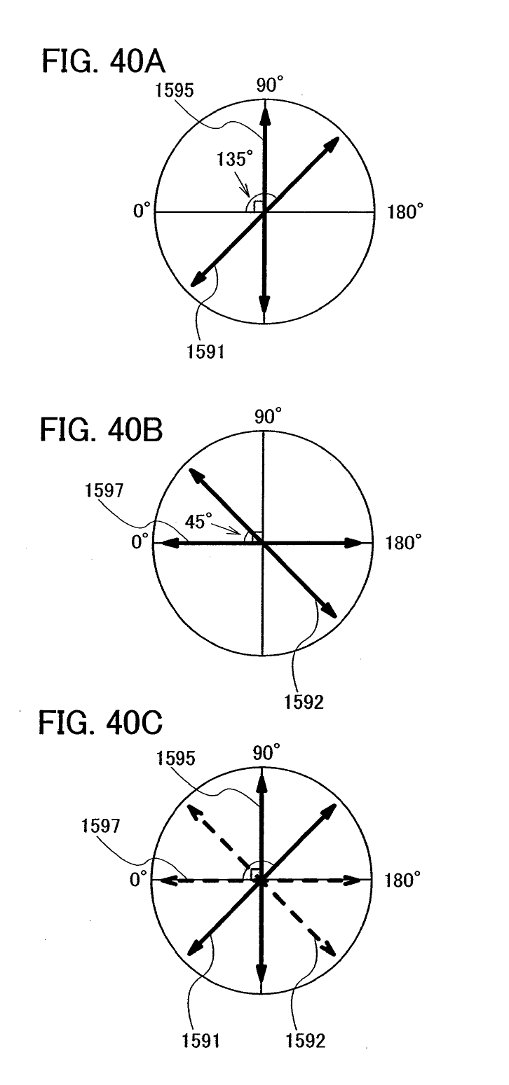

With reference to FIGS. 38, and 40A to 40C, the angular deviation between a slow axis 159 and a slow axis 1592 of the retardation plates is described. In FIG. 38, the arrow 1591 shows a slow axis of the retardation plate 1575 and the arrow 1592 shows a slow axis of the retardation plate 1576.

The slow axis 1591 of the retardation plate 1575 is arranged to be shifted from the absorption axis 1595 of the first polarizing plate 1571 and the absorption axis 1596 of the second polarizing plate 1572 by 45°.

FIG. 40A shows angular deviation between the absorption axis 1595 of the first polarizing plate 1571 and the slow axis 1591 of the retardation plate 1575. The angle formed by the slow axis 1591 of the retardation plate 1575 and the transmission axis of the polarizing plate 1571 is 135° and the angle formed by the absorption axis 1595 of the first polarizing plate 1571 and the transmission axis of the polarizing plate 1571 is 90°, which means they are shifted from each other by 45°.

The slow axis 1592 of the retardation plate 1576 is arranged to be shifted from the absorption axis 1597 of the third polarizing plate 1581 by 45°.

FIG. 40B shows angular deviation of the absorption axis 1597 of the third polarizing plate 1581. The formed by the slow axis 1592 of the retardation plate 1576 and the absorption axis 1597 of the third polarizing plate 1581 is 45°. In other words, the slow axis 1591 of the retardation plate 1575 is arranged to be shifted by 45° from the absorption axis 1595 of the first linear polarizing plate 1571 and the absorption axis 1596 of the second linear polarizing plate 1572. The slow axis 1592 of the retardation plate 1576 is arranged to be shifted by 45° from the absorption axis 1597 of the third linear polarizing plate 1581.

The absorption axis 1595 (and the absorption axis 1596) of the polarizing plates 1571 and 1572 provided over the first substrate 1561, and the absorption axis 1597 of the polarizing plate 1581 which has a single layer structure and provided under the second substrate 1562 are orthogonal to each other. In other words, the polarizing plates opposite to each other via the layer including the display device are arranged to be in a crossed Nicols state.

FIG. 40C shows a state where the absorption axis 1595 and the slow axis 1591 each indicated by a solid line and the absorption axis 1597 and the slow axis 1592 each indicated by a dashed line overlap each other. FIG. 40C shows that the absorption axis 1595 and the absorption axis 1597 are orthogonal, and the slow axis 1591 and the slow axis 1592 are also orthogonal.

A fast axis exists in the direction orthogonal to the slow axis based on the characteristics of the retardation plate. Therefore, arrangement of the retardation plate and the polarizing plate can be determined using not only the slow axis but also the fast axis. In this embodiment mode, the absorption axis and the slow axis are arranged to be shifted from each other by 45°, in other words, the absorption axis and the fast axis are arranged to be shifted from each other by 135°.

In this specification, it is assumed that the above angle condition is satisfied when angular deviation between absorption axes, angular deviation of an absorption axis and a slow axis, or angular deviation of slow axes is described; however, the angular deviation between the axes may differ from the above-described angles to some extent as long as a similar effect can be obtained.

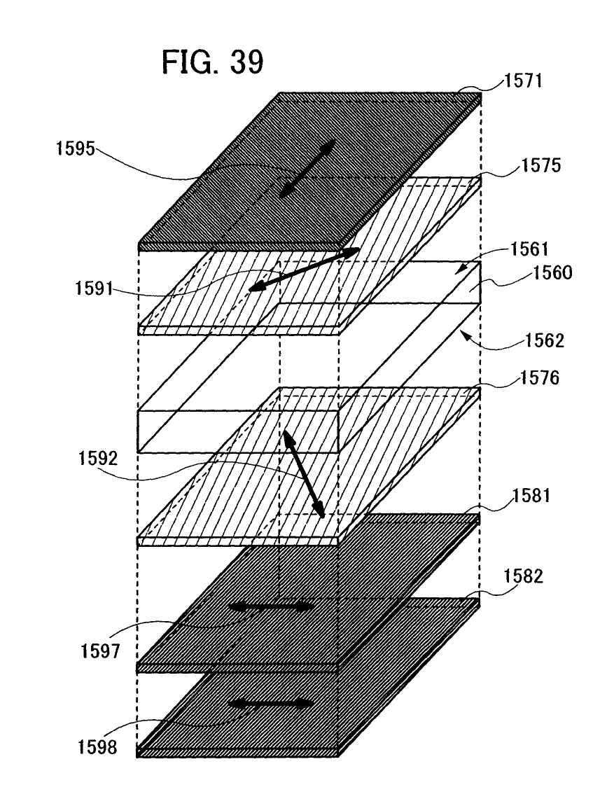

FIG. 39 shows a different stacked structure from that in FIG. 38. In FIG. 39, on the first substrate 1561 side, the retardation plate 1575 and the first polarizing plate 1571 are sequentially provided from the substrate side. That is, on the first substrate 1561 side, a polarizing plate having a single layer structure is formed from the first polarizing plate 1571. On the second substrate 1562 side, the retardation plate 1576, and the third polarizing plate 1581 and a fourth polarizing plate 1582 which are stacked, are sequentially provided from the substrate side. That is, on the second substrate 1562 side, a polarizing plate 1583 having a stacked structure is formed from the second polarizing plate 1581 and the third polarizing plate 1582.

An absorption axis 1598 of the third polarizing plate 1582 and the absorption axis 1597 of the second polarizing plate 1581 are arranged to be parallel Therefore, angular deviation between the absorption axis and the slow axis are the same as that of the structure shown in FIG. 38, and description thereof is omitted here.

The extinction coefficients of the polarizing plates 1571, 1581 and 1582 preferably have the same wavelength distribution.

As described above, by using polarizing plates stacked on a circularly polarizing plate on one side, and the polarizing plates opposite to each other via the layer including the display device are arranged to be in a crossed Nicols state. Thus, light leakage in the absorption axis direction can be reduced. Consequently, the contrast ratio of the display device can be increased.

In this embodiment mode, an example in which stacked polarizing plates are used as an example of the stacked polarizers and one polarizing plate is provided on one substrate side and two polarizing plates are provided on the other side is described. However, the number of stacked polarizers is not necessarily two, and three or more polarizers may be stacked.

In addition, this embodiment mode can be freely combined with any of other embodiment modes and other examples in this specification, if necessary.

### Embodiment Mode 28

Embodiment Mode 28 will describe a concept of a display device using a circularly polarizing plate having stacked polarizers and a circularly polarizing plate having one polarizer.

This embodiment mode can be applied to the transmissive type liquid crystal display devices (Embodiment Modes 7 to 9) and the dual-emission light emitting display devices (Embodiment Modes 18 and 19).

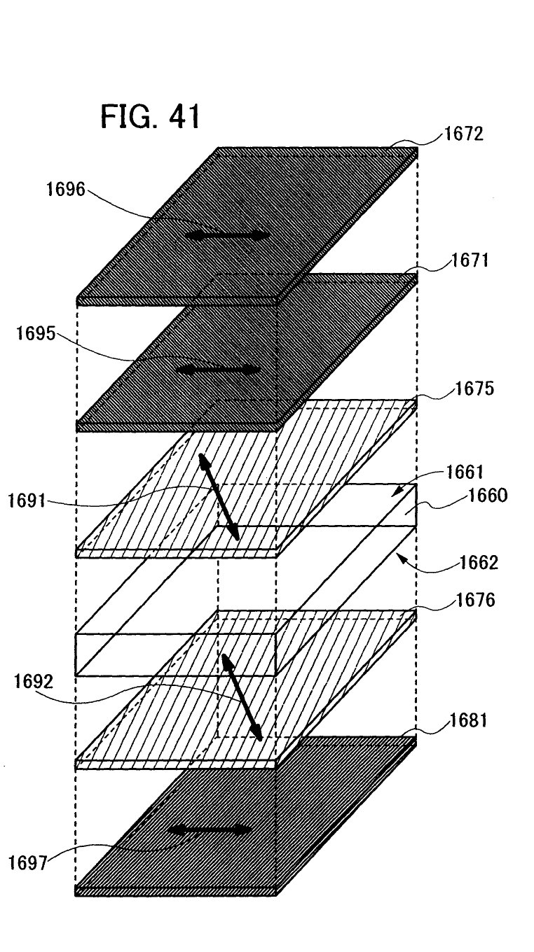

As shown in FIG. 41, a layer 1660 including a display element is interposed between a first substrate 1661 and a second substrate 1662 which are arranged to be opposite to each other.

The display element may be a liquid crystal element for a liquid crystal display device, and may be an electroluminescent element for a light emitting display device.

Light-transmitting substrates are used for the first substrate 1661 and the second substrate 1662. As the light-transmitting substrates, materials similar to those of the substrate 1561 and the substrate 1562 described in Embodiment Mode 27 may be used.

On the outer sides of the substrate 1661 and the substrate 1662, namely on the sides which are not in contact with the layer 1660 including the display element from the substrates 1661 and 1662, stacked polarizers and a polarizer having a single layer structure are provided, respectively. Note that in this embodiment mode, as the structure of the stacked polarizers, polarizing plates each including one polarizing film shown in FIG. 2A are stacked. Needless to say, the structures shown in FIGS. 2B and 2C may also be used.

In the liquid crystal display device, light from a backlight (not shown) is extracted outside, passing through a layer including a liquid crystal element, the substrate, a retardation plate, and the polarizer. In the light emitting display device, light from the electroluminescent element is emitted to the first substrate 1661 side and the second substrate 1662 side.

Light which has passed through the layer including having a liquid crystal element or light emitted from the electroluminescent element is linearly polarized by the polarizing plate. That is, the stacked polarizing plates. The stacked polarizing plates indicate a state where two or more polarizing plates are stacked. The polarizing plate having a single layer structure refers to a state where one polarizing plate is provided.

As shown in FIG. 41, on the first substrate 1661 side, a retardation plate 1675, a first polarizing plate 1671, and a second polarizing plate 1672 are sequentially provided from the substrate side. That is, on the first substrate 1661 side, a stacked polarizing plate 1673 is formed from the first polarizing plate 1671 and the second polarizing plate 1672. On the second substrate 1662 side, a retardation plate 1676 and a third polarizing plate 1681 are sequentially provided from the substrate side. That is, on the second substrate 1662 side, the polarizing plate having a single layer structure is formed from the third polarizing plate 1681.

The first polarizing plate 1671 and the second polarizing plate 1672 are arranged in such a way that an absorption axis 1695 of the first polarizing plate 1671 and an absorption axis 1696 of the second polarizing plate 1672 should be parallel, namely the polarizing plates 1671 and 1672 are arranged to be in a parallel Nicols state. A slow axis 1691 of the first retardation plate 1675 is arranged to be shifted from the absorption axis 1695 of the first polarizing plate 1671 and the absorption axis 1696 of the second polarizing plate 1672 by 45°.

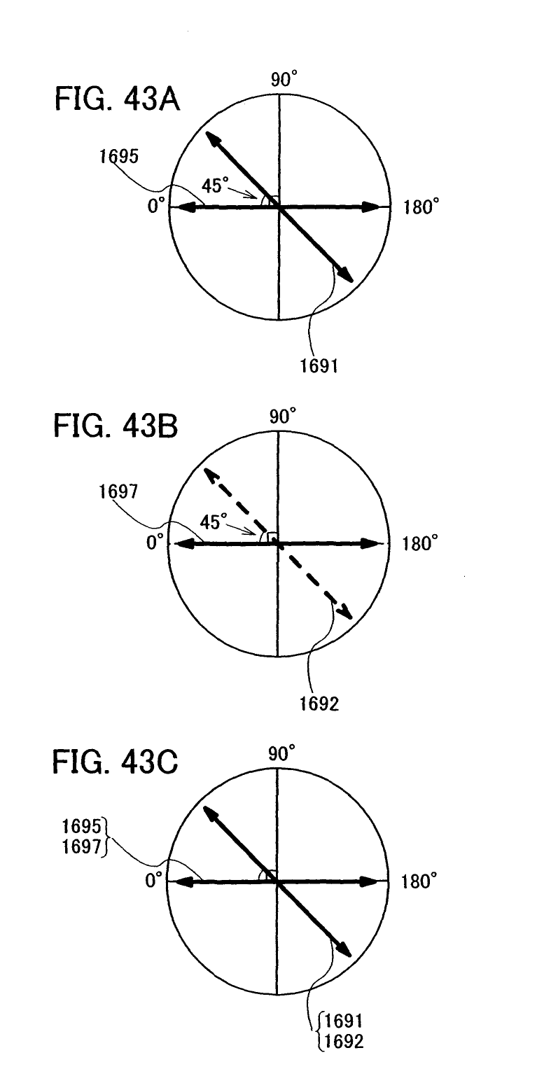

FIG. 43A shows angular deviation of the absorption axis 1695 (and the absorption axis 1696) and the slow axis 1691. The slow axis 1691 is 45° and the absorption axis 1695 (and the absorption axis 1696) is 0°, which means that they are shifted from each other by 45°

On the outer side of the second substrate 1662, the retardation plate 1676 and the third polarizing plate 1681 are sequentially provided. A slow axis 1692 of the retardation plate 1676 is arranged to be shifted from an absorption axis 1697 of the third polarizing plate 1681 by 45°.

FIG. 43B shows the angular deviation between the absorption axis 1697 and the slow axis 1692. The slow axis 1692 is 45° and the absorption axis 1697 is 0°, which means that they are shifted from each other by 45°.

That is, the slow axis 1691 of the retardation plate 1675 is arranged to be shifted from the absorption axis 1695 of the first linear polarizing plate 1671 and the absorption axis 1696 of the second linear polarizing plate 1672 by 45°. The slow axis 1692 of the retardation plate 1676 is arranged to be shifted from the absorption axis 1697 of the third linear polarizing plate 1681 by 45°. The absorption axis 1697 of the third linear polarizing plate 1681 is arranged so as to be parallel to the absorption axis 1695 of the first linear polarizing plate 1671 and the absorption axis 1696 of the second linear polarizing plate 1672.

One feature of the present invention is that the absorption axis 1695 (and the absorption axis 1696) of the polarizing plate 1673 having the stacked structure provided over the first substrate 1661 and the absorption axis 1697 of the polarizing plate 1681 provided for the second substrate 1662 are parallel to each other. In other words, the polarizing plate 1673 having the stacked structure and the polarizing plate 1681 having a single layer structure, namely opposite polarizing plates, are arranged so as to be in a parallel Nicols state.

FIG. 43C shows a state where the absorption axis 1695 and the absorption axis 1697 overlap with each other, and the slow axis 1691 and the slow axis 1692 overlap with each other, which means that they are in a parallel Nicols state.

Extinction coefficients of the polarizing plates 1671, 1672 and 1681 preferably have the same wavelength distribution.

As the circularly polarizing plate, a circularly polarizing plate with a widened band is given. The circularly polarizing plate with a widened band is an object in which a wavelength range in which phase difference (retardation) is 90°, is widened by stacking several retardation plates. Also in this case, a slow axis of each retardation plate arranged on the outer side of the first substrate 1661 and a slow axis of each retardation plate arranged on the outer side of the second substrate 1662 may be arranged to be parallel to each other, and absorption axes of opposite polarizing plates may be arranged to be in a parallel Nicols state.

Since the stacked polarizing plates are stacked such that their absorption axes are in a parallel Nicols state, light leakage in the absorption axis direction can be reduced. The opposite polarizing plates are arranged to be in a parallel Nicols state. Since a circularly polarizing plate is provided, light leakage can be further reduced compared to a circularly polarizing plate in which a pair of single polarizing plates is arranged to be in a parallel Nicols state. Accordingly, the contrast ratio of the display device can be increased.

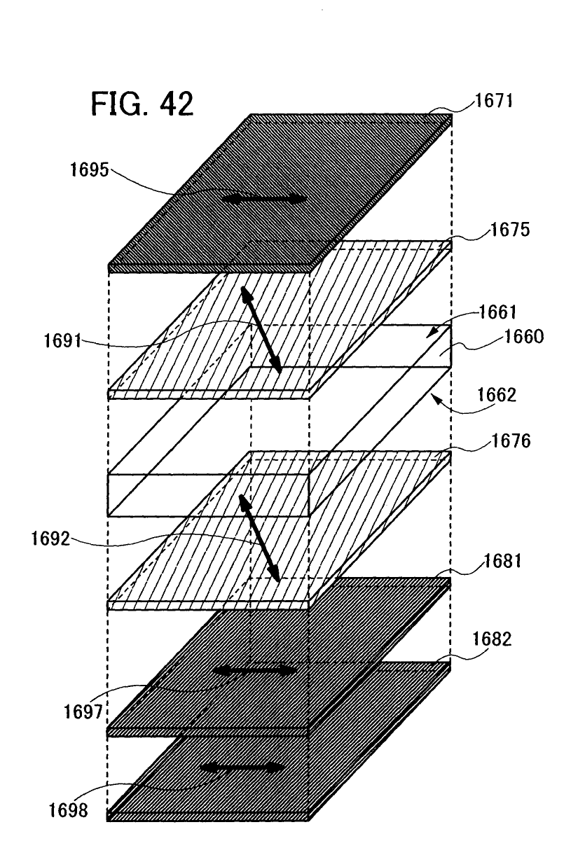

As shown in FIG. 42, on the first substrate 1661 side, the retardation plate 1675 and the first polarizing plate 1671 are sequentially provided from the substrate side. That is, on the first substrate 1661 side, a polarizing plate having a single layer structure is formed from the first polarizing plate 1671. On the second substrate 1662 side, the retardation plate 1676, the third polarizing plate 1681, and a fourth polarizing plate 1682 are sequentially provided from the substrate side. That is, on the second substrate 1662 side, a polarizing plate 1683 having a stacked structure is formed from the third polarizing plate 1681 and the fourth polarizing plate 1682.

The fourth polarizing plate 1682 and the third polarizing plate 1681 are arranged in such a way that an absorption axis 1698 of the fourth polarizing plate 1682 and the absorption axis 1697 of the third polarizing plate 1681 are arranged to be parallel to each other. Therefore, angular deviation of the absorption axis and the slow axis are the same as that of the structure shown in FIG. 43, and description thereof is omitted here.

Extinction coefficients of the polarizing plates 1671, 1681 and 1682 preferably have the same wavelength distribution.

Since the stacked polarizing plates in one circularly polarizing plate are provided and arranged such that transmission axes of opposite polarizing plates are arranged in a parallel Nicols state, light leakage in the transmission axis direction can be reduced. Accordingly, the contrast ratio of the display device can be increased.

In this embodiment mode, the example in which stacked polarizing plates are used as an example of the stacked polarizers and one polarizing plate is provided on one substrate side and two polarizing plates are provided on the other side is described. However, the number of stacked polarizers is not necessarily two, and three or more polarizers may be stacked.

In addition, this embodiment mode can be freely combined with any of other embodiment modes and other examples in this specification, if necessary.

### Embodiment Mode 29

As driving methods for liquid crystals in liquid crystal display devices, there is a vertical electric field method in which a voltage is applied perpendicularly to a substrate, and a horizontal electric field method in which a voltage is applied parallel to a substrate. The structure of the present invention, in which plural stacked polarizing plates are provided, can be applied to either the vertical electric field method or to the horizontal electric field method. Therefore, in this embodiment mode, examples of various types of liquid crystal modes to which a liquid crystal display device of the present invention can be applied will be explained.

This embodiment mode can be applied to liquid crystal display devices (Embodiment Modes 4 to 15, Embodiment Modes 25 to 28).

Note that the same elements are denoted by the same reference numerals in this embodiment mode.

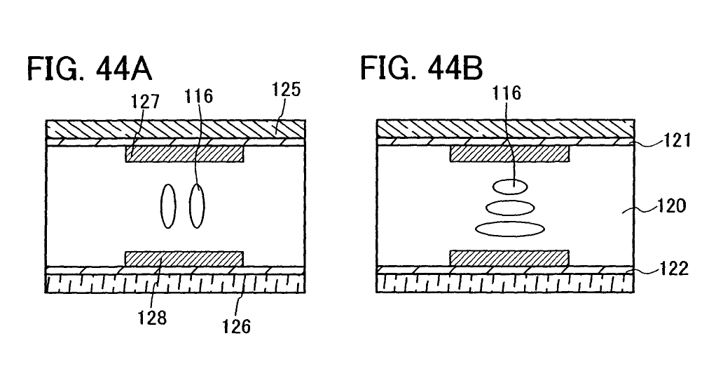

First, FIGS. 44A and 44B schematically show a Twisted Nematic (TN) mode liquid crystal display device.

A layer 120 having a liquid crystal element is interposed between a first substrate 121 and a second substrate 122 which are disposed so as to be opposite to each other. On the first substrate 121 side, a layer 125 including a polarizer is formed. Further, on the second substrate 122 side, a layer 126 including a polarizer is formed. The layers 125 and 126 each including a polarizer may have any of the structures described in Embodiment Modes 4 to 15 and Embodiment Modes 25 to 28. In other words, a circular polarizing plate including stacked polarizers may be provided, or only the stacked polarizers may be used without using a retardation plate. The numbers of polarizers above and below a layer including a display element may be equal or different. Moreover, the stacked polarizers may be in crossed Nicols or parallel Nicols above and below the substrate. When a reflective type liquid crystal display device is manufactured, one of the layers 125 and 125 including a polarizer is not necessarily formed. However, in the reflective type liquid crystal display device, both a retardation plate and a polarizer are provided for display in black.

In this embodiment mode, extinction coefficients of the stacked polarizers preferably have the same wavelength distribution.

A first electrode 127 and a second electrode 128 are provided over the first substrate 121 and the second substrate 122, respectively. In the case of a transmissive type liquid crystal display device, the electrode on the side opposite to backlight, i.e., the electrode on the display surface side, for example, the second electrode 128 has at least a light-transmitting property. In addition, in the case of a reflective type liquid crystal display device, one of the first electrode 127 and the second electrode 128 has a reflective property and the other one has a light-transmitting property.

In a liquid crystal display device with such a structure, in the case of normally white mode, when a voltage is applied to the first electrode 127 and the second electrode 128 (this is called the vertical electric field method), display in black is conducted as shown in FIG. 44A. At this time, the liquid crystal molecules line up vertically. Then, light from the backlight cannot pass through the substrate, and display in black results. Further, in the case of the reflective type liquid crystal display device, a retardation plate is provided, and as for light from the outside, light composition which oscillates in the direction of the transmission axis of the polarizer can be transmitted and becomes linear polarized light. This light becomes circularly polarized light by passing through the retardation plate (for example, right-handed circularly polarized light). When this right-handed circularly polarized light is reflected on a reflective plate (or a reflective electrode), it becomes left-handed circularly polarized light. When this left-handed circularly polarized light passes through the retardation plate, it becomes linear polarized light which oscillates perpendicularly to the transmission axis of the polarizer (parallel to the absorption axis). Therefore, light is absorbed by the absorption axis of the polarizer, and thus, display in black results.

Then, as shown in FIG. 44B, when a voltage is not applied between the first electrode 127 and the second electrode 128, display in white results. At this time, the liquid crystal molecules 116 line up horizontally, and rotate within the plane. As a result, in the case of the transmissive type liquid crystal display device, light from the backlight can pass through the substrates provided with the layers 125 and 126 each including a polarizer, and display of a designated image can be conducted. In addition, in the case of the reflective type liquid crystal display device, reflected light pass through the substrate provided with the layer including a polarizer, and display of a designated image can be conducted. At this time, full color display can be conducted by the provision of a color filter. The color filter can be provided on either the first substrate 121 side or on the second substrate 122 side.

A known liquid crystal material may be used as a liquid crystal material for the TN mode.

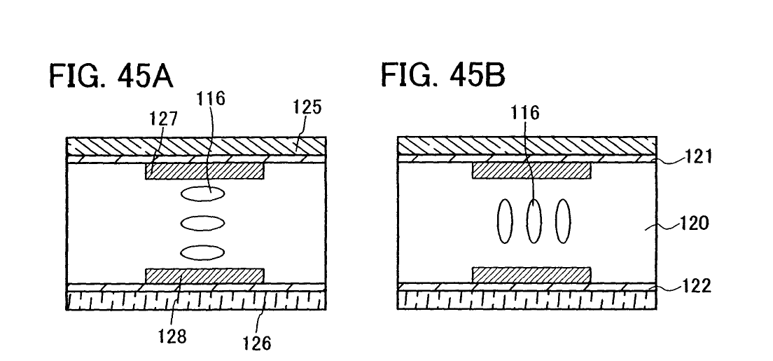

Next, FIGS. 45A and 45B show schematic diagrams of a Vertically Aligned (VA) mode liquid crystal display device. In VA mode, when no electric field is applied, liquid crystals are oriented such that they are perpendicular to substrates.

Similarly to FIGS. 44A and 44B, in the liquid crystal display device shown in FIGS. 45A and 45B, the first electrode 127 and the second electrode 128 are provided for the first substrate 121 and the second substrate 122, respectively. In the case of a transmissive type liquid crystal display device, the electrode on the side opposite to backlight, i.e., the electrode on the display surface side, for example, the second electrode 128 has at least a light-transmitting property. In addition, in the case of a reflective type liquid crystal display device, one of the first electrode 127 and the second electrode 128 has a reflective property and the other one has a light-transmitting property.

In a liquid crystal display device having such a structure, when a voltage is applied to the first electrode 127 and the second electrode 128 (the vertical electric field method), an on-state in which display in white is conducted results, as shown in FIG. 45A. At this time, the liquid crystal molecules 116 line up horizontally. As a result, in the case of the transmissive type liquid crystal display device, light from the backlight can pass through the substrates provided with the layers 125 and 126 each including a polarizer, and display of a designated image can be conducted. In addition, in the case of the reflective type liquid crystal display device, reflected light pass through the substrate provided with the layers including polarizers, and display of a designated image can be conducted. At this time, full color display can be conducted by the provision of a color filter. The color filter can be provided on either the first substrate 121 side or on the second substrate 122 side.

Then, as shown in FIG. 45B, when a voltage is not applied between the first electrode 127 and the second electrode 128, display in black, that is, an off-state, results. At this time, the liquid crystal molecules 116 line up vertically. As a result, in the case of the transmissive type liquid crystal display device, light from the backlight cannot pass through the substrates, and display in black results. Further, in the case of the reflective type liquid crystal display device, a retardation plate is provided, and as for light from the outside, light composition which oscillates in the direction of the transmission axis of the polarizer can be transmitted and becomes linear polarized light. This light becomes circularly polarized light by passing through the retardation plate (for example, right-handed circularly polarized light). When this right-handed circularly polarized light is reflected on a reflective plate (or a reflective electrode), it becomes left-handed circularly polarized light. When this left-handed circularly polarized light passes through the retardation plate, it becomes linear polarized light which oscillates perpendicularly to the transmission axis of the polarizer (parallel to the absorption axis). Therefore, light is absorbed by the absorption axis of the polarizer, and thus, display in black results.

In this manner, in the off-state, the liquid crystal molecules stand up perpendicularly to the substrates and display in black results, and in the on-state, the liquid crystal molecules 116 fall parallel to the substrate, and display in white results. In the off-state, since the liquid crystal molecules 116 are standing up, polarized light from the backlight can pass through the cell without being affected by the liquid crystal molecules 116 and can be completely blocked by the polarizer on the opposite substrate side, in the case of the transmissive type liquid crystal display device. The case of the reflective liquid crystal display device is as described above. Therefore, by providing layers each including a polarizer, further improvement of the contrast ratio can be expected.

A known material may be used as a liquid crystal material for VA mode.

The present invention can be applied to MVA mode in which orientation direction of liquid crystals is divided.

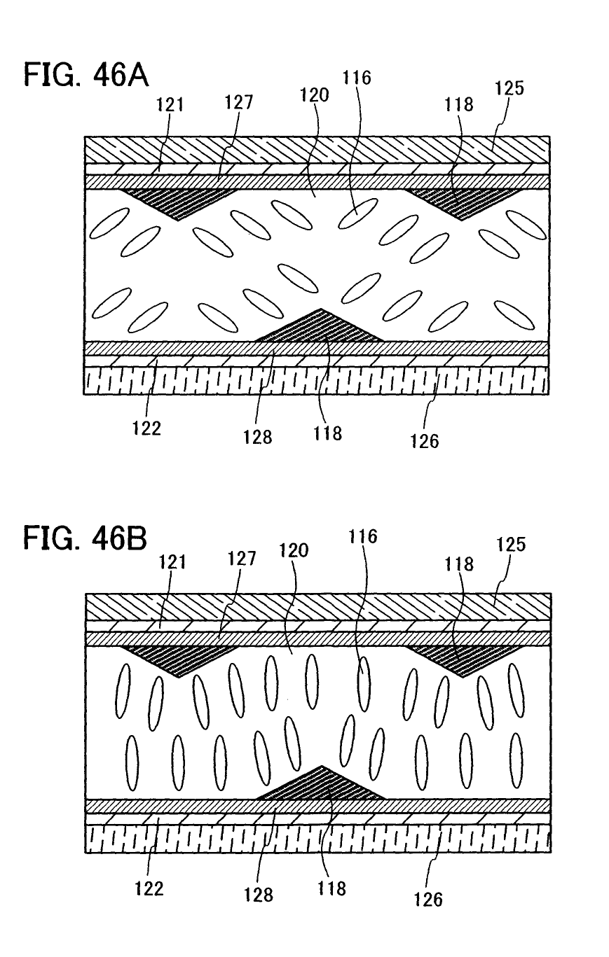

FIGS. 46A and 46B show a schematic view of a liquid crystal display device with an MVA (Multi-domain Vertically Aligned) mode.

The liquid crystal display device shown in FIGS. 46A and 46B is similar to that shown in FIGS. 44A and 44B. The first electrode 127 and the second electrode 128 are provided over the first substrate 121 and the second substrate 122, respectively. In the case of a transmissive type liquid crystal display device, the electrode on the opposite side of a backlight, i.e., the electrode on the display surface side, for example, the second electrode 128 is formed so as to have at least a light-transmitting property. In addition, in the case of a reflective type liquid crystal display device, one of the first electrode 127 and the second electrode 128 has a light-reflecting property and the other one thereof has a light-emitting property.

A plurality of protrusions (also referred to as ribs) 118 are formed on the first substrate 128 and the second electrode 128. The protrusion 118 may be formed from a resin such as acrylic. The protrusion 118 may be symmetrical, preferably a tetrahedron.

In the MVA mode, the liquid crystal display device is driven so that the liquid crystal molecules 116 incline symmetrically with respect to the protrusion 118. Accordingly, a difference in color seen from right and left sides can be reduced. When inclination directions of the liquid crystal molecules 116 are varied in a pixel, uneven color is not generated in any directions when the display device is seen.

FIG. 46A shows a state in which a voltage is applied, in other words, on-state. In the on-state, an inclined electric field is applied; accordingly, the liquid crystal molecules 116 incline along the direction perpendicular to the inclined surfaces of the protrusion 118. Accordingly, the long axes of the liquid crystal molecule 116 and an absorption axis of the polarizing plate intersect with each other, and light passes through one of the layers 125 and 126 each including a polarizer which is an extraction side of light, and a light state (display in white) results.

FIG. 46B shows a state in which a voltage is not applied, that is, an off-state. In the off-state, the liquid crystal molecules 116 line up to be perpendicular to the substrates 121 and 122. Therefore, incident light entered from one of the layers 125 and 126 each including a polarizer which are provided for the substrate 121 and 122 respectively, directly passes through the liquid crystal molecules 116, and intersects with the other one of the layers 125 and 126 each including a polarizer which is an extraction side of light, at right angles. Accordingly, the light is not emitted, and a dark state (display in black) results.

By providing the protrusion 118, the liquid crystal display device is driven so that the liquid crystal molecules 116 incline along the direction perpendicular to the inclined surfaces of the protrusion 118, and display with a symmetric property and an excellent viewing angle characteristic can be obtained.

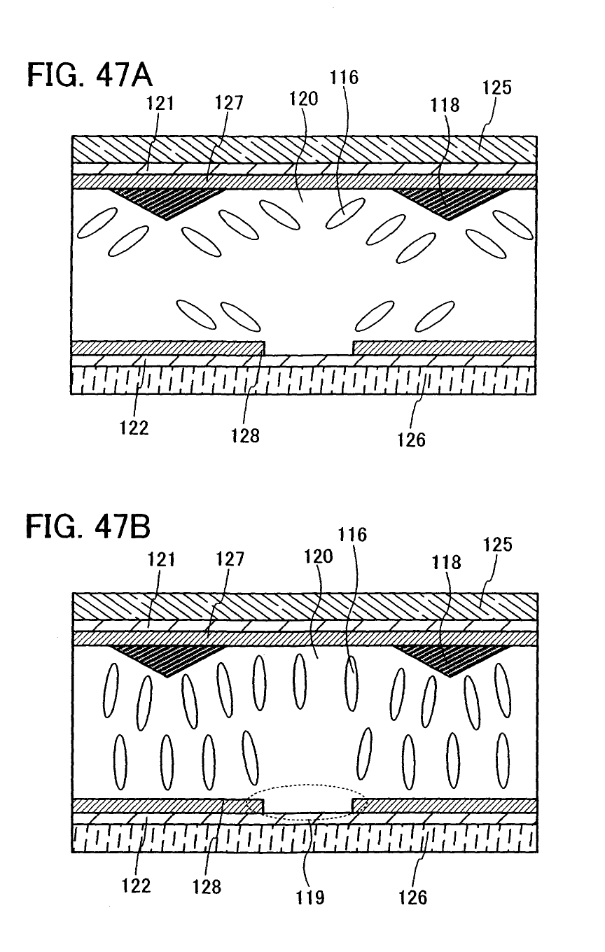

FIGS. 47A and 47B show another example of the MVA mode. Protrusions are provided on one of the first electrode 127 and the second electrode 128, in this embodiment mode, on the first electrode 127, and a part of the other of the first electrode 127 and the second electrode 128, in this embodiment mode, a part of the second electrode 128 is removed to form a slit 119.

FIG. 47A shows a state where a voltage is applied, in other words, on-state. At the time of on-state when the voltage is applied, an inclined electric field is generated near the slit 119, even if the protrusions 118 are not provided. By the inclined electric field, the liquid crystal molecules 116 are inclined along the direction perpendicular to the inclined surfaces of the protrusions 118. Thus, the long axes of the liquid crystal molecules 116 and an absorption axis of the polarizing plate intersect with each other, and light passes through one of the layers 125 and 126 each including a polarizer, and a light state (display in white) results.

FIG. 47B shows a state in which a voltage is not applied, that is, an off-state. In the off-state, the liquid crystal molecules 116 align to be perpendicular to the substrates 121 and 122. Therefore, incident light entered through one of the layers 125 and 126 each including a polarizer which are provided for the substrate 121 and 122 respectively, directly passes through the liquid crystal molecules 116, and intersects with the other one of the layers 125 and 126 each including a polarizer which is an extraction side of light, at right angles. Accordingly, the light is not emitted, and a dark state (display in black) results.

A known liquid crystal material may be used as a liquid crystal material for the MVA mode.

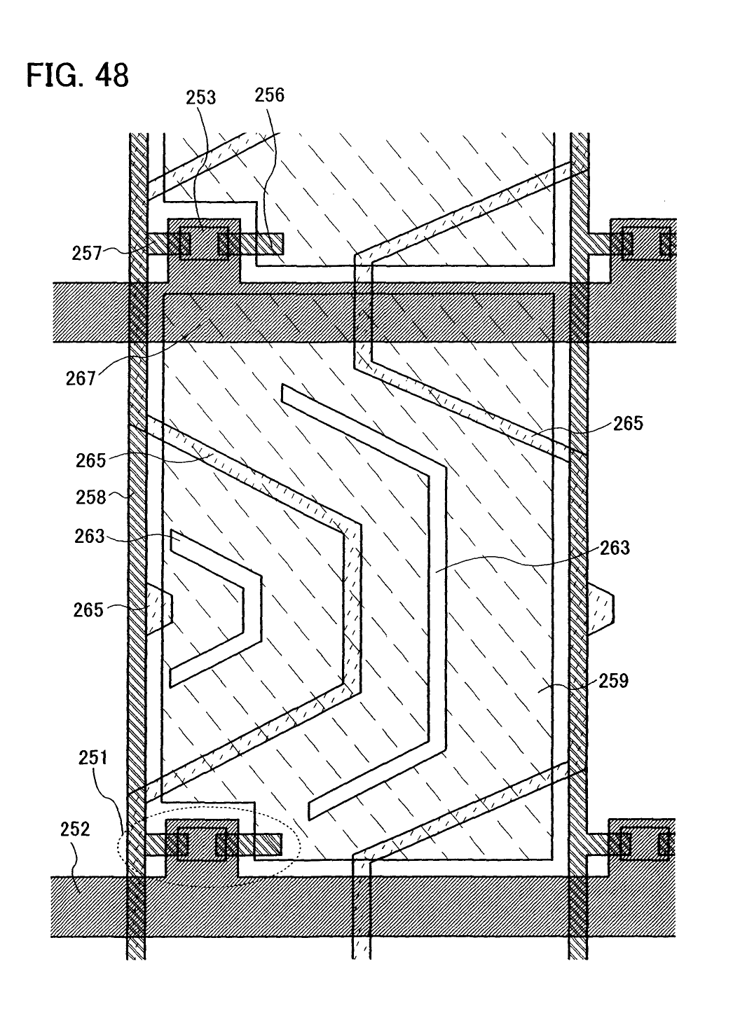

FIG. 48 shows a top view of an arbitrary pixel in the liquid crystal display device with MVA mode shown in FIGS. 47A and 47B, as an example.

A TFT 251 serving as a switching element of a pixel includes a gate wiring 252, a gate insulating film, an island-shaped semiconductor film 253, a source electrode 257 and a drain electrode 256.

Note that in this embodiment mode, the source electrode 257 and the source wiring 258 are formed in the same step and from the same material; however, they may be formed in different steps and from different materials and then may be electrically connected.

The pixel electrode 259 is electrically connected to the drain electrode 256.

A plurality of grooves 263 are formed in the pixel electrode 259.

In a region where the gate wiring 252 and the pixel electrode 259 are overlapped, an auxiliary capacitor 267 using the gate insulating film as a dielectric is formed.

On the opposite electrodes side (not shown) provided for the opposite substrate, a plurality of protrusions (also referred to as ribs) 265 are formed. The protrusions 265 may be formed from resin such as acrylic. The protrusions 265 may be symmetrical, preferably a tetrahedron.

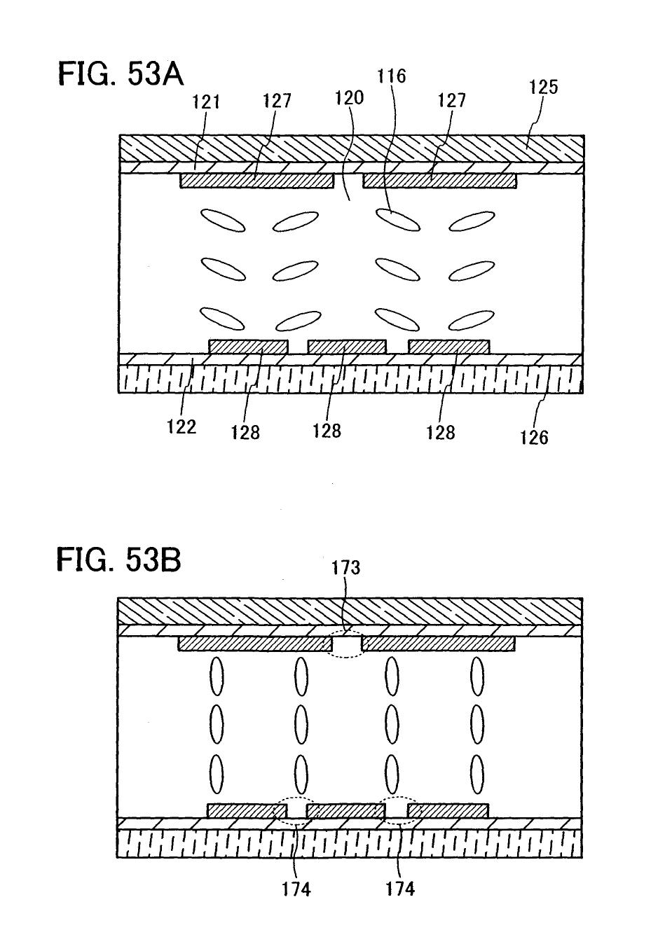

FIGS. 53A and 53B schematically show a liquid crystal display device with a Patterned Vertical Alignment (PVA) mode.

FIGS. 53A and 53B show movement of the liquid crystal molecules 116.

In the PVA mode, grooves 173 of an electrode 127 and grooves 174 of an electrode 128 are provided so as to be misaligned from each other, and the liquid crystal molecules 116 are aligned toward the grooves 173 and the grooves 174 which are misaligned.

FIGS. 53A and 53B show a state in which a voltage is applied, in other words, on-state. At the time of on-state, when an inclined electric field is applied, the liquid crystal molecules 116 are inclined diagonally. Thus, the long axes of the liquid crystal molecule 116 and an absorption axis of the polarizing plate intersect with each other, and light passes through one of the layers 125 and 126 each including a polarizer which is an extraction side of light, and a light state (display in white) results.

FIG. 53B shows a state in which a voltage is not applied, that is, an off-state. In the off-state, the liquid crystal molecules 116 line up to be perpendicular to the substrates 121 and 122. Therefore, incident light entered through one of the layers 125 and 126 each including a polarizer which are provided for the substrate 121 and 122 respectively, directly passes through the liquid crystal molecules 116, and intersects with the other one of the layers 125 and 126 each including a polarizer which is an extraction side of light, at right angles. Accordingly, the light is not emitted, and a dark state (display in black) results.

By providing the grooves 173 in the electrode 127 and the grooves 174 in the pixel electrode 128, by the inclined electric field toward the grooves 173 and 174, the liquid crystal molecules 116 are driven obliquely. Accordingly, display with a symmetric property in an oblique direction as well as up and down or right and left and with an excellent viewing angle characteristic can be obtained.

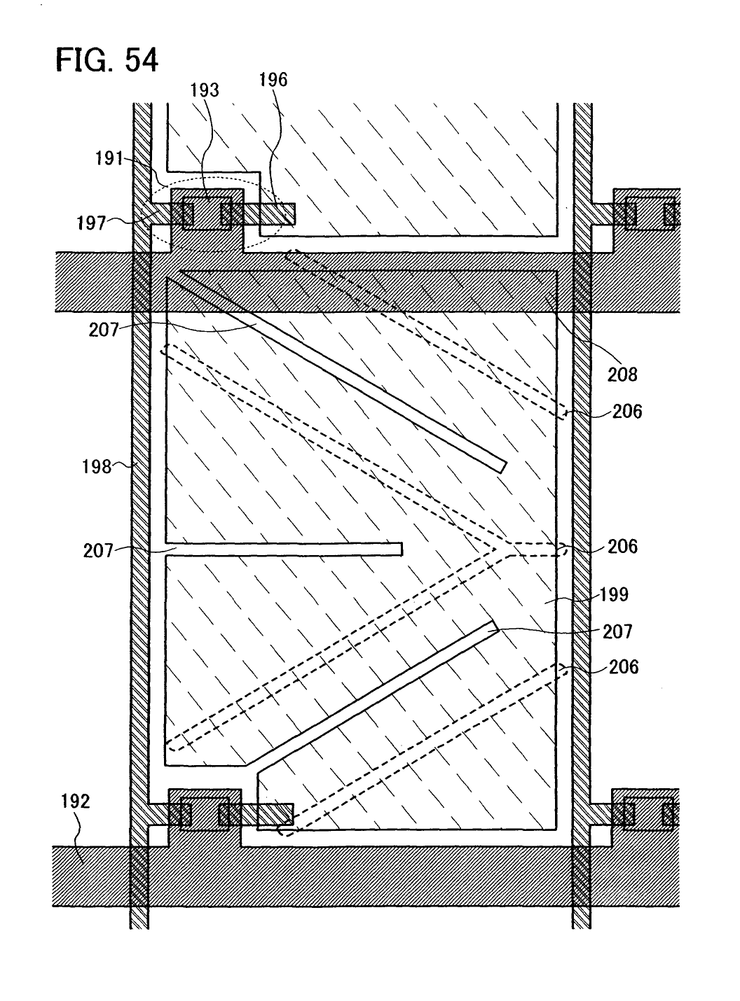

FIG. 54 is a top view of an arbitrary pixel in the liquid crystal display device with PVA mode shown in FIGS. 53A and 53B as an example.

A TFT 191 serving as a switching element of a pixel includes a gate wiring 192, a gate insulating film, an island-shaped semiconductor film 193, a source electrode 197 and a drain electrode 196.

Note that in this embodiment mode, the source electrode 197 and the source wiring 198 are distinguished from each other as a matter of convenience; however the source electrode and the source wiring are formed from the same material and connected to each other. The drain electrode 196 is also formed from the same material and in the same step as the source electrode 197 and the source wiring 198.

A plurality of grooves 207 are provided for the pixel electrode 199 which is electrically connected to the drain electrode 196.

In a region where the gate wiring 192 and the pixel electrode 199 are overlapped, an auxiliary capacitor 208 is formed with the gate insulating film therebetween.

On the opposite electrode side (not shown) provided for the opposite substrate, a plurality of protrusions 206 are formed. The protrusions 206 of the opposite electrode 206 are arranged so as to be alternated with the grooves 207 of the pixel electrode 199.

In the liquid crystal display device of the PVA mode, display with a symmetric property and an excellent viewing angle characteristic can be obtained.

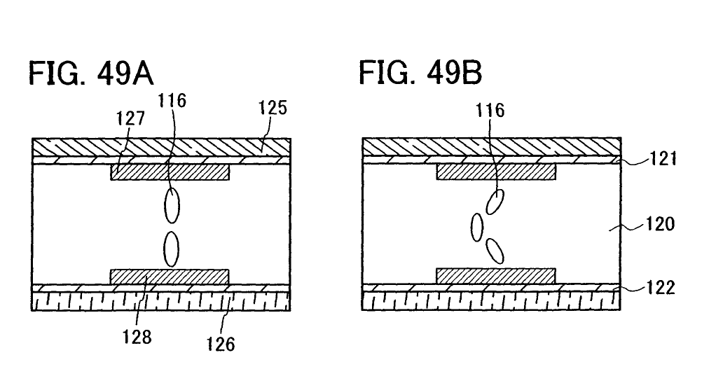

FIGS. 49A and 49B show a liquid crystal display device of an OCB mode. In the OCB mode, alignment of liquid crystal molecules forms a compensation-state optically in a liquid crystal layer, which is referred to as a bend orientation.

Similarly to FIGS. 44A and 44B, in the liquid crystal display device shown in FIGS. 49A and 49B, the first electrode 127 and the second electrode 128 are provided over the first substrate 121 and the second substrate 122 respectively. In the case of a transmissive type liquid crystal display device, the electrode on the opposite side of a backlight, i.e., the electrode on the display surface side, for example, the second electrode 128 is formed so as to have at least a light-transmitting property. In addition, in the case of a reflective type liquid crystal display device, one of the first electrode 127 and the second electrode 128 has a light-reflecting property and the other thereof has a light-emitting property.

In a liquid crystal display device having such a structure, when a voltage is applied to the first electrode 127 and the second electrode 128 (the vertical electric field method), display in black is conducted as shown in FIG. 49A. At this time, the liquid crystal molecules line up vertically. As a result, in the case of the transmissive type liquid crystal display device, light from the backlight cannot pass through the substrate, and display in black results. Further, in the case of the reflective type liquid crystal display device, a retardation plate is provided, and as for light from the outside, only light composition which oscillates in the direction of the transmission axis of the polarizer can be transmitted and becomes linear polarized light. This light becomes circularly polarized light by passing through the retardation plate (for example, right-handed circularly polarized light). When this right-handed circularly polarized light is reflected on a reflective plate (or a reflective electrode), it becomes left-handed circularly polarized light. When this left-handed circularly polarized light passes through the retardation plate, it becomes linear polarized light which oscillates perpendicularly to the transmission axis of the polarizer (parallel to the absorption axis). Therefore, light is absorbed by the absorption axis of the polarizer, and thus, display in black results.

As shown in FIG. 49B, when a voltage is not applied between the first electrode 127 and the second electrode 128, display in white results. At this time, the liquid crystal molecules 116 are aligned to be oriented obliquely. Then, in the case of the transmissive type liquid crystal display device, light from the backlight can pass through the substrates provided with the layers 125 and 126 each including a polarizer, and display of a designated image can be conducted. In addition, in the case of the reflective type liquid crystal display device, reflected light pass through the substrate provided with the layer including polarizers, and display of a designated image can be conducted. At this time, full color display can be conducted by the provision of a color filter. The color filter can be provided on either the first substrate 121 side or on the second substrate 122 side.

In such an OCB mode, birefringence in a liquid crystal layer caused in another mode is compensated only in the liquid crystal layer, thereby suppressing the dependency on the viewing angle. Further, a contrast ratio can be enhanced by the layer including a polarizer of the present invention.

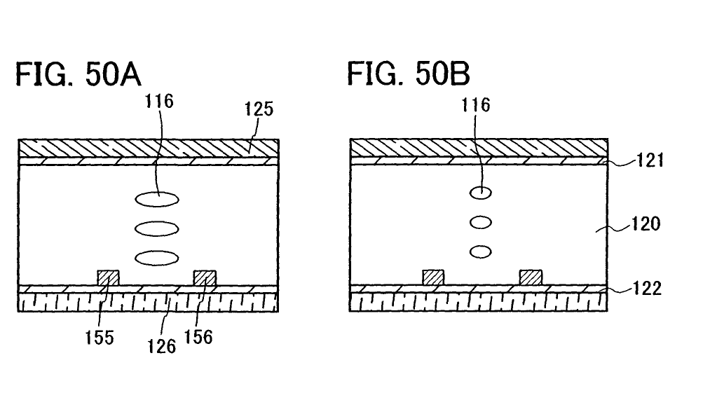

FIGS. 50A and 50B schematically show a liquid crystal display device of an In-Plane Switching (IPS) mode. In the IPS mode, liquid crystal molecules are rotated constantly within a plane with respect to substrates, and a lateral electrical field method where electrodes are provided only on one substrate side is employed.

In the IPS mode, a liquid crystal is controlled by a pair of electrodes provided on one of the substrates. Therefore, a pair of electrodes 155 and 156 are provided on the second substrate 122. The pair of electrodes 155 and 156 preferably have light transmitting property.

When a voltage is applied to the pair of electrodes 155 and 156 in a liquid crystal display device having such a structure, display in white results, which means an on-state, as shown in FIG. 50A. Then, in the case of the transmissive type liquid crystal display device, light from the backlight can pass through the substrates provided with the layers 125 and 126 each including a polarizer, and display of a designated image can be conducted. In addition, in the case of the reflective type liquid crystal display device, reflected light pass through the substrate provided with the layer including polarizer, and display of a designated image can be conducted. At this time, full color display can be conducted by the provision of a color filter. The color filter can be provided on either the first substrate 121 side or on the second substrate 122 side. When a voltage is not applied between the pair of electrodes 155 and 156, display in black is performed, which means an off state, as shown in FIG. 50B. At this time, the liquid crystal molecules 116 are aligned horizontally (parallel to the substrate) and rotated in a plane. Thus, in the case of a transmissive type liquid crystal display device, light from the backlight cannot pass through the substrate, which leads to display in black. In the case of a reflective type liquid crystal display device, a retardation plate is provided if necessary, and the phase together with the liquid crystal layer is shifted by 90° and display in black is made.

A known liquid crystal material may be used for the IPS mode.

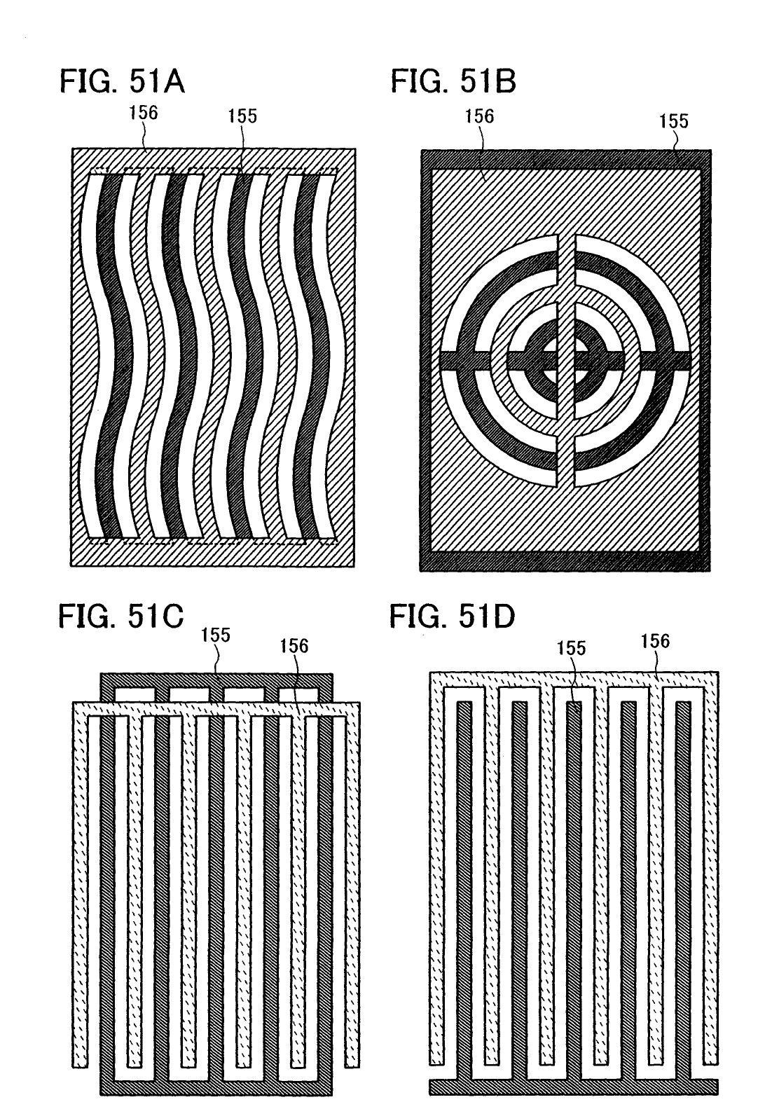

FIGS. 51A to 51D show examples of the pair of electrodes 155 and 156. In FIG. 51A, the pair of electrodes 155 and 156 has a wave-like shape. In FIG. 51B, a part of the pair of electrodes 155 and 156 has a circular shape. In FIG. 51C, the electrode 155 is a lattice-like shape and the electrode 156 has a comb-like shape. In FIG. 51D, each of the electrodes 155 and 156 as a pair has a comb-like shape.

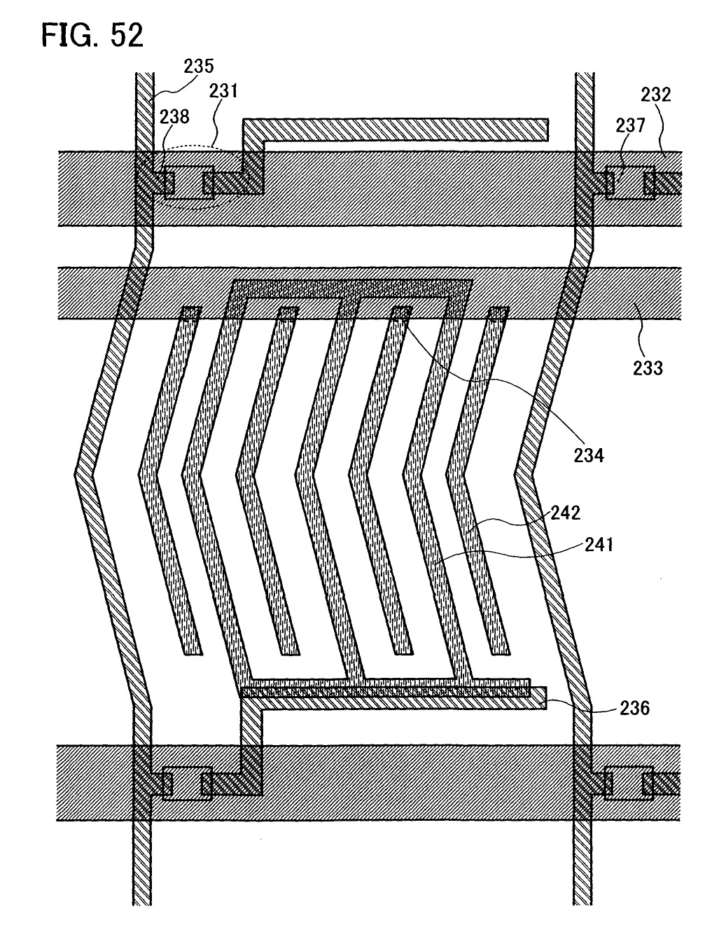

FIG. 52 is a top view of an arbitrary pixel in the liquid crystal display device with IPS mode shown in FIGS. 50A and 50B as an example.

Over a substrate, a gate wiring 232 and a common wiring 233 are formed. The gate wiring 232 and the common wiring 233 are formed from the same material, in the same layer and in the same step.

A TFT 231 serving as a switching element of the pixel includes a gate wiring 232, a gate insulating film, an island-shaped semiconductor film 237, a source electrode 238 and a drain electrode 236.

The source electrode 237 and the source wiring 238 are distinguished from each other as a matter of convenience; however the source electrode and the source wiring are formed from the same conductive film and connected to each other. The drain electrode 236 is also formed from the same material and in the same step as the source electrode 237 and the source wiring 238.

The drain electrode 236 is electrically connected to a pixel electrode 241.

The pixel electrode 241 and a plurality of common electrodes 242 are formed in the same step and from the same material. The common electrode 242 is electrically connected to the common wire 233 through a contact hole 234 in the gate insulating film.

Between the pixel electrode 241 and the common electrode 242, a lateral electric field parallel to the substrates is generated to control the liquid crystal.

In the liquid crystal display device with IPS mode, the liquid crystal molecules do not stand up obliquely, and thus, optical characteristics hardly changes depending on the viewing angle, and thus, a wide viewing angle characteristic can be obtained.

By applying a layer including a polarizer of the present invention to a liquid crystal display device using a lateral electric field, reflection can be suppressed and display with high contrast ratio can be provided. Such lateral electric field type liquid crystal display device are suitable for display devices of mobile phones.

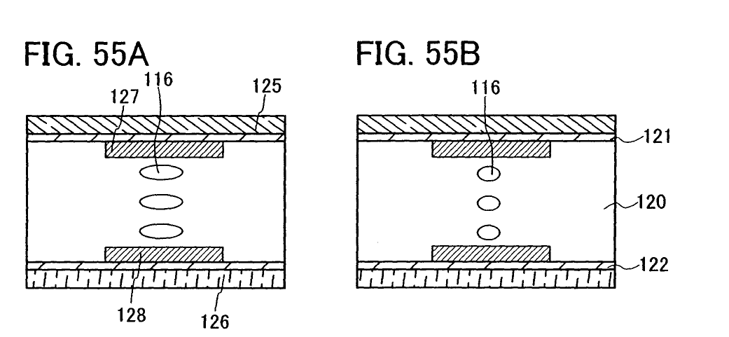

FIGS. 55A and 55B schematically show a Ferro-Electric Liquid Crystal (FLC) mode liquid crystal display mode and an Antiferro-Electric Liquid Crystal (AFLC) mode liquid crystal display device.

The liquid crystal display devices shown in FIGS. 55A and 55B are similar to those shown in FIGS. 44A and 44B, and include the first electrode 127 and the second electrode 128 which are provided on the first substrate 121 and the second substrate 122, respectively. In the case of a transmissive type liquid crystal display device, the electrode on the opposite side of a backlight, i.e., the electrode on the display surface side, for example, the second electrode 128 is formed so as to have at least a light-transmitting property. In addition, in the case of a reflective type liquid crystal display device, one of the first electrode 127 and the second electrode 128 has a light-reflecting property and the other one thereof has a light-emitting property.

In the liquid crystal display device having such a structure, when a voltage is applied between the first electrode 127 and the second electrode 128 (vertical electric field), display in white is obtained as shown in FIG. 55A. At this time, the liquid crystal molecules line up horizontally (parallel to the substrate) and rotated within the plane. Then, in the case of the transmissive type liquid crystal display device, light from the backlight can pass through the substrates provided with the layers 125 and 126 each including a polarizer, and display of a designated image can be conducted. In addition, in the case of the reflective type liquid crystal display device, reflected light pass through the substrate provided with the layer including a polarizer, and display of a designated image can be conducted. At this time, full color display can be conducted by the provision of a color filter. The color filter can be provided on either the first substrate 121 side or on the second substrate 122 side.

When a voltage is not applied between the pair of electrodes 155 and 156, display in black is performed, which means an off-state, as shown in FIG. 55B. At this time, the liquid crystal molecules 116 line up horizontally and rotated within a plane. Thus, in the case of a transmissive type liquid crystal display device, light from the backlight cannot pass through the substrate, which leads to display in black. In the case of a reflective type liquid crystal display device, a retardation plate is provided if necessary, and the phase together with the liquid crystal layer is shifted by 90° and display in black is made.

Known materials can be used as liquid crystal materials used for an FLC mode liquid crystal display device and an AFLC mode liquid crystal display device.

Next, examples in which the present invention is applied to a Fringe Field Switching (FFS) mode liquid crystal display device and an Advanced Fringe Field Switching (AFFS) mode liquid crystal display device, are described.

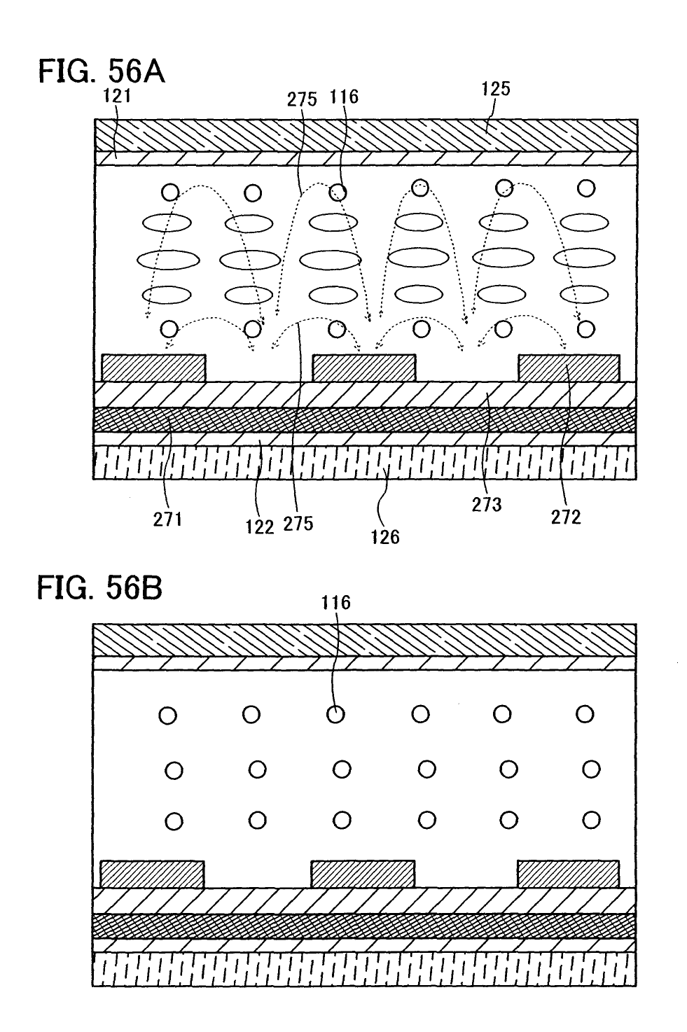

FIGS. 56A and 56B schematically show an AFFS mode liquid crystal display device.

The same elements in the liquid crystal display device shown in FIGS. 56A and 56B as those in FIGS. 44A and 44B are denoted by the same reference numerals. Over the second electrode 122, a first electrode 271, an insulating layer 273, and a second electrode 272 are provided. The first electrode 271 and the second electrode 272 have a light-transmitting property.

As shown in FIG. 56A, when a voltage is applied to the first electrode 271 and the second electrode 272, a horizontal electric field 275 is generated. The liquid crystal molecules 116 rotate in a horizontal direction and twist, so that light can pass through the liquid crystal molecules. The rotation angles of the liquid crystal molecules are various, and obliquely incident light can pass the liquid crystal molecules. Then, in the case of the transmissive type liquid crystal display device, light from the backlight can pass through the substrates provided with the layers 125 and 126 each including a polarizer, and display of a designated image can be conducted. In addition, in the case of the reflective type liquid crystal display device, reflected light pass through the substrate provided with the layer including a polarizer, and display of a designated image can be conducted. At this time, full color display can be conducted by the provision of a color filter. The color filter can be provided on either the first substrate 121 side or on the second substrate 122 side.

As shown in FIG. 50B, a state in which a voltage is not applied between the first electrode 271 and the second electrode 272, display in black, i.e., an off-state is obtained. At this time, the liquid crystal molecules 116 line up horizontally and rotated within a plane. Thus, in the case of the transmissive type liquid crystal display device, light from the backlight cannot pass through the substrate, which leads to display in black. In the case of the reflective type liquid crystal display device, a retardation plate is provided if necessary, and the phase together with the liquid crystal layer is shifted by 90° and display in black (black display) is made.

Known materials may be used as liquid crystal materials used for an FFS mode liquid crystal display device and an AFFS mode liquid crystal display device.

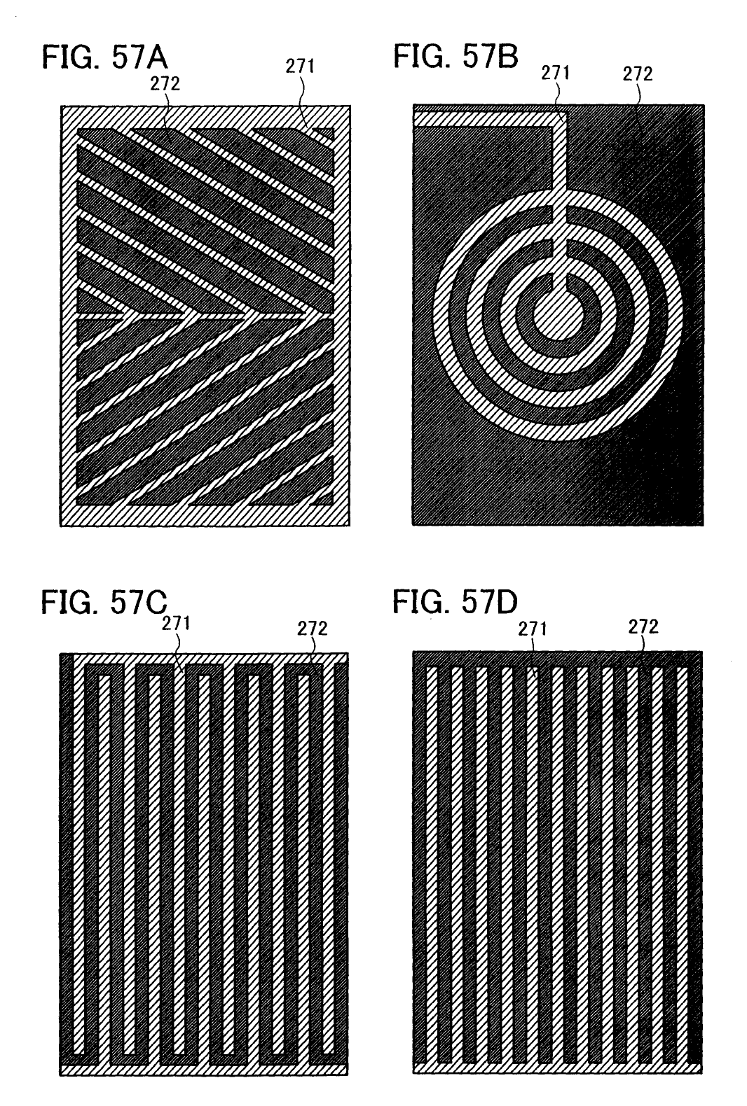

FIGS. 57A to 57D show examples of the first electrode 271 and the second electrode 272. In FIGS. 57A to 57D, the first electrode 271 is formed entirely, and the second electrodes 272 have various shapes. In FIG. 57A, the second electrode 272 has a reed-shaped and is arranged obliquely. In FIG. 57B, the second electrode 272 has partially a circular shape. In FIG. 57C, the second electrode 272 has a zigzag shape. In FIG. 57D, the second electrode 272 has a comb-like shape.

Additionally, the present invention can be applied to an optical rotation mode liquid crystal display device, a scattering mode liquid crystal display device, and a birefringence mode liquid crystal display device.

This embodiment mode can be freely combined with any of other embodiment modes and examples in this specification.

### Embodiment Mode 30

Embodiment Mode 30 will describe application examples in which the liquid crystal display devices shown in Embodiment Modes 4 to 15 and Embodiment Modes 25 to 28 are applied to 2D/3D switchable (two dimensional and three dimensional switchable) liquid crystal display devices.

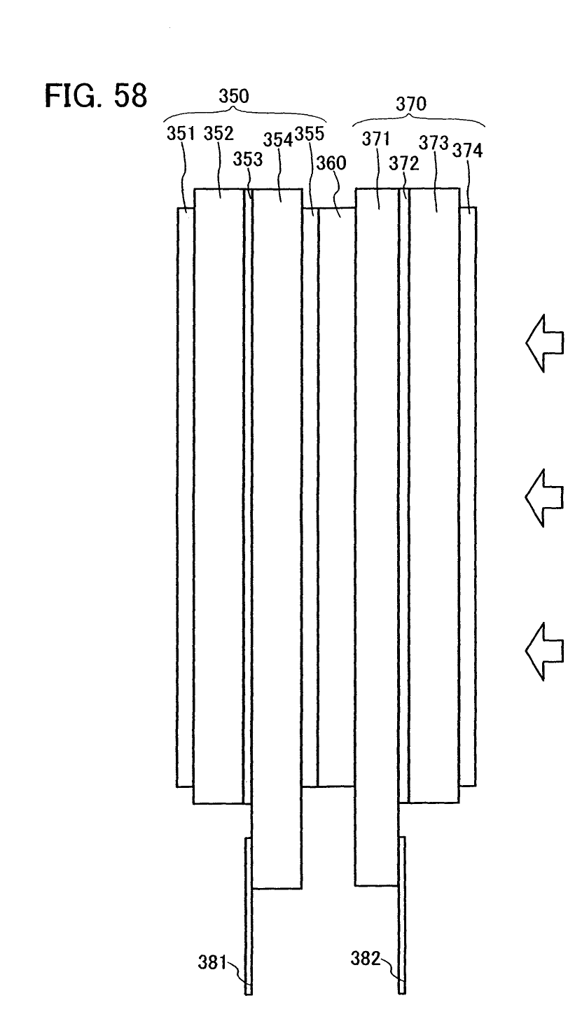

FIG. 58 shows a structure of a 2D/3D switchable liquid crystal display panel in this embodiment mode.

As shown in FIG. 58, the 2D/3D switchable liquid crystal display panel has a structure in which a display panel of liquid crystal 350 (also referred to as a liquid crystal display panel 350), a retardation plate 360, and a switching liquid crystal panel 370 are attached.

The liquid crystal display panel 350 is provided as a TFT liquid crystal display panel, in which a first polarizing plate 351, an opposite substrate 352, a liquid crystal layer 353, an active matrix type substrate 354, and a second polarizing plate 355 are stacked. To the active matrix type substrate 354, video data corresponding to an image to be displayed is input, through a wiring 381 such as a flexible printed circuit (FPC).

In other words, the liquid crystal display panel 350 is provided so as to give the 2D/3D switchable liquid crystal display panel a function for producing an image on a display screen in accordance with the video data. In addition, there are no particular limitations on display modes (e.g., TN mode and STN mode) and driving methods (e.g., active matrix driving or passive matrix driving), as long as a function for producing images on the display screen can be obtained.

The retardation plate 360 serves as a part of a parallax barrier, and has a structure in which an alignment film is provided for a substrate having a light-transmitting property, and a liquid crystal layer is stacked thereover.

In the switching liquid crystal panel 370, a substrate 371 on a driver side, a liquid crystal layer 372, an opposite substrate 373 and a third polarizing plate 374 are stacked, and a wiring 382 for applying a driving voltage at the time of turning on the liquid crystal layer 372 is connected to the substrate 371 on the driver side.

The switching liquid crystal panel 370 is provided in order to switch polarized state of light which passes through the switching liquid crystal panel 370, in accordance with ON/OFF of the liquid crystal layer 372. In addition, it is not necessary that the switching liquid crystal panel 370 is driven by a matrix driving method, which is different from the display liquid crystal panel 350, and driving electrodes provided for the substrate 371 on the driver side and the opposite substrate 373 may be provided over the entire surface of an active area of the switching liquid crystal panel 370.

Next, display operation of the 2D/3D switchable liquid crystal display panel is described.

Incident light which is emitted from a light source is polarized by the third polarizing plate 374 of the switching liquid crystal panel 370 first. In addition, the switching liquid crystal panel 370 serves as a retardation plate (here, a half wave plate) at the off-state when 3D display is conducted.

In addition, then, the light which has passed through the switching liquid crystal panel 370 enters the retardation plate 360. The retardation plate 360 includes a first region and a second region, and rubbing directions of the first region and the second region are different. A state of the different rubbing directions means a state in which light which has passed through the first region and light which has passed through the second region have different polarizing states since the slow axes are in different directions. For example, a polarizing axis of the light which has passed through the first region is different by 90° from that of the light which has passed through the second region. In addition, the retardation plate 360 is set to serve as a half wave plate, based on birefringence anisotropy and thickness of the liquid crystal layer 360.

The light which has passed through the retardation plate 360 enters the second polarizing plate 355 of the liquid crystal display panel 350. At the time of 3D display, the polarizing axis of the light which has passed through the first region of the retardation plate 360 is parallel with a transmission axis of the second polarizing plate 355, and the light which has passed through the first region passes through the second polarizing plate 355. On the other hand, the polarizing axis of the light which has passed through the second region of the retardation plate 360 is shifted by 90° from the transmission axis of the second polarizing plate 355, and the light which has passed through the second region does not passes through the second polarizing plate 355.

In other words, by the optical characteristics of the retardation plate 360 and the second polarizing plate 355, the function of a parallax barrier is achieved, and the first region of the retardation plate 360 becomes a transmission region and the second region thereof becomes a shielding region.

The light which has passed through the second polarizing plate 355 is subjected to different optical modulation in pixels of black and pixels of white in the liquid crystal layer 353 of the liquid crystal display panel 350, and only light which has been subjected to optical modulation in the pixels of white passes through the first polarizing plate 351 and an image is displayed.

At this time, light passes through the transmission region of the parallax barrier, or light having a particular viewing angle passes through each pixel corresponding to an image for right eye and an image for left eye in the liquid crystal display panel 350. Thus, the image for right eye and the image for left eye are separated into different viewing angles, and thus 3D display is provided.

Further, at the time of 2D display, the switching liquid crystal panel 370 is turned on, and the light which has passed through the switching liquid crystal panel 370 is not subjected to optical modulation. The light which has passed through the switching liquid crystal panel 370 then passes through the retardation plate 360, and the light which has passed through the first region and the light which has passed through the second region are provided with different polarized states.

However, 2D display is different from 3D display in that optical modulation effect is not generated in the switching liquid crystal display panel 370. Thus, in the case of 2D display, the polarizing axis of the light which passes through the polarizing plate 360 is symmetrically misaligned in the angle from the transmission axis of the second polarizing plate 355. Therefore, the light which has passed through the first region of the retardation plate 360 and the light which has passed through the second region thereof both pass through the second polarizing plate 355 with the same transmittance, and the function of a parallax barrier by the optical effect between the retardation plate 360 and the second polarizing plate 355 is not achieved (a particular viewing angle is not obtained). In this manner, 2D display is provided.

This embodiment mode can be freely combined with any of other embodiment modes and examples in this specification if necessary.

### Embodiment Mode 31

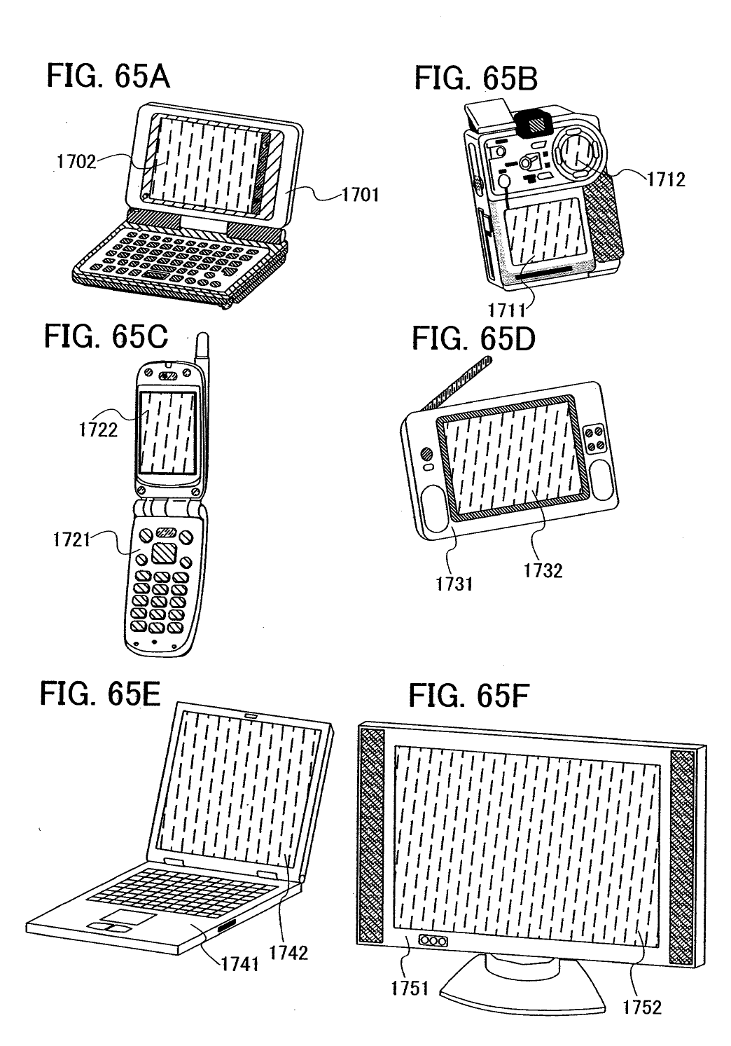

Electronic devices to which a display device of the present invention is applied, includes: television devices (also simply referred to as TVs or television receivers), cameras such as digital cameras and digital video cameras, mobile phone sets (also simply referred to as cellular phone sets or cellular phones), portable information terminals such as PDA, portable game machines, monitors for computers, computers, audio reproducing devices such as car audio sets, image reproducing devices provided with a recording medium such as home-use game machines, and the like. Specific examples thereof are described with reference to FIGS. 65A to 65F.

A portable information terminal shown in FIG. 65A includes a main body 1701, a display portion 1702, and the like. A display device of the present invention can be applied to the display portion 1702. Thus, the portable information terminal with a high contrast ratio can be provided.

A digital video camera shown in FIG. 65B includes a display portion 1711, a display portion 1712, and the like. A display device of the present invention can be applied to the display portion 1711. Thus, the digital video camera with a high contrast ratio can be provided.

A cellular phone set shown in FIG. 65C includes a main body 1721, a display portion 1722, and the like. A display device of the present invention can be applied to the display portion 1722. Thus, the cellular phone set with a high contrast ratio can be provided.

A portable type television device shown in FIG. 65D includes a main body 1731, a display portion 1732, and the like. A display device of the present invention can be applied to the display portion 1732. Thus, a portable television device with a high contrast ratio can be provided. The display device of the present invention can be applied to various types of television devices including a small-sized television incorporated in a portable terminal such as a cellular phone set, a medium-sized television which is portable, and a large-sized television (for example, 40 inches in size or more).

A portable type computer shown in FIG. 65E includes a main body 1741, a display portion 1742, and the like. A display device of the present invention can be applied to the display portion 1742. Thus, the portable type computer with a high contrast ratio can be provided.

A television device shown in FIG. 65F includes a main body 1751, a display portion 1752, and the like. A display device of the present invention can be applied to the display portion 1752. Thus, the television device with a high contrast ratio can be provided.

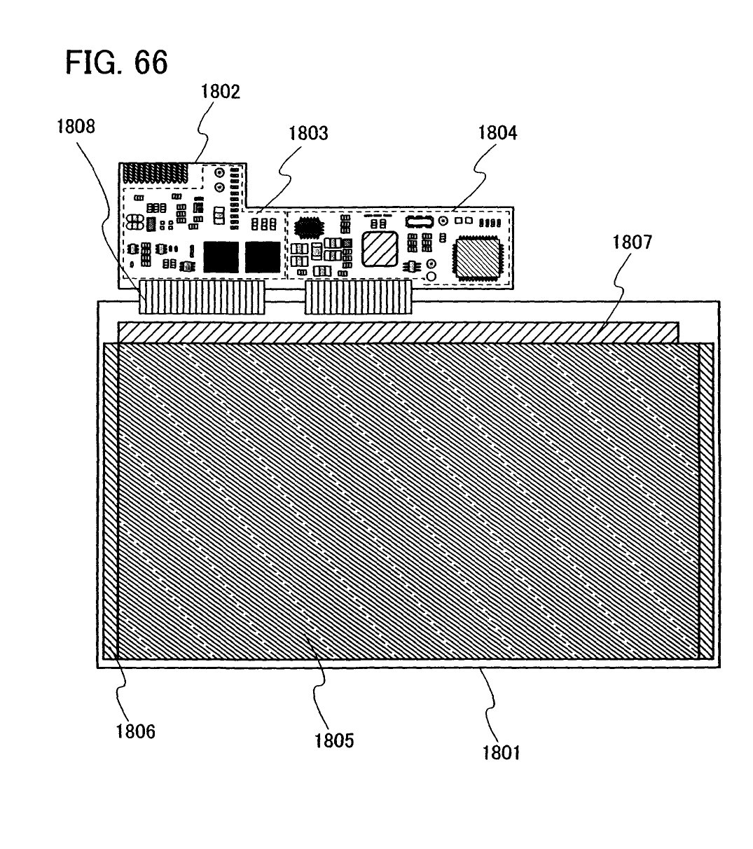

FIGS. 66 to 68 show detailed structures of the television device shown in FIG. 65F.

FIG. 66 shows a liquid crystal module or a light-emitting display module (e.g., an EL module) constructed by combining a display panel 1801 and a circuit board 1802. Over the circuit board 1802, for example, a control circuit 1803, a signal dividing circuit 1804 and/or the like are formed. The circuit board 1802 is electrically connected to the display panel 1801 through a connecting wiring 1808.

The display panel 1801 includes a pixel portion 1805, a scan line driver circuit 1806, and a signal line driver circuit 1807 for supplying a video signal to a selected pixel. This structure is similar to those shown in FIGS. 20, 21 and 32.

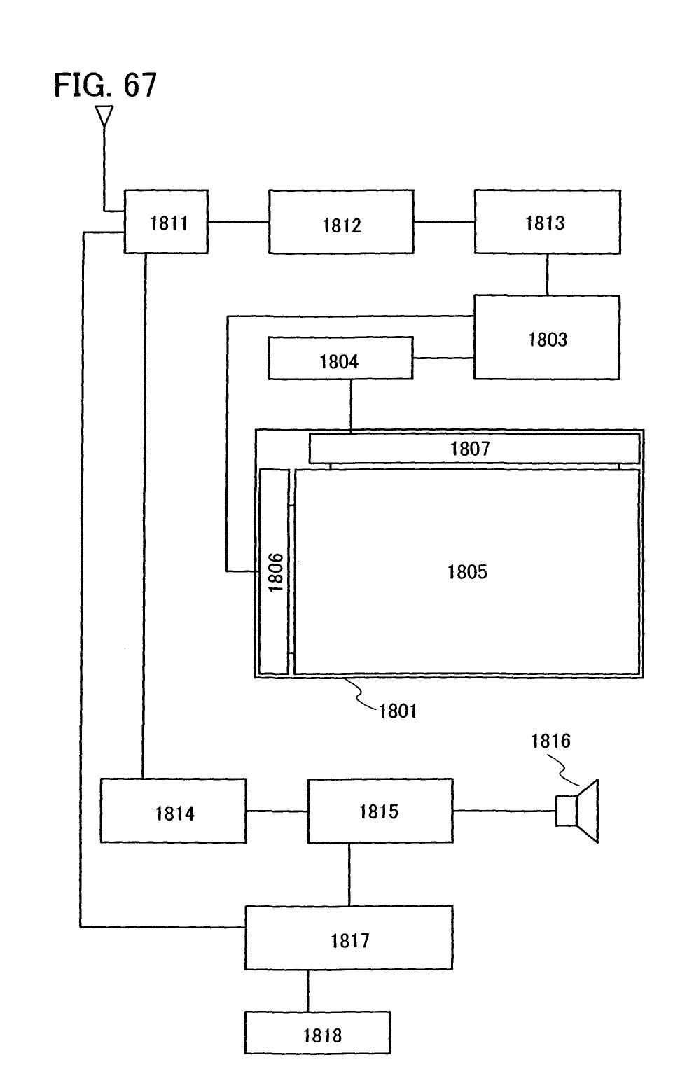

A liquid crystal television device or a light-emitting display television device can be completed by using the liquid crystal module or the light-emitting display module. FIG. 67 is a block diagram showing the main configuration of the liquid crystal television device or the light-emitting display television device. A tuner 1811 receives a video signal and an audio signal. The video signal is processed by a video signal amplifying circuit 1812, a video signal processing circuit 1813 for converting an output signal from the video signal amplifying circuit 1812 to a color signal corresponding to each color of red, green and blue, and the control circuit 1803 for converting the video signal to be input into a driver IC. The control circuit 1803 outputs a signal to each of a scan line side and a signal line side. In the case of digital drive, the signal dividing circuit 1804 may be provided on the signal line side so that the input digital signal is divided into m signals to be supplied.

Of the signals received by the tuner 1811, an audio signal is transmitted to the audio signal amplifying circuit 1814, and an output thereof is supplied to a speaker 1816 through an audio signal processing circuit 1815. A control circuit 1817 receives control data on the receiving station (receive frequency) and volume from an input portion 1818, and transmits the signal to the tuner 1811 and the audio signal processing circuit 1815.

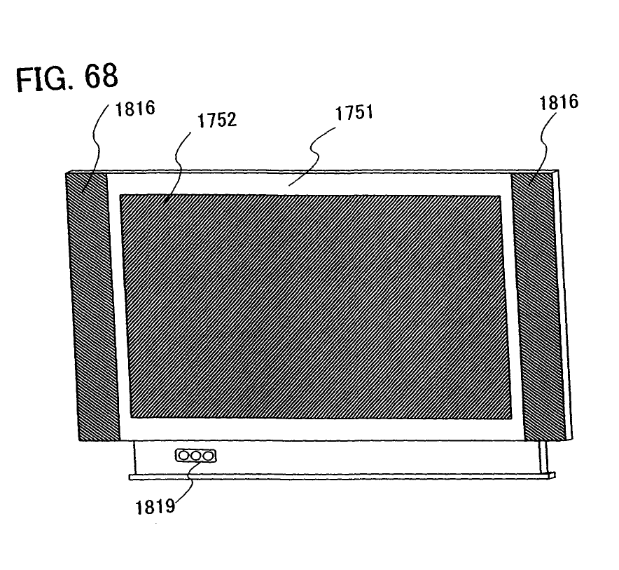

As shown in FIG. 68, a television receiver can be completed by incorporating a liquid crystal module or a light-emitting display module into the main body 1751. A display screen 1752 is formed using the liquid crystal module or the light-emitting display module. In addition, speakers 1816, operating switches 1819 and/or the like are provided as appropriate.

By incorporating the display panel 1801 formed according to the present invention, a television device with a high contrast ratio can be provided.

Needless to say, the present invention is not limited to such television receivers, and can be applied to various objects, in particular, as a large-area advertising display medium, for example, an information display board at the train station or airport, an advertising display board on the street and the like, in addition to a monitor of a personal computer.

As described above, electronic devices with high contrast ratio can be provided by using the display devices of the present invention.

This embodiment mode can be freely combined with any of other embodiment modes and examples in this specification if necessary.

### EXAMPLE 1

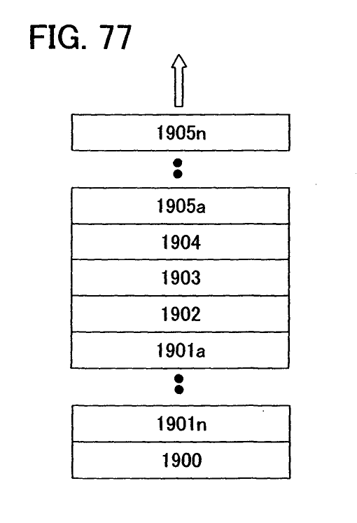

In Example 1, it is examined by calculation whether contrast ratio can be increased by stacking polarizing plates in a transmissive type liquid crystal display device. The results are explained with reference to FIGS. 77 to 80.

First, as calculation software, liquid crystal optical calculation software LCD MASTER (made by Shintech Inc.) is used. Optical calculation algorithm in 4×4 matrix, in which multiple beam interference by coming and going of reflected light between elements is considered, is adopted and the wavelength of a light source is set 550 nm.

A panel structure of this example includes a backlight 1900, a polarizing plate 1901 having a stacked structure (including polarizing plates 1901a to 1901n), a transparent glass 1902, a liquid crystal cell 1903, a transparent glass 1904, and a polarizing plate 1905 having a stacked structure (including polarizing plates 1905a to 1905n) (FIG. 77).

For each of the polarizing plates 1901a to 1901n and the polarizing plates 1905a to 1905n, a polarizing plate EG1425DU manufactured by NITTO DENKO CORPORATION (hereinafter, referred to as a polarizing plate A) is used. As for the polarizing plates 1901 and 1905, at a wavelength of 550 nm, an extinction coefficient with respect to a transmission axis is 3.22×10⁻⁵, and an extinction coefficient with respect to an absorption axis is 2.21×10⁻³, and refractive indexes of the transmission axis and the absorption axis are both 1.5.

As a liquid crystal of a liquid crystal cell 1903, TN liquid crystal of which rotational viscosity coefficient is 0.1232 (Pa·sec), dielectric anisotropy Δε is 5.2, and birefringence Δn is 0.099 (550 nm) is used. The elastic constant and dielectric anisotropy of this TN liquid crystal are shown in Tables 1(A) and 1(B). The thickness of the liquid crystal cell 1903 is 2.5 μm. In addition, the pretilt angle, twist angle and pretwist angle are 3°, 90° and 0° respectively.

TABLE 1(A)
Elastic Constant (N)

| K11 | K22 | K33 |
|---|---|---|
| 1.32E−11 | 6.50E−12 | 1.83E−11 |

TABLE 1(B)
Dielectric Anisotropy

| ε1 | ε2 | ε3 |
|---|---|---|
| 8.3 | 3.1 | 3.1 |

The refractive index at a wavelength of 550 nm of the transparent glass substrates 1902 and 1904 is 1.520132. In addition, the thickness of each of the transparent glass substrates 1902 and 1904 is 0.7 mm.

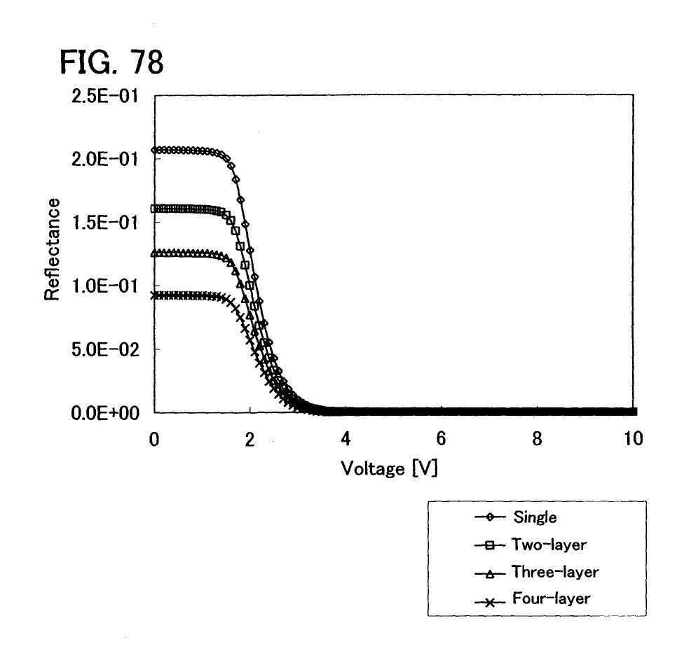

FIG. 78 is a graph showing transmittance with respect to an applied voltage. The graph of FIG. 78 shows calculation results in the cases where the polarizing plates 1901 and 1905 are each single, a two-layer stack, a three-layer stack, and a four-layer stack. According to these results, it can be known that as the number of the stacked plates included in the polarizing plates 1901 and 1905 is increased, the transmittance is reduced as a whole.

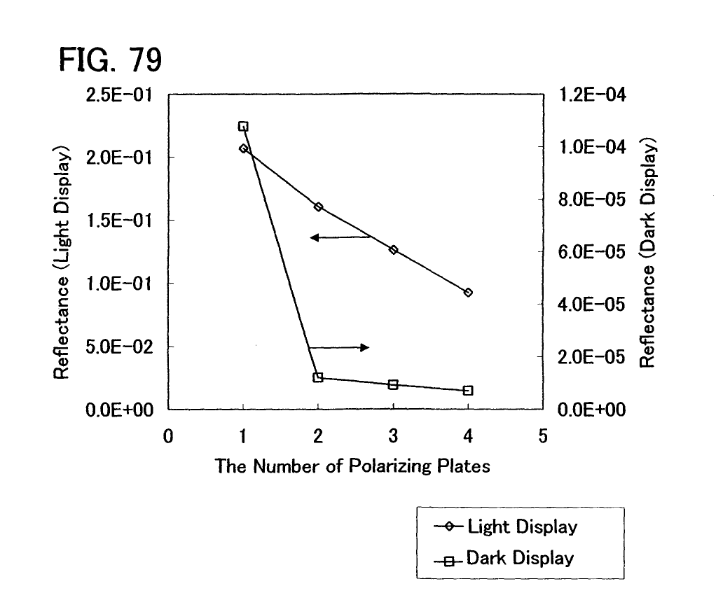

FIG. 79 shows changes in transmittance when the number of the stacked polarizing plates 1901 and 1905 is changed between light display (a voltage applied to the liquid crystal is 0 V) and dark display (a voltage applied to the liquid crystal is 5 V).

In FIG. 79, in the case of the light display, it seems that the transmittance is reduced constant as the number of the polarizing plates is increased. On the contrary, as for the dark display, when the case where the polarizing plates 1901 and 1905 are each single, and the case where the polarizing plates 1901 and 1905 are each two-layer stack are compared, it is known that transmittance is reduced greatly in the latter case. In the structure in which the polarizing plates 1901 and 1905 each have two or more stacked polarizing plates, the transmittance is reduced constant as the number of polarizing plates is increased even in the dark display.

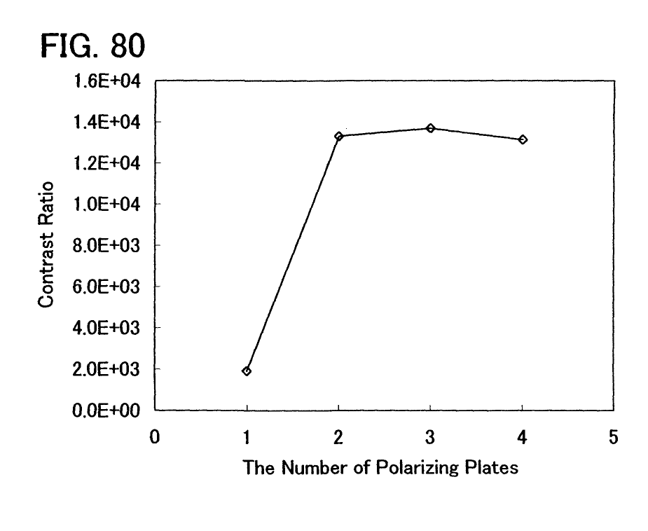

In FIG. 79, when the polarizing plates 1901 and 1905 each are two-layer stack, the degree of reduction in transmittance in the light display is smaller than that in the dark display. In other words, it is known that the degree of reduction in the transmittance in the dark display is larger than that in the light display. Thus, as shown in FIG. 80, the contrast ratio can be much more increased by stacking two polarizing 20 plates for each of the polarizing plates 1901 and 1905 than by providing a single polarizing for each thereof.

However, even if the number of polarizing plates included in each of the polarizing plates 1901 and 1905 is increased, since the degrees of reduction in relation to the number of the polarizing plates in the light display and the dark display are equal, the result that the contrast ratio is constant is obtained. It is thought that this is because the degree of reduction in transmittance in the light display in relation to the number of the polarizing plates and the degree of reduction in transmittance in the dark display are equal, and the contrast ratio is in saturation state.

### EXAMPLE 2

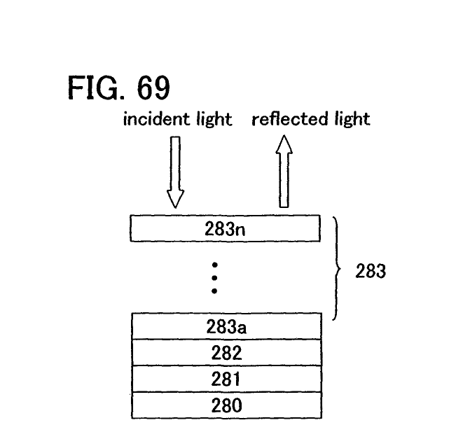

In Example 2, it is examined by calculation that contrast ratio can be increased by stacking polarizing plates in a reflective type liquid crystal display device. The results are explained with reference to FIGS. 69 to 72.

First, as calculation software, liquid crystal optical calculation software LCD MASTER (made by Shintech Inc.) is used. Optical calculation algorithm in 4×4 matrix, in which multiple beam interference by coming and going of reflected light between elements is considered, is adopted and the wavelength of a light source is set 550 nm. In addition, the polar angles of incident light from the light source and reflected light to be observed are 0° (front side).

A panel structure of this example includes a reflective plate 280, a liquid crystal cell 281, a retardation plate (also referred to as a wavelength plate) 282, and a polarizing plate 283 having a stacked structure (FIG. 69). In other words, the retardation plate 282 and the polarizing plate having 283 a stacked structure are provided on the viewer side (observer side) of the liquid crystal cell 281. Combination of the retardation plate and the polarizing plate forms a circular polarizing plate.

As the reflective plate 280, a mirror of which reflectance of incident light and reflected light at the front side of the light source is 1, is arranged.

As the liquid crystal cell 281, a structure in which the liquid crystal is interposed between a pair of transparent substrates is used. As the transparent substrate, a glass substrate is used in this example. As the liquid crystal, TN liquid crystal of which dielectric anisotropy Δε is 5.2, and birefringence Δn is 0.099 (550 nm) is used. The thickness of the liquid crystal cell 281 is 2.5 μm.

Note that properties of the liquid crystal of the liquid crystal cell 281 and the polarizing plate are similar to those in Example 1, and thus, detailed description is omitted here.

Reflectance in light display and dark display is calculated, in which a voltage applied to the liquid crystal is 0 V in the light display and a voltage is 5 V in the dark display. The contrast ratio is a ratio of reflectance at 0 V which is applied to the liquid crystal and reflectance at 5 V which is applied to the liquid crystal (reflectance at the applied voltage of 0 V/reflectance at the applied voltage of 5 V).

As the retardation plate 282, a quarter-wave plate is used, and the slow axis is 45°. In addition, the retardation plate 282 has a retardation of 137.5 nm in the plane direction. The thickness of the quarter-wave plate is 100 μm.

The refractive indexes in x, y, z directions of the quarter-wave plate are 1.58835, 1.586975, and 1.586975, respectively.

The polarizing plate 283 having a stacked structure includes polarizing plates 283a to 283n, and calculation is done by changing the number of the polarizing plates 283a to 283n. The absorption axis direction of each of the polarizing plates 283a to 283n is 90°, and these polarizing plates are arranged in parallel Nicols state. As for the polarizing plates 283a to 283n, extinction coefficient with respect to the absorption axis is 2.21×10⁻³, and extinction coefficient with respect to the transmission axis is 3.22×10⁻⁵ (550 nm).

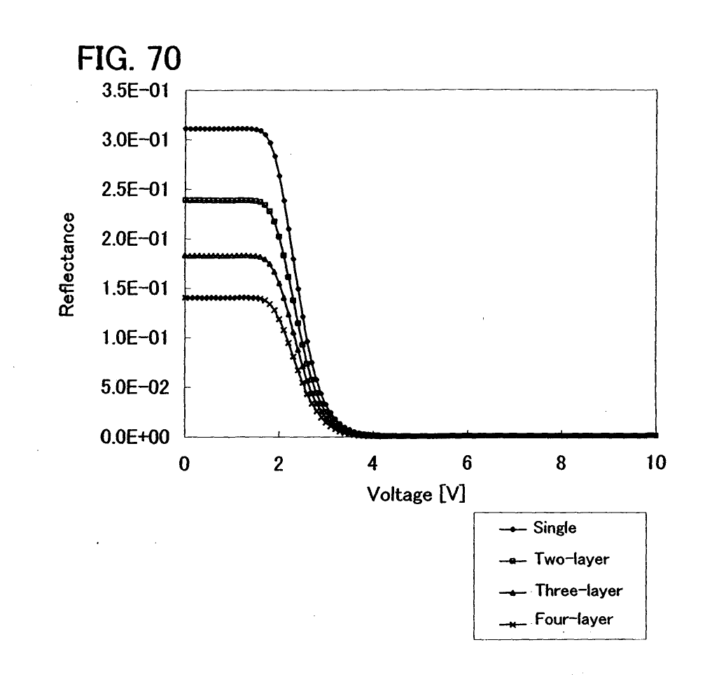

FIG. 70 is a graph of reflectance with respect to the applied voltage. FIG. 70 is a graph of calculation results in the cases where the polarizing plate 283 is single, a two-layer stack, a three-layer stack, and a four-layer stack. According to these results, it can be known that as the number of the stacked plates included in the polarizing plate 283 is increased, the transmittance is reduced generally.

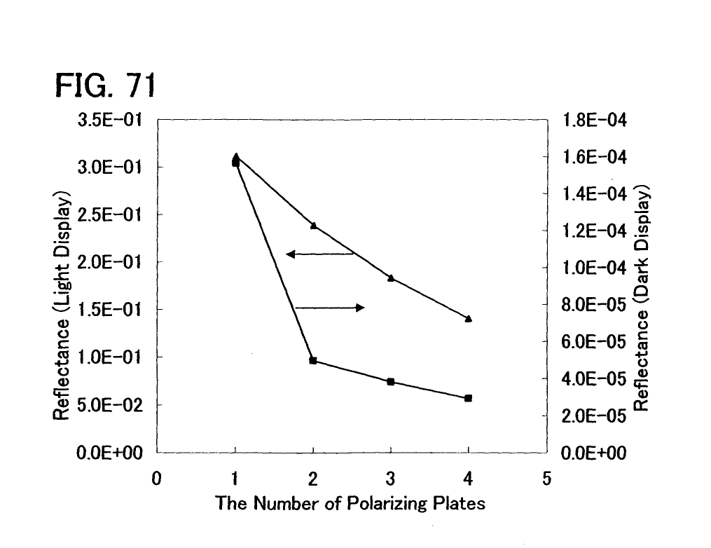

FIG. 71 shows changes in transmittance when the number of stacked plates included in the polarizing plate 283 is changed between light display (the voltage applied to the liquid crystal is 0 V) and dark display (the voltage applied to the liquid crystal is 5 V).

In FIG. 71, in the case of the light display, the transmittance is reduced constant as the number of the polarizing plates is increased. On the contrary, as for the dark display, when the case where the polarizing plate 283 is single, and the case where the polarizing plate 283 is two-layer stack are compared, it is known that transmittance is reduced greatly in the latter case. In the structure in which the polarizing plate 283 has two or more stacked polarizing plates, the transmittance is reduced constant as the number of the polarizing plates is increased even in the dark display.

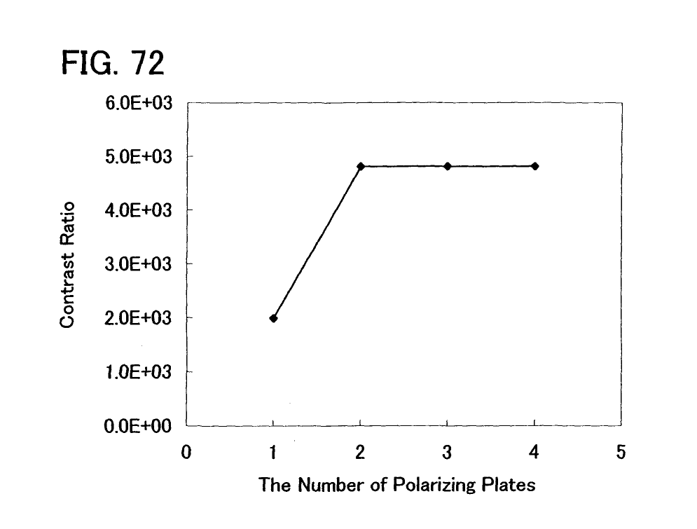

In FIG. 71, when the polarizing plate 283 is two-layer stack, the degree of reduction in reflectance in the light display is smaller than that in the dark display. In other words, it is known that the degree of reduction in the reflectance in the dark display is larger than that in the light display. Thus, as shown in FIG. 72, the contrast ratio can be much more increased by stacking two polarizing plates for the polarizing plate 283 than by providing a single polarizing plate.

However, even if the number of plates included in the polarizing plate 283 is increased, since the degree of reduction in relation to the number of the polarizing plates in the light display and the dark display are equal, the result that the contrast ratio is constant is obtained. It is thought that this is because the degree of reduction in reflectance in the light display in relation to the number of the polarizing plates and the degree of reduction in reflectance in the dark display are equal, and the contrast ratio is in saturation state.

### EXAMPLE 3

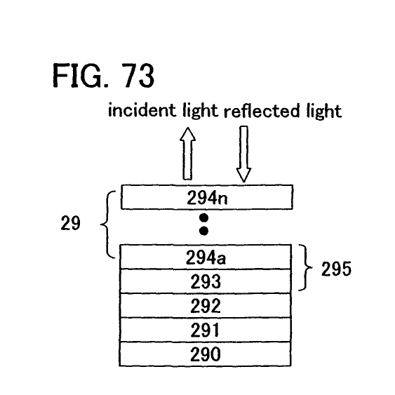

In Example 3, an experiment for confirming that contrast ratio can be increased by stacking a plurality of polarizing plates in a reflective type liquid crystal display device is conducted. The results are explained with reference to FIGS. 73 to 76.

In this example, measurement is conducted using a spectrophotometer U-4000. The wavelength range of a light source is 380 to 780 nm, and the polar angle of incident light is 5° (the angle with respect to a line perpendicular to the substrate is 5°), and the polar angle of reflected light is 5° (regular reflection of 5° with respect to the incident angle).

A panel structure of this example includes a reflective plate 290, a liquid crystal cell 291, a substrate 292, a retardation plate (also referred to as a wavelength plate or a wave plate) 293 and a polarizing plate 294 having a stacked structure (FIG. 73). In other words, the substrate 292, the retardation plate 293 and the polarizing plate 294 having a stacked structure are provided on the viewer side (observer side) of the liquid crystal cell 291.

For the reflective plate 290, a material having high reflectance, for example, a substrate provided with a metal substance in which Al and Ti are mixed is used.

The liquid crystal cell 291 has a structure in which a liquid crystal is interposed between transparent substrates and the thickness of the cell is 2.2 μm. TN liquid crystal is used for the liquid crystal and the mode thereof is normally white type.

The substrate 292, the retardation plate 293 and the polarizing plate 294 are stacked on the viewer side (observer side) of the liquid crystal cell.

As the substrate 292, a transparent substrate such as a glass substrate is used. As the retardation plate 293, a quarter-wave plate of which film thickness is 80 to 90 μm and retardation at a wavelength of 550 μm is 142 nm is used. As the polarizing plate, an iodine type one having a thickness of 100 μm and a total transmittance of 45% is used.

A polarizing plate 294 having a stacked structure is provided over the retardation plate 293. The polarizing plate 294 having a stacked structure includes a plurality of polarizing plates 294a to 294n, and absorption axes of the polarizing plates are arranged in parallel Nicols to each other. Note that the retardation plate 293 and the polarizing plate 294a as the first plate form a circular polarizing plate 295.

Reflectance in each wavelength in light display and dark display is calculated, in which the voltage applied to the liquid crystal is 0 V in the light display and the voltage is 5 V in the dark display. The contrast ratio is a ratio of reflectance at 0 V which is applied to the liquid crystal and reflectance at 5 V which is applied to the liquid crystal (reflectance at applied voltage of 0 V/reflectance at applied voltage of 5 V).

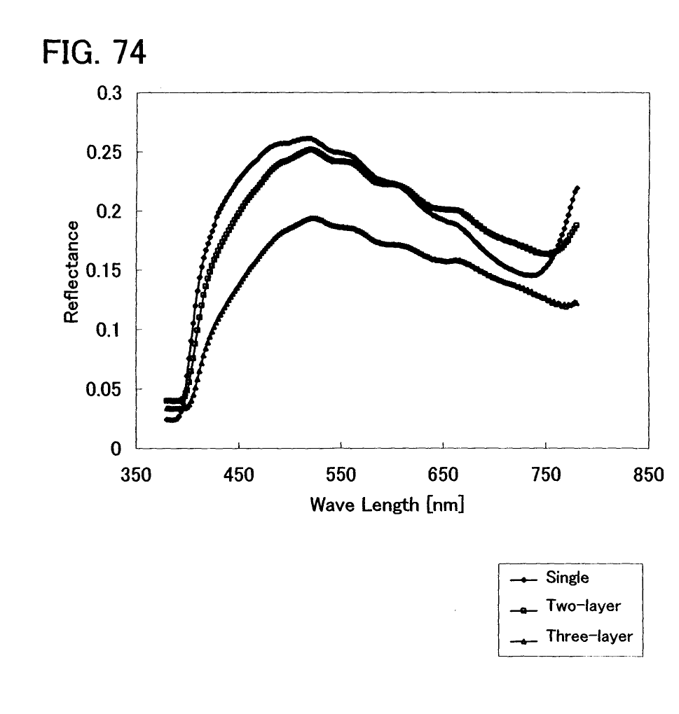

FIG. 74 shows reflectance with respect to a wavelength when the number of polarizing plates is changed when the voltage applied to the liquid crystal is 0 V (in light display).

According to FIG. 74, it can be known that reflectance is reduced in the whole wavelength region, as the number of plates included in the polarizing plate 294 is increased.

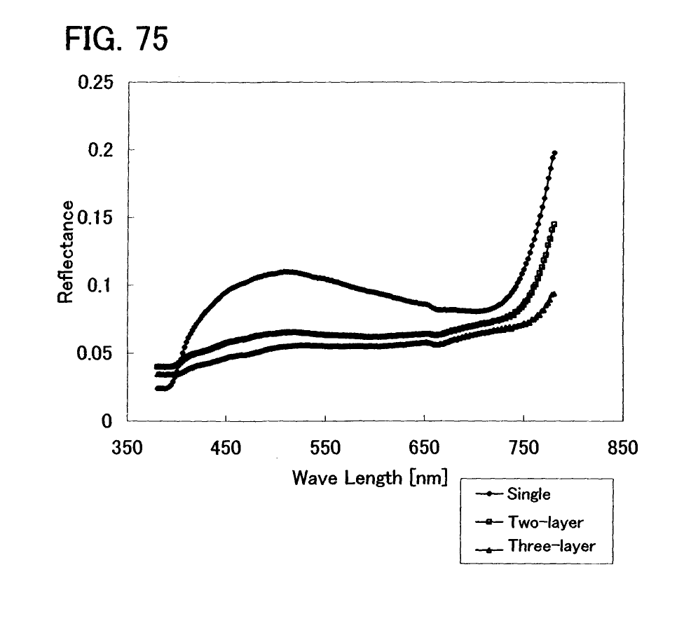

FIG. 75 shows reflectance with respect to a wavelength when the number of polarizing plates is changed when the voltage applied to the liquid crystal is 5 V (in dark display).

In FIG. 75, when the case where the polarizing plate 294 is single, and the case where the polarizing plate 294 is two-layer stack are compared, it is known that reflectance is reduced greatly in the case where the polarizing plate 283 is two-layer stack. In other words, it is known that since the reflectance is reduced greatly, black luminance is reduced.

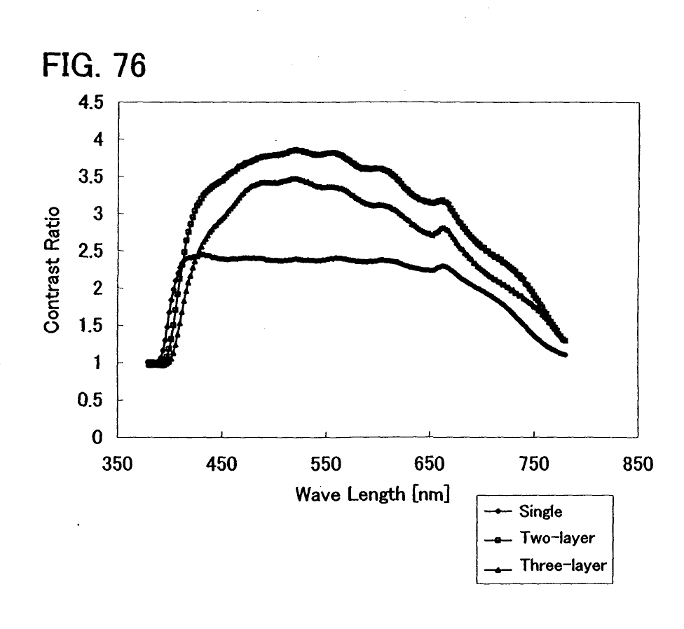

FIG. 76 shows a contrast ratio with respect to a wavelength when the number of plates included in the polarizing plate 294 is changed.

In FIG. 76, when the case where the polarizing plate 294 is single, and the case where the polarizing plate 294 is two-layer stack are compared, it is known that the contrast ratio in a wavelength region of 410 nm or more is increased in the latter case.

Even when the number of plates included in the polarizing plate 294 is more increased, in other words, three polarizing plates 294a, 294b and 294c are stacked, the contrast ratio is not changed so greatly. It is thought that this is because the degree of reduction in reflectance in the light display in relation to the number of the polarizing plate 294 and the degree of reduction in reflectance in the dark display are equal, and the contrast ratio is in saturation state, similarly to the optical calculation results described in Example 2.

According to the above described experiment results, it can be said that the contrast ratio can be increased by stacking the polarizing plates in a reflective type liquid crystal display device. The present application is based on Japanese Patent application No. 2006-026415 filed on Feb. 2, 2006 in the Japanese Patent Office, the entire contents of which are hereby incorporated by reference.

### EXPLANATION OF REFERENCE NUMERALS

100: display element, 101: substrate, 102: substrate, 103: polarizer, 104: polarizer, 111: substrate, 112: substrate, 113: polarizing plate, 114: polarizing plate, 116: liquid crystal molecule, 118: protrusion, 119: slit, 120: layer having a liquid crystal element, 121: substrate, 122: substrate, 125: layer having a polarizer, 126: layer having a polarizer, 127: electrode, 128: electrode, 131: adhesive layer, 132: protective film, 133: polarizing film, 135: adhesive layer, 136: protective film, 137: polarizing film, 140: adhesive layer, 141: adhesive layer, 142: protective film, 143: polarizing film, 144: polarizing film, 145: polarizing plate, 146: protective film, 147: polarizing film, 148: polarizing film, 149: polarizing plate, 151: absorption axis, 152: absorption axis, 155: electrode, 156: electrode, 158: polarizing film, 159: polarizing plate, 160: layer having a liquid crystal element, 161: substrate, 162: substrate, 163: polarizing plate, 164: polarizing plate, 165: polarizing plate, 166: polarizing plate, 168: polarizing film, 169: polarizing plate, 171: retardation plate, 172: retardation plate, 173: groove, 174: groove, 176: layer having a display element, 181: absorption axis, 182: absorption axis, 183: absorption axis, 184: absorption axis, 186: slow axis, 187: slow axis, 191: TFT, 192: gate wiring, 193: island-shaped semiconductor film, 196: drain electrode, 197: source electrode, 198: source wiring, 199: pixel electrode, 200: display element, 201: substrate, 202: substrate, 203: polarizer, 204: polarizer, 206: groove, 207: groove, 208: auxiliary capacitor, 211: retardation plate, 215: polarizing film, 216: polarizing film, 217: polarizing plate, 221: absorption axis, 222: absorption axis, 223: slow axis, 225: polarizing film, 226: polarizing film, 227: polarizing plate, 231: TFT, 232: gate wiring, 233: common wiring, 234: contact hole, 235: source wiring, 236: drain electrode, 237: island-shaped semiconductor film, 238: source electrode, 241: pixel electrode, 242: common electrode, 251: TFT, 252: gate wiring, 253: island-shaped semiconductor film, 256: drain electrode, 257: source electrode, 258: source wiring, 259: pixel electrode, 263: groove, 265: protrusion, 267: auxiliary capacitor, 271: electrode, 272: electrode, 273: insulating layer, 275: electric field, 280: reflective plate, 281: liquid crystal cell, 282: retardation plate, 283: polarizing plate, 283a: polarizing plate, 283n: polarizing plate, 290: reflective plate, 291: liquid crystal cell, 292: substrate, 293: retardation plate, 294: polarizing plate, 294a: polarizing plate, 294n: polarizing plate, 295: circular polarizing plate, 300: layer having a liquid crystal element, 301: substrate, 302: substrate, 303: polarizing plate, 304: polarizing plate, 305: polarizing plate, 306: polarizing plate, 308: alignment film, 321: absorption axis, 322: absorption axis, 323: absorption axis, 324: absorption axis, 350: liquid crystal display panel, 351: polarizing plate, 352: counter substrate, 353: liquid crystal layer, 354: active matrix substrate, 355: polarizing plate, 360: retardation plate, 370: Switching liquid crystal panel, 371: substrate on the driver side, 372: liquid crystal layer, 373: counter substrate, 374: polarizing plate, 381: wiring, 382: wiring, 401: video signal, 402: control circuit, 403: signal line driver circuit, 404: scanning line driver circuit, 405: pixel portion, 406: lighting means, 407: power source: 408: driver circuit portion, 410: scanning line, 412: signal line, 421: IC, 422: conductive microparticle, 431: shift register, 432: latch, 433: latch, 434: level shifter, 435: buffer, 441: shift register, 442: level shifter, 443: buffer, 501: substrate, 502: base film, 503: switching TFT, 504: capacitor element, 505: interlayer insulating film, 506: pixel electrode, 507: protective film, 508: alignment film, 510: connecting terminal, 511: liquid crystal, 516: polarizing plate, 520: counter substrate, 521: polarizing plate, 522: color filter, 523: counter electrode, 524: black matrix, 525: spacer, 526: alignment film, 528: sealing material, 531: light source: 532: lamp reflector, 533: switching TFT, 534: reflective plate, 535: light guide plate, 536: diffusing plate, 537: bump, 541: polarizing plate, 542: polarizing plate, 543: polarizing plate, 544: polarizing plate, 546: retardation plate, 547: retardation plate, 552: backlight unit, 554: CMOS circuit, 571: cold cathode tube, 572: light emitting diode, 573: light emitting diode, 574: light emitting diode, 575: light emitting diode, 600: layer having a liquid crystal element, 601: substrate, 602: substrate, 603: polarizing plate, 604: polarizing plate, 621: retardation plate, 651: absorption axis, 652: absorption axis, 701: substrate, 702: base film, 703: switching TFT, 704: capacitor element, 705: interlayer insulating film, 706: pixel electrode, 707: protective film, 708: alignment film, 710: connecting terminal, 711: liquid crystal, 716: retardation plate, 717: polarizing plate, 718: polarizing plate, 720: counter substrate, 722: color filter, 723: counter electrode, 724: black matrix, 725: spacer, 726: alignment film, 728: sealing material, 733: switching TFT, 741: retardation plate, 742: polarizing plate, 743: polarizing plate, 754: CMOS circuit, 800: layer having a liquid crystal element, 801: substrate, 802: substrate, 803: polarizing plate, 804: polarizing plate, 811: pixel electrode, 812: counter electrode, 821: retardation plate, 825: retardation plate, 826: polarizing plate, 827: polarizing plate, 831: pixel electrode, 832: counter electrode, 841: retardation plate, 842: polarizing plate, 843: polarizing plate, 851: absorption axis, 852: absorption axis, 853: slow axis, 1100: layer including an electroluminescent element, 1101: substrate, 1102: substrate, liii: polarizing plate, 1112: polarizing plate, 1121: polarizing plate, 1122: polarizing plate, 1131: polarizing plate, 1132: polarizing plate, 1151: absorption axis, 1152: absorption axis, 1153: absorption axis, 1154: absorption axis, 1201: substrate, 1203: thin film transistor, 1204: thin film transistors, 1205: insulating layer, 1206: electrode, 1207: electroluminescent layer, 1208: electrode, 1209: light emitting element, 1210: insulating layer, 1214: capacitor element, 1215: pixel portion, 1216: polarizing plate, 1217: polarizing plate, 1218: driver circuit portion, 1218a: signal line driver circuit portion, 1218b: scanning line driver circuit portion, 1219: polarizing plate, 1220: counter substrate, 1225: retardation plate, 1226: polarizing plate, 1227: polarizing plate, 1228: sealing material, 1229: polarizing plate, 1235: retardation plate, 1241: electrode, 1242: electrode, 1251: electrode, 1252: electrode, 1300: layer having electroluminescent element, 1301: substrate, 1302: substrate, 1311: polarizing plate, 1312: polarizing plate, 1313: retardation plate, 1315: polarizing plate, 1321: polarizing plate, 1322: polarizing plate, 1323: retardation plate, 1325: polarizing plate, 1331: slow axis, 1332: slow axis, 1335: absorption axis, 1336: absorption axis, 1337: absorption axis, 1338: absorption axis, 1351: shift register, 1354: level shifter, 1355: buffer, 1361: shift register, 1362: latch circuit, 1363: latch circuit, 1364: level shifter, 1365: buffer, 1371: scanning line, 1372: signal line, 1380: transistor, 1381: transistor, 1382: capacitor element, 1383: light emitting element: 1384: signal line, 1385: power supply line, 1386: scanning line, 1388: transistor, 1389: scanning line, 1395: transistor, 1396: wiring, 1400: layer including an electroluminescent element, 1401: substrate, 1402: substrate, 1403: polarizing plate, 1404: polarizing plate, 1421: retardation plate, 1451: absorption axis, 1452: absorption axis, 1453: slow axis, 1460: layer having a display element, 1461: substrate, 1462: substrate, 1471: polarizing plate, 1472: polarizing plate, 1473: retardation plate, 1475: polarizing plate, 1481: polarizing plate, 1482: polarizing plate, 1483: retardation plate, 1485: polarizing plate, 1491: slow axis, 1492: slow axis, 1495: absorption axis, 1496: absorption axis, 1497: absorption axis, 1498: absorption axis, 1500: layer including an electroluminescent element, 1501: substrate, 1502: substrate, 1503: polarizing plate, 1504: polarizing plate, 1521: retardation plate, 1523: polarizing plate, 1551: absorption axis, 1552: absorption axis, 1553: slow axis, 1560: layer including a display element, 1561: substrate, 1562: substrate, 1571: polarizing plate, 1572: polarizing plate, 1573: polarizing plate, 1575: retardation plate, 1576: retardation plate, 1581: polarizing plate, 1582: polarizing plate, 1583: polarizing plate, 1591: slow axis, 1592: slow axis, 1595: absorption axis, 1596: absorption axis, 1597: absorption axis, 1598: absorption axis, 1600: layer including a display element, 1601: substrate, 1602: substrate, 1611: polarizing plate, 1612: polarizing plate, 1613: polarizing plate, 1621: polarizing plate, 1622: polarizing plate, 1623: polarizing plate, 1631: absorption axis, 1632: absorption axis, 1633: absorption axis, 1634: absorption axis, 1660: layer including a display element, 1661: substrate, 1662: substrate, 1671: polarizing plate, 1672: polarizing plate, 1673: polarizing plate, 1675: retardation plate, 1676: retardation plate, 1681: polarizing plate, 1682: polarizing plate, 1683: polarizing plate, 1691: slow axis, 1692: slow axis, 1695: absorption axis, 1696: absorption axis, 1697: absorption axis, 1698: absorption axis, 1701: main body, 1702: display portion, 1711: display portion, 1712: display portion, 1721: main body, 1722: display portion, 1731: main body, 1732: display portion, 1741: main body, 1742: display portion, 1751: main body, 1752: display portion, 1801: display panel, 1802: circuit board, 1803: control circuit, 1804: signal dividing circuit, 1805: pixel portion, 1806: scanning line driver circuit, 1807: signal line driver circuit, 1808: connecting wiring, 1811: tuner, 1812: video signal amplifying circuit, 1813: video signal processing circuit, 1814: audio signal amplifying circuit, 1815: audio signal processing circuit, 1816: speaker, 1817: control circuit, 1818: input portion, 1819: operation switch, 1900: backlight, 1901: polarizing plate, 1901a: polarizing plate, 1901n: polarizing plate, 1902: Transparent glass, 1903: liquid crystal cell, 1904: transparent glass, 1905: polarizing plate, 1905a: polarizing plate, 1905n: polarizing plate,

1. A display device comprising:
a first substrate;
a second substrate;
a layer including a display element which is interposed between the first substrate and the second substrate;
stacked first polarizers; and
stacked second polarizers,
wherein the stacked first polarizers are arranged to be in a parallel Nicols;
wherein the stacked second polarizers are arranged to be in a parallel Nicols; and
wherein the stacked first polarizers and the stacked second polarizers are arranged to be in a crossed Nicols.

2. A display device comprising:
a first substrate;
a second substrate;
a layer including a display element which is interposed between the first substrate and the second substrate;
stacked first polarizers; and
stacked second polarizers,
wherein the stacked first polarizers are arranged to be in a parallel Nicols;
wherein the stacked second polarizers are arranged to be in a parallel Nicols, and
wherein the stacked first polarizers and the stacked second polarizers are arranged to be in a parallel Nicols.

3. A display device comprising:
a first substrate;
a second substrate;
a layer including a display element which is interposed between the first substrate and the second substrate; and
stacked polarizers,
wherein the stacked polarizers on the first substrate are arranged to be in a parallel Nicols;
wherein the stacked polarizers have the same wavelength distribution in the extinction coefficients.

4. A display device comprising:
a first substrate;
a second substrate;
a layer including a display element which is interposed between the first substrate and the second substrate;
stacked first polarizers; and
stacked second polarizers,
wherein the stacked first polarizers on the first substrate are arranged to be in a parallel Nicols;
wherein the stacked first polarizers have the same wavelength distribution in the extinction coefficients;
wherein the stacked second polarizers on the second substrate are arranged to be in a parallel Nicols;
wherein the stacked second polarizers have the same wavelength distribution in the extinction coefficients, and
wherein the stacked first polarizers and the stacked second polarizers are arranged to be in a crossed Nicols state.

5. A display device comprising:
a first substrate;
a second substrate;
a layer including a display element which is interposed between the first substrate and the second substrate;
stacked first polarizers; and
stacked second polarizers,
wherein the stacked first polarizers on the first substrate are arranged to be in a parallel Nicols;
wherein the stacked first polarizers have the same wavelength distribution in the extinction coefficients;
wherein the stacked second polarizers on the second substrate are arranged to be in a parallel Nicols;
wherein the stacked second polarizers have the same wavelength distribution in the extinction coefficients, and
wherein the stacked first polarizers and the stacked second polarizers are arranged to be in a parallel Nicols state.

6. A display device comprising:
a first substrate;
a second substrate;
a layer including a display element which is interposed between the first substrate and the second substrate;
a retardation plate, and
stacked polarizers,
wherein the stacked polarizers on the first substrate are arranged to be in a parallel Nicols;
wherein the retardation plate is interposed between the first substrate and the stacked polarizers, and
wherein the stacked polarizers have the same wavelength distribution in the extinction coefficients.

7. A display device comprising:
a first substrate;
a second substrate;
a layer including a display element which is interposed between the first substrate and the second substrate;
a first retardation plate;
a second retardation plate;
stacked first polarizers; and
stacked second polarizers,
wherein the stacked first polarizers on the first substrate are arranged to be in a parallel Nicols;
wherein the stacked first polarizers have the same wavelength distribution in the extinction coefficients;
wherein the first retardation plate is interposed between the first substrate and the stacked first polarizers;
wherein the stacked second polarizers on the second substrate are arranged to be in a parallel Nicols;
wherein the stacked second polarizers have the same wavelength distribution in the extinction coefficients;
wherein the second retardation plate is interposed between the second substrate and the stacked second polarizers, and
wherein the stacked first polarizers and the stacked second polarizers are arranged to be in a crossed Nicols state.

8. A display device comprising:
a first substrate;
a second substrate;
a layer including a display element which is interposed between the first substrate and the second substrate;
a first retardation plate;
a second retardation plate;
stacked first polarizers; and
stacked second polarizers,
wherein the stacked first polarizers on the first substrate are arranged to be in a parallel Nicols;
wherein the stacked first polarizers have the same wavelength distribution in the extinction coefficients;
wherein the first retardation plate is interposed between the first substrate and the stacked first polarizers;
wherein the stacked second polarizers on the second substrate are arranged to be in a parallel Nicols;
wherein the stacked second polarizers have the same wavelength distribution in the extinction coefficients;
wherein the second retardation plate is interposed between the second substrate and the stacked second polarizers, and
wherein the stacked first polarizers and the stacked second polarizers are arranged to be in a parallel Nicols state.

9. The display device according to claim 6, wherein the absorption axes of the stacked polarizers and a slow axis of the retardation plate are arranged to be shifted by 45°.

10. The display device according to claim 7 or 8,
wherein the absorption axes of the stacked first polarizers and a slow axis of the first retardation plate are arranged to be shifted by 45°; and
wherein the absorption axes of the stacked second polarizers and a slow axis of the second retardation plate are arranged to be shifted by 45°.

11. The display device according to any one of claims 1 to 8, wherein the display element is a liquid crystal element.

12. The display device according to any one of claims 1 to 8, wherein the display element is an electroluminescent element.
